(19) United States
(12) Patent Application Publication
(10) Pub. No.: US 2024/0215289 A1
(43) Pub. Date: Jun. 27, 2024

(54) DISPLAY DEVICE AND MANUFACTURING METHOD OF DISPLAY DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Takayuki IKEDA, Atsugi, Kanagawa (JP)

(21) Appl. No.: 18/289,002

(22) PCT Filed: Apr. 26, 2022
(86) PCT No.: PCT/IB2022/053834

§ 371 Date: Oct. 31, 2023

(30) Foreign Application Priority Data
May 13, 2021 (JP) 2021-081588
May 13, 2021 (JP) 2021-081594
Jun. 8, 2021 (JP) 2021-096113

(51) Int. Cl. H10K 50/13; H10K 59/123; H10K 71/13; H10K 71/16; H10K 71/20; H10K 71/60

(52) U.S. Cl. CPC H10K 50/13; H10K 59/123; H10K 71/13; H10K 71/166; H10K 71/233; H10K 71/60

(57) ABSTRACT

A display device with a substantially high resolution is provided. The display device includes first to fourth EL layers arranged in this order to be adjacent to each other in one direction. The first and second EL layers emit light of the same color, and the third and fourth EL layers emit light of the same color. The third and fourth EL layers emit light of a color different from the color of the light emitted from the first and second EL layers. A first EL film and a second EL film are formed and divided by a photolithography method, whereby the first to fourth EL layers are formed. The first and second EL layers are formed from the first EL film, and the third and fourth EL layers are formed from the second EL film.

### TECHNICAL FIELD

One embodiment of the present invention relates to a display device. One embodiment of the present invention relates to a method for manufacturing a display device. One embodiment of the present invention relates to a method for driving a display device. One embodiment of the present invention relates to a display module and an electronic device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for fabricating any of them.

### BACKGROUND ART

Display devices have been required to have higher resolution. For example, devices for virtual reality (VR), augmented reality (AR), substitutional reality (SR), or mixed reality (MR) are given as devices requiring high-resolution display devices and have been actively developed.

In recent years, display devices have been expected to be applied to a variety of uses. Examples of uses for a large display device include a television device for home use (also referred to as a TV or a television receiver), digital signage, and a PID (Public Information Display). In addition, a smartphone, a tablet terminal, and the like including a touch panel are being developed as portable information terminals.

Light-emitting apparatuses including light-emitting devices (also referred to as light-emitting elements) have been developed as display devices, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display devices.

Patent Document 1 discloses a display device using an organic EL device (also referred to as an organic EL element) for VR. Patent Document 2 discloses a large display device using an organic EL device (also referred to as an organic EL element). Non-Patent Document 1 discloses a method for fabricating an organic optoelectronic device using standard UV photolithography.

### REFERENCE

### Patent Document

[Patent Document 1] PCT International Publication No. 2018/087625
[Patent Document 2] Japanese Published Patent Application No. 2019-175832

### Non-Patent Document

[Non-Patent Document 1] B. Lamprecht et al., “Organic optoelectronic device fabrication using standard UV photolithography” phys. stat. sol. (RRL) 2, No. 1, pp. 16-18 (2008)

### SUMMARY OF THE INVENTION

### Problems to be Solved by the Invention

In the case of fabricating a display device including a plurality of organic EL elements emitting light of different colors, light-emitting layers emitting light of different colors each need to be formed into an island shape.

For example, an island-shaped light-emitting layer can be formed by a vacuum evaporation method using a metal mask (also referred to as a shadow mask). However, this method causes a deviation from the designed shape and position of an island-shaped light-emitting layer due to various influences such as a low accuracy of the metal mask, positional deviation between the metal mask and a substrate, a warp of the metal mask, and vapor-scattering-induced expansion of outline of the formed film, for example. Accordingly, an island-shaped light-emitting layer with a fine pattern is difficult to obtain, making it difficult to achieve high resolution and a high aperture ratio of the display device. In addition, the outline of the layer may blur during vapor deposition, whereby the thickness of an end portion might be small. That is, the thickness of the island-shaped light-emitting layer might vary from area to area.

An object of one embodiment of the present invention is to provide a display device with a substantially high resolution. An object of one embodiment of the present invention is to provide a display device capable of displaying a high-definition image. An object of one embodiment of the present invention is to provide a display device capable of displaying a high-quality image. An object of one embodiment of the present invention is to provide a highly reliable display device.

An object of one embodiment of the present invention is to provide a method for manufacturing a display device with a substantially high resolution. An object of one embodiment of the present invention is to provide a method for manufacturing a display device capable of displaying a high-definition image. An object of one embodiment of the present invention is to provide a method for manufacturing a display device capable of displaying a high-quality image. An object of one embodiment of the present invention is to provide a method for manufacturing a highly reliable display device. An object of one embodiment of the present invention is to provide a method for manufacturing a display device with high yield.

An object of one embodiment of the present invention is to provide a method for driving a display device with a substantially high resolution. An object of one embodiment of the present invention is to provide a method for driving a display device capable of displaying a high-definition image. An object of one embodiment of the present invention is to provide a method for driving a display device capable of displaying a high-quality image.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display device including a first pixel electrode, a second pixel electrode, a third pixel electrode, a fourth pixel electrode, a first EL layer over the first pixel electrode, a second EL layer over the second pixel electrode, a third EL layer over the third pixel electrode, and a fourth EL layer over the fourth pixel electrode. The first EL layer, the second EL layer, the third EL layer, and the fourth EL layer are arranged in this order to be adjacent to each other in one direction. The first EL layer and the second EL layer emit light of the same color. The third EL layer and the fourth EL layer emit light of the same color. The third and fourth EL layers emit light of a color different from the color of the light emitted from the first and second EL layers.

The above embodiment may be as follows: a first transistor, a second transistor, a third transistor, and a fourth transistor are included; one of a source and a drain of the first transistor is electrically connected to the first pixel electrode; one of a source and a drain of the second transistor is electrically connected to the second pixel electrode; one of a source and a drain of the third transistor is electrically connected to the third pixel electrode; one of a source and a drain of the fourth transistor is electrically connected to the fourth pixel electrode; and one or more of the first to fourth transistors include a metal oxide in a channel formation region.

In the above embodiment, an insulating layer may be provided in a region between the first EL layer and the second EL layer, a region between the second EL layer and the third EL layer, and a region between the third EL layer and the fourth EL layer.

In the above embodiment, the insulating layer may include an organic material.

In the above embodiment, the insulating layer may include a photosensitive material.

The above embodiment may be as follows: a common layer over the first to fourth EL layers and the insulating layer, and a common electrode over the common layer are included, and the common layer includes at least one of a hole-injection layer, a hole-transport layer, a hole-blocking layer, an electron-blocking layer, an electron-transport layer, and an electron-injection layer.

Another embodiment of the present invention is a method for manufacturing a display device, including the steps of forming a first pixel electrode, a second pixel electrode, a third pixel electrode, and a fourth pixel electrode, forming a first EL film over the first and second pixel electrodes and a second EL film over the third and fourth pixel electrodes, processing the first EL film to form a first EL layer over the first pixel electrode and a second EL layer over the second pixel electrode, and processing the second EL film to form a third EL layer over the third pixel electrode and a fourth EL layer over the fourth pixel electrode. The first EL layer, the second EL layer, the third EL layer, and the fourth EL layer are arranged in this order to be adjacent to each other in one direction.

In the above embodiment, the first and second EL layers may emit light of a color different from the color of the light emitted from the third and fourth EL layers.

In the above embodiment, the first EL film and the second EL film may be formed by an evaporation method using a metal mask.

In the above embodiment, the first EL film and the second EL film may be formed by a wet method.

The above embodiment may be as follows: after the first EL film and the second EL film are formed, a sacrificial film is formed over the first EL film and the second EL film; a resist mask is formed over the sacrificial film; and the sacrificial film, the first EL film, and the second EL film are processed to form the first to fourth EL layers and first to fourth sacrificial layers over the first to fourth EL layers.

The above embodiment may be as follows: after the first to fourth EL layers are formed, an insulating film is formed to cover the first to fourth EL layers; and the insulating film is processed to form an insulating layer in a region between the first EL layer and the second EL layer, a region between the second EL layer and the third EL layer, and a region between the third EL layer and the fourth EL layer.

In the above embodiment, the insulating film may be formed by a spin coating method, a spray coating method, or a screen printing method.

In the above embodiment, the insulating film may be formed using a photosensitive material and processed by a photolithography method.

The above embodiment may be as follows: at least one of a hole-injection layer, a hole-transport layer, a hole-blocking layer, an electron-blocking layer, an electron-transport layer, and an electron-injection layer is formed as a common layer over the first to fourth EL layers; and a common electrode is formed over the common layer.

Another embodiment of the present invention is a method for driving a display device. The display device includes a first subpixel, a second subpixel adjacent to the first subpixel and emitting light of the same color as the first subpixel, a third subpixel emitting light of a color different from the color of the light emitted from the first and second subpixels, and a fourth subpixel adjacent to the third subpixel and emitting light of the same color as the third subpixel. The first to fourth subpixels are arranged in one direction. The display device further includes a fifth subpixel, a sixth subpixel adjacent to the fifth subpixel and emitting light of a color different from the color of the light emitted from the fifth subpixel, a seventh subpixel emitting light of the same color as the fifth subpixel, and an eighth subpixel adjacent to the seventh subpixel and emitting light of the same color as the sixth subpixel. The fifth to eighth subpixels are arranged in one direction. Image data assumed to be displayed on the display device is generated. The image data has a first value corresponding to the luminance of the light emitted from the fifth subpixel, a second value corresponding to the luminance of the light emitted from the sixth subpixel, a third value corresponding to the luminance of the light emitted from the seventh subpixel, and a fourth value corresponding to the luminance of the light emitted from the eighth subpixel. A fifth value is generated from the first value and the third value. A sixth value is generated from the second value and the fourth value. The first subpixel emits light with the luminance corresponding to the first value. The second subpixel emits light with the luminance corresponding to the fifth value. The third subpixel emits light with the luminance corresponding to the sixth value. The fourth subpixel emits light with the luminance corresponding to the fourth value.

The above embodiment may be as follows: the fifth value includes the sum of a value obtained by multiplying the first value by a first coefficient and a value obtained by multiplying the third value by a second coefficient; and the sixth value includes the sum of a value obtained by multiplying the second value by a third coefficient and a value obtained by multiplying the fourth value by a fourth coefficient.

The above embodiment may be as follows: the first coefficient is larger than the second coefficient and the third coefficient is smaller than the fourth coefficient.

### Effect of the Invention

According to one embodiment of the present invention, a display device with a substantially high resolution can be provided. According to one embodiment of the present invention, a display device capable of displaying a high-definition image can be provided. According to one embodiment of the present invention, a display device capable of displaying a high-quality image can be provided. According to one embodiment of the present invention, a highly reliable display device can be provided.

According to one embodiment of the present invention, a method for manufacturing a display device with a substantially high resolution can be provided. According to one embodiment of the present invention, a method for manufacturing a display device capable of displaying a high-definition image can be provided. According to one embodiment of the present invention, a method for manufacturing a display device capable of displaying a high-quality image can be provided. According to one embodiment of the present invention, a method for manufacturing a highly reliable display device can be provided. An object of one embodiment of the present invention is to provide a method for manufacturing a display device with high yield.

According to one embodiment of the present invention, a method for driving a display device with a substantially high resolution can be provided. According to one embodiment of the present invention, a method for driving a display device capable of displaying a high-definition image can be provided. According to one embodiment of the present invention, a method for driving a display device capable of displaying a high-quality image can be provided.

Note that the description of these effects does not preclude the existence of other effects. One embodiment of the present invention does not need to have all of these effects. Other effects can be derived from the description of the specification, the drawings, and the claims.

### BRIEF DESCRIPTION OF THE DRAWINGS

FIG. 1 is a top view illustrating a structure example of a display device.

FIG. 2A to FIG. 2D are cross-sectional views illustrating structure examples of a display device.

FIG. 3A, FIG. 3B, FIG. 3C1, and FIG. 3C2 are cross-sectional views illustrating structure examples of a display device.

FIG. 4 is a cross-sectional view illustrating a structure example of a display device.

FIG. 5A to FIG. 5E are cross-sectional views illustrating structure examples of a display device.

FIG. 6A to FIG. 6C are cross-sectional views illustrating structure examples of a display device.

FIG. 7A to FIG. 7D are cross-sectional views illustrating a manufacturing method example of a display device.

FIG. 8A is a top view illustrating a manufacturing method example of a display device. FIG. 8B is a cross-sectional view illustrating a manufacturing method example of a display device.

FIG. 9A is a top view illustrating a manufacturing method example of a display device. FIG. 9B is a cross-sectional view illustrating a manufacturing method example of a display device.

FIG. 10A to FIG. 10C are cross-sectional views illustrating a manufacturing method example of a display device.

FIG. 11A and FIG. 11B are cross-sectional views illustrating a manufacturing method example of a display device.

FIG. 12 is a flowchart showing a driving method example of a display device.

FIG. 13 is a top view for describing a driving method example of a display device.

FIG. 14A is a top view illustrating a structure example of a display device. FIG. 14B is a cross-sectional view illustrating the structure example of the display device.

FIG. 15A and FIG. 15B are cross-sectional views illustrating a manufacturing method example of a display device. FIG. 15C is a top view illustrating a structure example of the display device.

FIG. 16 is a top view illustrating a structure example of a display device.

FIG. 17A to FIG. 17D are cross-sectional views illustrating a structure example of a display device.

FIG. 18 is a top view illustrating a structure example of a display device.

FIG. 19A is a top view illustrating a structure example of a display device. FIG. 19B is a cross-sectional view illustrating the structure example of the display device.

FIG. 20 is a top view illustrating a structure example of a display device.

FIG. 21 is a top view illustrating a structure example of a display device.

FIG. 22A and FIG. 22B are perspective views illustrating a structure example of a display device.

FIG. 23A, FIG. 23B1, and FIG. 23B2 are cross-sectional views illustrating structure examples of a display device.

FIG. 24 is a cross-sectional view illustrating a structure example of a display device.

FIG. 25 is a cross-sectional view illustrating a structure example of a display device.

FIG. 26 is a cross-sectional view illustrating a structure example of a display device.

FIG. 27 is a cross-sectional view illustrating a structure example of a display device.

FIG. 28 is a cross-sectional view illustrating a structure example of a display device.

FIG. 29 is a perspective view illustrating a structure example of a display device.

FIG. 30A is a cross-sectional view illustrating a structure example of a display device. FIG. 30B and FIG. 30C are cross-sectional views illustrating structure examples of the display device.

FIG. 31A and FIG. 31B1 to FIG. 31B4 are cross-sectional views illustrating structure examples of a display device.

FIG. 32A to FIG. 32F illustrate structure examples of a light-emitting element.

FIG. 33A to FIG. 33D illustrate examples of an electronic device.

FIG. 34A to FIG. 34F illustrate examples of an electronic device.

FIG. 35A to FIG. 35F illustrate examples of electronic devices.

FIG. 36A to FIG. 36G illustrate examples of electronic devices.

FIG. 37A to FIG. 37F illustrate examples of electronic devices.

FIG. 38A and FIG. 38B are top views illustrating structures of a display device in Example.

FIG. 39A1, FIG. 39A2, FIG. 39B1, and FIG. 39B2 show images in Example.

FIG. 40 is a top view for describing a driving method of a display device in Example.

FIG. 41A1, FIG. 41A2, FIG. 41B1, and FIG. 41B2 show images in Example.

FIG. 42A and FIG. 42B are top views illustrating structures of a display device in Example.

FIG. 43A1, FIG. 43A2, FIG. 43B1, and FIG. 43B2 show images in Example.

FIG. 44A and FIG. 44B are top views illustrating structures of a display device in Example.

FIG. 45A1, FIG. 45A2, FIG. 45B1, and FIG. 45B2 show images in Example.

FIG. 46A and FIG. 46B are top views illustrating structures of a display device in Example.

FIG. 47A1, FIG. 47A2, FIG. 47B1, and FIG. 47B2 show images in Example.

FIG. 48A and FIG. 48B are top views illustrating structures of a display device in Example.

FIG. 49A1, FIG. 49A2, FIG. 49B1, and FIG. 49B2 show images in Example.

### MODE FOR CARRYING OUT THE INVENTION

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Note that the term “film” and the term “layer” can be interchanged with each other depending on the case or circumstances. For example, the term “conductive layer” can be replaced with the term “conductive film”. As another example, the term “insulating film” can be replaced with the term “insulating layer”.

In this specification and the like, a device manufactured using a metal mask or an FMM (a fine metal mask, a high-resolution metal mask) is sometimes referred to as a device having an MM (a metal mask) structure. In this specification and the like, a device manufactured without using a metal mask or an FMM is sometimes referred to as a device having an MML (metal maskless) structure.

### Embodiment 1

In this embodiment, a display device of one embodiment of the present invention, a manufacturing method thereof, and a driving method thereof will be described with reference to drawings.

One embodiment of the present invention relates to a display device in which subpixels are provided in a matrix and each include a light-emitting element. The light-emitting element includes an island-shaped light-emitting layer, and the display device can perform display when the light-emitting layer emits light. The display device of one embodiment of the present invention has a structure in which light-emitting layers are separately formed in subpixels with different colors. In the display device of one embodiment of the present invention, a plurality of subpixels emitting light of the same color are arranged adjacent to each other not only in the column direction but also in the row direction. In other words, the plurality of subpixels emitting light of the same color are separated independently.

In this specification and the like, two subpixels that have the same coordinate in the row direction but have coordinates in the column direction different from each other by one are referred to as subpixels adjacent in the row direction. For example, a subpixel in the first row and the second column is adjacent, in the row direction, to a subpixel in the first row and the first column. Two subpixels that have the same coordinate in the column direction but have coordinates in the row direction different from each other by one are referred to as subpixels adjacent in the column direction. For example, a subpixel in the second row and the first column is adjacent, in the column direction, to the subpixel in the first row and the first column. The same expression is also applied to components, other than subpixels, as long as they are arranged in a matrix. For example, in the case where a plurality of subpixels emitting light of the same color are divided into four, they may be divided into two in the row direction and divided into two in the column direction.

To manufacture the display device with the above structure, after a pixel electrode is formed for each subpixel, a light-emitting film is formed by a vacuum evaporation method using a metal mask, for example. The light-emitting film is formed over a plurality of pixel electrodes. Then, the light-emitting film is processed by a photolithography method, for example. Thus, the light-emitting film is divided for each subpixel, so that island-shaped light-emitting layers can be formed for the respective subpixels. The number of times of processing the light-emitting film by a photolithography method is preferably as small as possible in view of the manufacturing cost and the manufacturing yield. The number of times of processing the light-emitting film by a photolithography method is preferably less than or equal to three, and further preferably one.

As described above, a light-emitting layer with a fine pattern is difficult to obtain with a vacuum evaporation method using a metal mask, for example. In contrast, a fine pattern can be formed by processing a film by, for example, a photolithography method. Thus, an island-shaped light-emitting layer with a fine pattern can be obtained by forming a light-emitting film by a vacuum evaporation method using a metal mask and then processing the light-emitting film by a photolithography method, for example. Accordingly, fine subpixels can be formed and the display device of one embodiment of the present invention can have a substantially high resolution. In addition, the display device of one embodiment of the present invention can display a high-definition image.

As described above, the thickness of an end portion of a light-emitting layer is reduced in some cases in a vacuum evaporation method using a metal mask, for example. In contrast, in the above method for manufacturing the display device, the end portion of the light-emitting layer, which is formed by a vacuum evaporation method using a metal mask, can be removed by processing using a photolithography method. Accordingly, the display device of one embodiment of the present invention can be a display device in which the light-emitting layer has a uniform thickness, specifically, the difference in thickness of the light-emitting layer between the center portion and the end portion is small.

### Structure Example 1 of Display Device

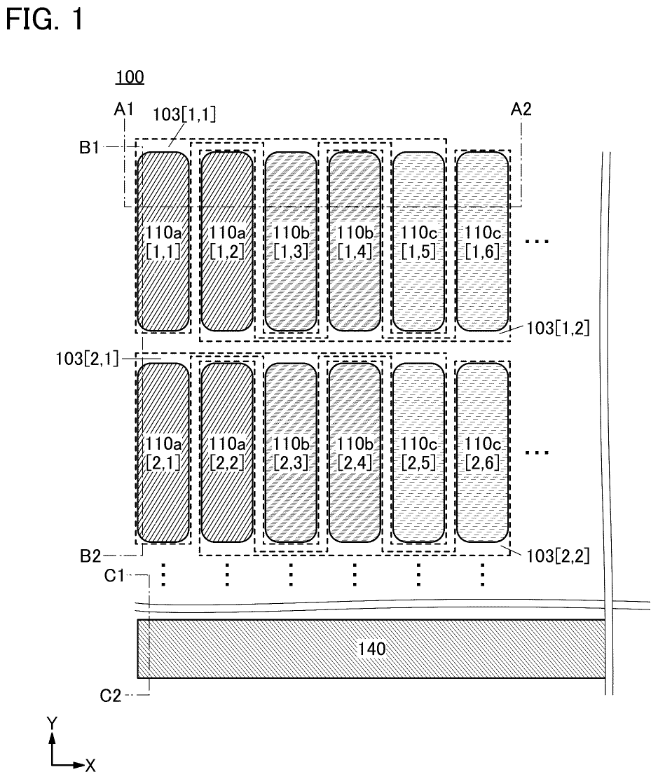

FIG. 1 is a top view illustrating a structure example of a display device 100, which is a display device of one embodiment of the present invention. The display device 100 includes a display portion in which a plurality of pixels 103 are arranged in a matrix, and a connection portion 140 outside the display portion. The connection portion 140 can also be referred to as a cathode contact portion.

The pixel 103 illustrated in FIG. 1 consists of three subpixels: a subpixel 110a, a subpixel 110b, and a subpixel 110c. The subpixel 110a, the subpixel 110b, and the subpixel 110c include light-emitting elements that emit light of different colors. The subpixel 110a, the subpixel 110b, and the subpixel 110c can be subpixels of three colors of red (R), green (G), and blue (B) or subpixels of three colors of yellow (Y), cyan (C), and magenta (M), for example. It can be said that the subpixels 110 illustrated in FIG. 1 employ stripe arrangement.

In this specification and the like, for example, matters common to the subpixel 110a, the subpixel 110b, and the subpixel 110c are described using the collective term “subpixel 110” in some cases. As for other components that are distinguished from each other using alphabets, matters common to the components are sometimes described using reference numerals excluding the alphabets.

FIG. 1 illustrates the subpixels 110 in the first row and the first column to the second row and the sixth column. These subpixels 110 constitute the pixels 103 of two rows and two columns.

In this specification and the like, the row direction is referred to as X direction and the column direction is referred to as Y direction. The X direction and the Y direction intersect with each other and are perpendicular to each other, for example.

In this specification and the like, a sign such as [,] is used in order to distinguish the pixels 103 and the subpixels 110 arranged in a matrix, for example. The same applies to other components in some cases. For example, the position of a component denoted by a sign [,] is referred to as coordinates in some cases.

As illustrated in FIG. 1, the subpixels 110 in the first row and the first column, in the first row and the second column, in the second row and the first column, and in the second row and the second column are each the subpixel 110a; the subpixels 110 in the first row and the third column, in the first row and the fourth column, in the second row and the third column, and in the second row and the fourth column are each the subpixel 110b; and the subpixels 110 in the first row and the fifth column, in the first row and the sixth column, in the second row and the fifth column, and in the second row and the sixth column are each the subpixel 110c. That is, the subpixels 110 emitting light of the same color are arranged at least in two rows and two columns to be adjacent to each other. In other words, subpixels emitting light of the same color are at least divided into two in the row direction and divided into two in the column direction. Note that the subpixels 110 emitting light of the same color may be arranged in three or more columns to be adjacent to each other. In addition, the subpixels 110 emitting light of the same color may be arranged in three or more rows to be adjacent to each other; for example, all of the subpixels 110 in the same column can emit light of the same color.

In the case where the subpixels 110 are arranged in the above manner, for example, a subpixel 110a[1,1], a subpixel 110b[1,3], and a subpixel 110c[1,5] can constitute a pixel 103[1,1]. A subpixel 110a[1,2], a subpixel 110b[1,4], and a subpixel 110c[1,6] can constitute a pixel 103[1,2]. A subpixel 110a[2,1], a subpixel 110b[2,3], and a subpixel 110c[2,5] can constitute a pixel 103[2,1]. A subpixel 110a[2,2], a subpixel 110b[2,4], and a subpixel 110c[2,6] can constitute a pixel 103[2,2]. That is, the following structure can be employed, for example: the subpixels 110 constituting the pixel 103[1,1] and the subpixels 110 constituting the pixel 103[1,2] are alternately arranged; and the subpixels 110 constituting the pixel 103[2,1] and the subpixels 110 constituting the pixel 103[2,2] are alternately arranged.

Although FIG. 1 illustrates an example where the connection portion 140 is positioned on the lower side of the display portion in the top view, there is no particular limitation on the position of the connection portion 140. The connection portion 140 only needs to be provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of the connection portions 140 can be one or more.

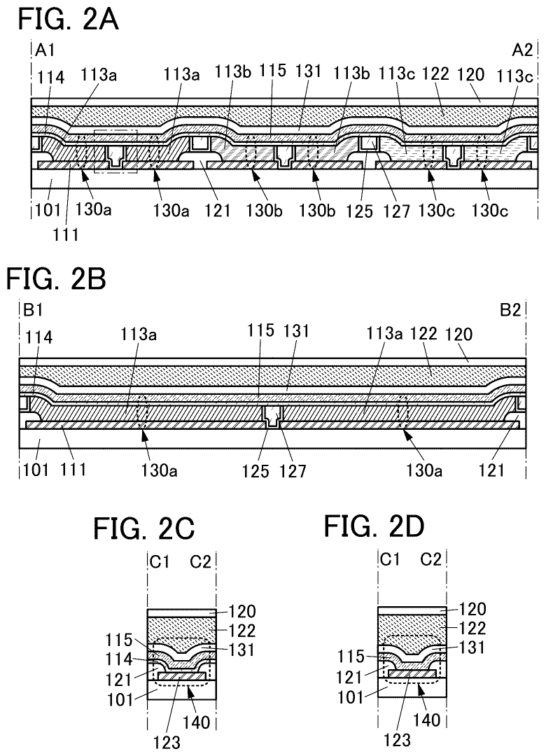

FIG. 2A is a cross-sectional view illustrating a structure example along the dashed-dotted line A1-A2 in FIG. 1. FIG. 2B is a cross-sectional view illustrating a structure example along the dashed-dotted line B1-B2 in FIG. 1.

As illustrated in FIG. 2A and FIG. 2B, in the display device 100, a light-emitting element 130a, a light-emitting element 130b, and a light-emitting element 130c are provided over a layer 101 including transistors. The light-emitting element 130a is provided in the subpixel 110a illustrated in FIG. 1, the light-emitting element 130b is provided in the subpixel 110b illustrated in FIG. 1, and the light-emitting element 130c is provided in the subpixel 110c illustrated in FIG. 1. That is, the light-emitting element 130a, the light-emitting element 130b, and the light-emitting element 130c emit light of different colors.

A protective layer 131 is provided to cover the light-emitting element 130. A substrate 120 is bonded to the protective layer 131 with a resin layer 122. In a region between adjacent light-emitting elements 130, an insulating layer 125 and an insulating layer 127 over the insulating layer 125 are provided. In a region between the light-emitting elements 130 emitting light of different colors among the regions between the adjacent light-emitting elements 130, an insulating layer 121 is provided, and the insulating layer 125 and the insulating layer 127 are provided over the insulating layer 121.

Although FIG. 2A, FIG. 2B, and the like show that a plurality of insulating layers 125 and a plurality of insulating layers 127 are provided, the insulating layers 125 may be connected to each other and the insulating layers 127 may be connected to each other when the display device 100 is seen from above. In other words, the display device 100 can be configured to include one insulating layer 125 and one insulating layer 127, for example. Note that the display device 100 may include the plurality of insulating layers 125 that are separated from each other and the plurality of insulating layers 127 that are separated from each other.

The display device of one embodiment of the present invention can have any of the following structures: a top-emission structure in which light is emitted in a direction opposite to a substrate where the light-emitting element 130 is formed, a bottom-emission structure in which light is emitted toward a substrate where the light-emitting element 130 is formed, and a dual-emission structure in which light is emitted toward both surfaces.

The layer 101 including transistors can employ a stacked-layer structure in which a plurality of transistors are provided on a substrate and an insulating layer is provided to cover these transistors, for example. The layer 101 including transistors may have a depressed portion between adjacent light-emitting elements 130. For example, an insulating layer positioned on the outermost surface of the layer 101 including transistors may have a depressed portion. Structure examples of the layer 101 including transistors will be described later in Embodiment below.

The light-emitting element 130a emits red (R) light, for example. The light-emitting element 130b emits green (G) light, for example. The light-emitting element 130b emits blue (B) light, for example. The light-emitting element 130a, the light-emitting element 130b, and the light-emitting element 130c may each emit yellow (Y), cyan (C), or magenta (M) light.

As the light-emitting element 130a, the light-emitting element 130b, and the light-emitting element 130c, an EL element such as an OLED (Organic Light Emitting Diode) or a QLED (Quantum-dot Light Emitting Diode) is preferably used. Examples of a light-emitting substance contained in the EL element include a substance that emits fluorescent light (a fluorescent material), a substance that emits phosphorescent light (a phosphorescent material), an inorganic compound (e.g., a quantum dot material), and a substance that exhibits thermally activated delayed fluorescence (a TADF material). As a TADF material, a material that is in thermal equilibrium between a singlet excited state and a triplet excited state may be used. Such a TADF material has a shorter light emission lifetime (excitation lifetime) and thus can inhibit a reduction in efficiency of the light-emitting element in a high-luminance region.

The light-emitting element includes an EL layer between a pair of electrodes. In this specification and the like, one of the pair of electrodes is referred to as a pixel electrode and the other is referred to as a common electrode in some cases.

The light-emitting element 130 includes a pixel electrode 111 over the layer 101 including transistors, an island-shaped EL layer 113 over the pixel electrode 111, a common layer 114 over the EL layer 113, and a common electrode 115 over the common layer 114.

The EL layer 113 includes at least a light-emitting layer (a layer containing a light-emitting organic compound). The EL layer 113 preferably includes a light-emitting layer and a carrier-transport layer over the light-emitting layer. Accordingly, the light-emitting layer is inhibited from being exposed on the outermost surface in the fabrication process of the display device 100, so that damage to the light-emitting layer can be reduced. Thus, the reliability of the display device 100 can be increased.

The EL layer 113 can include one or more of a hole-injection layer, a hole-transport layer, a hole-blocking layer, an electron-blocking layer, an electron-transport layer, and an electron-injection layer. For example, the EL layer 113 can have a structure in which a hole-injection layer, a hole-transport layer, a light-emitting layer, and an electron-transport layer are stacked in this order from the pixel electrode 111 side. Alternatively, the EL layer 113 can have a structure in which an electron-injection layer, an electron-transport layer, a light-emitting layer, and a hole-transport layer are stacked in this order from the pixel electrode 111 side.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that in some cases, the above-described carrier-injection layer, carrier-transport layer, and carrier-blocking layer cannot be distinguished from each other depending on the cross-sectional shape, properties, or the like. One layer may have two or three functions of the carrier-injection layer, the carrier-transport layer, and the carrier-blocking layer in some cases.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 and the common electrode 115 are each shared by the plurality of light-emitting elements 130 and for example, shared by all the light-emitting elements 130.

There is no particular limitation on the structure of the light-emitting element in this embodiment, and the light-emitting element can have a single structure or a tandem structure. Note that structure examples of the light-emitting element will be described later in Embodiment below.

The EL layer 113 included in the light-emitting element 130a is an EL layer 113a. The EL layer 113 included in the light-emitting element 130b is an EL layer 113b. The EL layer 113 included in the light-emitting element 130c is an EL layer 113c.

As described above, the insulating layer 121 is provided in the region between the light-emitting elements 130 emitting light of different colors among the regions between the adjacent light-emitting elements 130. The insulating layer 121 is provided so as to cover end portions of the pixel electrodes 111. This can prevent a short circuit between the pixel electrodes 111 in the adjacent light-emitting elements 130. Thus, unintended light emission from the light-emitting elements 130 can be prevented.

The insulating layer 121 can have a single-layer structure or a stacked-layer structure including one or both of an inorganic insulating film and an organic insulating film.

When an inorganic insulating film is used as the insulating layer 121 that covers the end portions of the pixel electrodes 111, impurities are less likely to enter the EL layer 113 as compared with the case where an organic insulating film is used; therefore, the reliability of the light-emitting element 130 can be improved. When an organic insulating film is used as the insulating layer 121, high step coverage can be obtained as compared with the case where an inorganic insulating film is used; therefore, an influence of the shape of the pixel electrodes 111 can be small. It is thus possible to prevent a short circuit in the light-emitting element 130 and unintended light emission from the light-emitting element 130. Specifically, when an organic insulating film is used as the insulating layer 121, the insulating layer 121 can be processed into, for example, a tapered shape.

In this specification and the like, a tapered shape indicates a shape in which at least part of the side surface of a structure is inclined to a substrate surface. For example, a tapered shape preferably includes a region where the angle between the inclined side surface and the substrate surface (such an angle is also referred to as a taper angle) is less than 90°.

Examples of an organic insulating material that can be used for the insulating layer 121 include an acrylic resin, an epoxy resin, a polyimide resin, a polyamide resin, a polyimide-amide resin, a polysiloxane resin, a benzocyclobutene-based resin, and a phenol resin. Examples of an inorganic insulating film usable for the insulating layer 121 include an oxide insulating film, a nitride insulating film, an oxynitride insulating film, and a nitride oxide insulating film. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

A side surface of the EL layer 113 is covered with the insulating layer 125 and the insulating layer 127. Furthermore, the insulating layer 125 and the insulating layer 127 are positioned not only between the EL layers 113 but also between the pixel electrodes 111 in the adjacent light-emitting elements 130 emitting light of the same color. Accordingly, side surfaces of the pixel electrodes 111 can be covered with the insulating layer 125 and the insulating layer 127. It is thus possible to inhibit the common layer 114 or the common electrode 115 from being in contact with the pixel electrode 111 or the EL layer 113. This can prevent a short circuit between the light-emitting elements 130 and unintended light emission from the light-emitting elements 130.

In the example illustrated in FIG. 2A and FIG. 2B, the insulating layer 121 is not provided in a region between the light-emitting elements 130 emitting light of the same color among the regions between the adjacent light-emitting elements 130. Also in that case, providing the insulating layer 125 and the insulating layer 127 can prevent a short circuit between the light-emitting elements 130 and unintended light emission from the light-emitting elements 130. Note that the insulating layer 121 may be provided in the region between the light-emitting elements 130 emitting light of the same color. This allows the EL layer 113 to have a more highly symmetric shape, for example.

The insulating layer 125 can be configured to be in contact with at least a side surface of the EL layer 113. The insulating layer 127 is provided over the insulating layer 125 so as to fill a depressed portion formed in the insulating layer 125. The insulating layer 127 can be configured to overlap with at least the side surface of the EL layer 113 with the insulating layer 125 therebetween.

Providing the insulating layer 125 and the insulating layer 127 can fill a space between adjacent island-shaped layers, such as the EL layers 113 and the pixel electrodes 111, whereby the formation surface of a layer (e.g., the common electrode 115) provided over the island-shaped layers can be less uneven and flatter. Thus, the coverage with the common electrode 115 can be increased and disconnection of the common electrode 115 can be prevented. Alternatively, it is possible to inhibit an increase in electric resistance due to local thinning of the common electrode 115 by the level difference.

In order to improve the planarity of the formation surfaces of the common layer 114 and the common electrode 115, the level of the top surface of the insulating layer 125 and the level of the top surface of the insulating layer 127 are each preferably equal to or substantially equal to the level of the top surface of the end portion of the EL layer 113. The top surface of the insulating layer 127 preferably has a flat shape and may have a protruding portion, a convex curved surface, a concave curved surface, or a depressed portion.

As described above, the insulating layer 125 can be provided in contact with the island-shaped layers and the insulating layer 127 can be provided over the insulating layer 125. Thus, peeling of the island-shaped layers can be prevented. Close contact between the insulating layer and the island-shaped layers has an effect of fixing or bonding adjacent island-shaped layers to each other. Thus, the reliability of the light-emitting element 130 can be increased. In addition, the yield of the light-emitting element 130 can be increased.

Note that one of the insulating layer 125 and the insulating layer 127 is not necessarily provided. When the insulating layer 125 having a single-layer structure using an inorganic material is formed, for example, the insulating layer 125 can be used as a protective insulating layer for the EL layer 113. This can increase the reliability of the display device 100.

The insulating layer 125 includes regions in contact with side surfaces of the EL layer 113a, the EL layer 113b, and the EL layer 113c, and functions as a protective insulating layer for the EL layer 113a, the EL layer 113b, and the EL layer 113c. Providing the insulating layer 125 can inhibit impurities (e.g., oxygen and moisture) from entering the EL layer 113a, the EL layer 113b, and the EL layer 113c through their side surfaces, resulting in a highly reliable display device.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Aluminum oxide is particularly preferable because it has high selectivity with the EL layer in etching and has a function of protecting the EL layer in forming the insulating layer 127 which is to be described later. In particular, when an inorganic insulating film such as an aluminum oxide film, a hafnium oxide film, or a silicon oxide film formed by an atomic layer deposition (ALD) method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. For example, the insulating layer 125 may have a stacked-layer structure of an aluminum oxide film formed by an ALD method and a silicon nitride film formed by a sputtering method.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The insulating layer 125 preferably has a function of a barrier insulating layer against at least one of water and oxygen. The insulating layer 125 preferably has a function of inhibiting diffusion of at least one of water and oxygen. The insulating layer 125 preferably has a function of capturing or fixing (also referred to as gettering) at least one of water and oxygen.

When the insulating layer 125 has a function of a barrier insulating layer or a gettering function, entry of impurities (typically, at least one of water and oxygen) that might diffuse into the light-emitting elements from the outside can be inhibited. With this structure, a highly reliable light-emitting element and a highly reliable display device can be provided.

The insulating layer 125 preferably has a low impurity concentration. In this case, deterioration of the EL layer due to entry of impurities from the insulating layer 125 into the EL layer can be inhibited. In addition, when having a low impurity concentration, the insulating layer 125 can have a high barrier property against at least one of water and oxygen. For example, the insulating layer 125 preferably has one of a sufficiently low hydrogen concentration and a sufficiently low carbon concentration, desirably has both of them.

For example, the hydrogen concentration in the insulating layer 125 is preferably lower than or equal to 1.0×10²² atoms/cm³, further preferably lower than or equal to 9.0×10²¹ atoms/cm³, still further preferably lower than or equal to 8.0×10²¹ atoms/cm³, and yet still further preferably lower than or equal to 6.0×10²¹ atoms/cm³. For example, as the insulating layer 125, an aluminum oxide film whose hydrogen concentration is within the above range is preferably used.

For example, the carbon concentration in the insulating layer 125 is preferably lower than or equal to 2.5×10²¹ atoms/cm³, further preferably lower than or equal to 2.0×10²¹ atoms/cm³, still further preferably lower than or equal to 1.0×10²¹ atoms/cm³, and yet still further preferably lower than or equal to 6.0×10²⁰ atoms/cm³. For example, as the insulating layer 125, an aluminum oxide film whose carbon concentration is within the above range is preferably used.

Examples of the formation method of the insulating layer 125 include a sputtering method, a chemical vapor deposition (CVD) method, a pulsed laser deposition (PLD) method, and an ALD method. The insulating layer 125 is preferably formed by an ALD method achieving good coverage.

When the substrate temperature in forming the insulating layer 125 is increased, the formed insulating layer 125, even with a small thickness, can have a low impurity concentration and a high barrier property against at least one of water and oxygen. Therefore, the substrate temperature is preferably higher than or equal to 60° C., further preferably higher than or equal to 80° C., still further preferably higher than or equal to 100° C., and yet still further preferably higher than or equal to 120° ° C. Meanwhile, the insulating layer 125 is formed after formation of an island-shaped EL layer, and thus is preferably formed at a temperature lower than the upper temperature limit of the EL layer. Therefore, the substrate temperature is preferably lower than or equal to 200° C., further preferably lower than or equal to 180° C., still further preferably lower than or equal to 160° C., yet still further preferably lower than or equal to 150° C., and yet still further preferably lower than or equal to 140° C.

Examples of indicators of the upper temperature limit include the glass transition point, the softening point, the melting point, the thermal decomposition temperature, and the 5% weight loss temperature. The upper temperature limit of the EL layer can be, for example, any of the above temperatures, preferably the lowest temperature thereof.

The insulating layer 127 provided over the insulating layer 125 has a planarization function for the depressed portion of the insulating layer 125, which is formed between adjacent light-emitting elements. In other words, the insulating layer 127 has an effect of improving the planarity of the formation surface of the common electrode 115. As the insulating layer 127, an insulating layer containing an organic material can be suitably used. For example, the insulating layer 127 can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. Moreover, the insulating layer 127 can be formed using a photosensitive resin. A photoresist may be used as the photosensitive resin. As the photosensitive resin, a positive photosensitive material or a negative photosensitive material can be used.

The insulating layer 127 may be formed using a material absorbing visible light. When the insulating layer 127 absorbs light emitted from the light-emitting element, leakage of light (stray light) from the light-emitting element to an adjacent light-emitting element through the insulating layer 127 can be inhibited. Thus, the display quality of the display device can be improved.

The protective layer 131 is preferably provided over the light-emitting element 130. Providing the protective layer 131 can improve the reliability of the light-emitting elements. The protective layer 131 may have a single-layer structure or a stacked-layer structure of two or more layers.

There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting element 130, for example; thus, the reliability of the display device can be improved.

For the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

The protective layer 131 preferably includes a nitride insulating film or a nitride oxide insulating film, and further preferably includes a nitride insulating film.

For the protective layer 131, an inorganic film containing an In—Sn oxide (also referred to as ITO), an In—Zn oxide, a Ga—Zn oxide, an Al—Zn oxide, an indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high property of transmitting visible light. For example, ITO, IGZO, and aluminum oxide are preferable because they are inorganic materials having a high property of transmitting visible light.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) into the EL layer.

Furthermore, the protective layer 131 may include an organic film. For example, the protective layer 131 may include both an organic film and an inorganic film.

The protective layer 131 may have a stacked-layer structure of two layers which are formed by different deposition methods. Specifically, the first layer of the protective layer 131 may be formed by an ALD method and the second layer of the protective layer 131 may be formed by a sputtering method.

A light-blocking layer may be provided on the surface of the substrate 120 on the resin layer 122 side. Any of a variety of optical members can be arranged on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be placed on the outer surface of the substrate 120.

For the substrate 120, glass, quartz, ceramic, sapphire, a resin, a metal, an alloy, a semiconductor, or the like can be used. The substrate on the side from which light from the light-emitting element is extracted is formed using a material that transmits the light. When the substrate 120 is formed using a flexible material, the flexibility of the display device can be increased. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display device, a highly optically isotropic substrate is preferably used as the substrate included in the display device. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of a display panel might be changed, e.g., creases are generated. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

Examples of materials that can be used for a gate, a source, and a drain of a transistor and conductive layers such as a variety of wirings and electrodes included in a display device include metals such as aluminum, titanium, chromium, nickel, copper, yttrium, zirconium, molybdenum, silver, tantalum, or tungsten, and an alloy containing any of these metals as its main component. A single layer or a stacked-layer structure of a film containing any of these materials can be used.

For a conductive material having a light-transmitting property, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) or the like may be used. Note that in the case of using the metal material or the alloy material (or the nitride thereof), the thickness is preferably set small enough to have a light-transmitting property. A stacked film of any of the above materials can be used as a conductive layer. For example, a stacked film of indium tin oxide and an alloy of silver and magnesium is preferably used for increased conductivity. These materials can also be used for conductive layers such as a variety of wirings and electrodes included in the display device, and conductive layers (e.g., a conductive layer functioning as the pixel electrode or the common electrode) included in the light-emitting element.

For an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

A conductive film that transmits visible light is used as the electrode through which light is extracted among the pixel electrode 111 and the common electrode 115. A conductive film that reflects visible light is preferably used as the electrode through which light is not extracted.

As a material that forms the pair of electrodes (the pixel electrode and the common electrode) of the light-emitting element, a metal, an alloy, an electrically conductive compound, a mixture thereof, and the like can be used as appropriate. Specific examples include an indium tin oxide (In—Sn oxide, also referred to as ITO), an In—Si—Sn oxide (also referred to as ITSO), an indium zinc oxide (In—Zn oxide), an In—W—Zn oxide, an alloy containing aluminum (an aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting element preferably employs a microcavity structure. Therefore, one of the pair of electrodes of the light-emitting element is preferably an electrode having properties of transmitting and reflecting visible light (a semi-transmissive and semi-reflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light at wavelengths greater than or equal to 400 nm and less than 750 nm) transmittance higher than or equal to 40% is preferably used in the light-emitting element. The visible light reflectance of the semi-transmissive and semi-reflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

FIG. 2C is a cross-sectional view illustrating the structure example along dashed-dotted line C1-C2 in FIG. 1, and is a cross-sectional view illustrating a structure example of the connection portion 140. In the connection portion 140, a connection electrode 123 is provided over the layer 101 including transistors, and the insulating layer 121 is provided so as to cover end portions of the connection electrode 123.

The common electrode 115 is electrically connected to the connection electrode 123 provided in the connection portion 140. Thus, the same potential is supplied to the common electrode 115 included in the light-emitting elements of the respective colors. As the connection electrode 123, a conductive layer formed using the same material in the same step as the pixel electrode 111 can be used.

Note that FIG. 2C illustrates an example where the common layer 114 is provided over the connection electrode 123 and the connection electrode 123 and the common electrode 115 are electrically connected to each other through the common layer 114. The common layer 114 is not necessarily provided in the connection portion 140. For example, FIG. 2D illustrates an example where the common layer 114 is not provided over the connection electrode 123 and the connection electrode 123 and the common electrode 115 are directly connected to each other. For example, by using a mask for specifying a film formation area (also referred to as an area mask, a rough metal mask, or the like), the common layer 114 and the common electrode 115 can be formed in different regions.

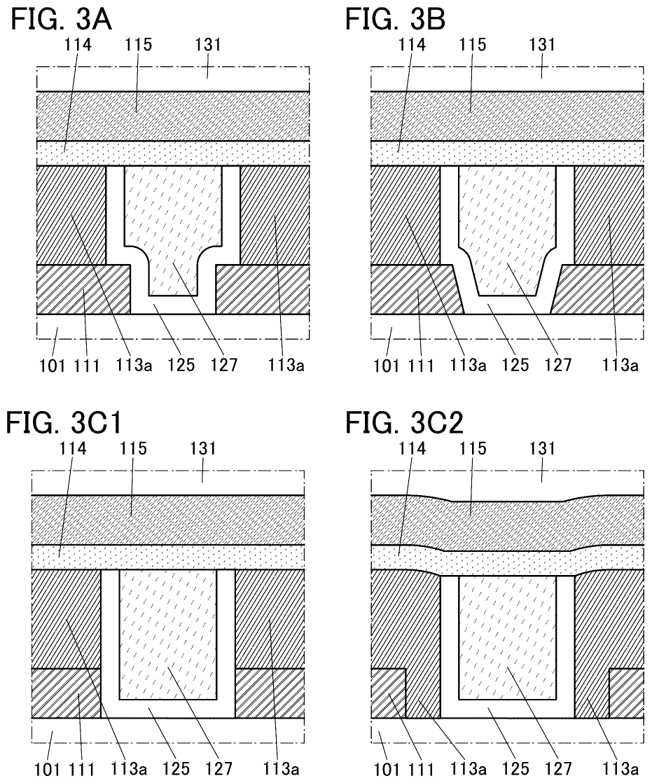

FIG. 3A is an enlarged view of a region surrounded by a dashed-dotted line in FIG. 2A. As illustrated in FIG. 3A, an end portion of the EL layer 113 can be positioned inward from an end portion of the pixel electrode 111.

FIG. 3B is a modification example of the structure illustrated in FIG. 3A; the end portion of the pixel electrode 111 has a tapered shape. A side surface of the pixel electrode 111 is preferably tapered, in which case the coverage with the insulating layer 125 provided along the side surface of the pixel electrode 111 can be improved. The tapered side surface of the pixel electrode 111 is also preferable because a material (also referred to as dust, particles, or the like) in the manufacturing process can be favorably removed by processing such as cleaning,

FIG. 3C1 and FIG. 3C2 are modification examples of the structure illustrated in FIG. 3A. FIG. 3C1 illustrates an example in which end portions of the EL layer 113 are aligned or substantially aligned with end portions of the pixel electrode 111. FIG. 3C2 illustrates an example in which the end portion of the EL layer 113 is positioned outward from the end portion of the pixel electrode 111. In FIG. 3C2, the EL layer 113 is provided so as to cover the end portion of the pixel electrode 111.

In the case where end portions are aligned or substantially aligned with each other and the case where top surface shapes are the same or substantially the same, it can be said that outlines of stacked layers at least partly overlap with each other in a top view. For example, the case of processing an upper layer and a lower layer with the use of the same mask pattern or mask patterns that are partly the same is included. However, in some cases, the outlines do not completely overlap with each other and the upper layer is positioned inward from the lower layer or the upper layer is positioned outward from the lower layer; such a case is also represented as “end portions are substantially aligned with each other” or “top surface shapes are substantially the same”.

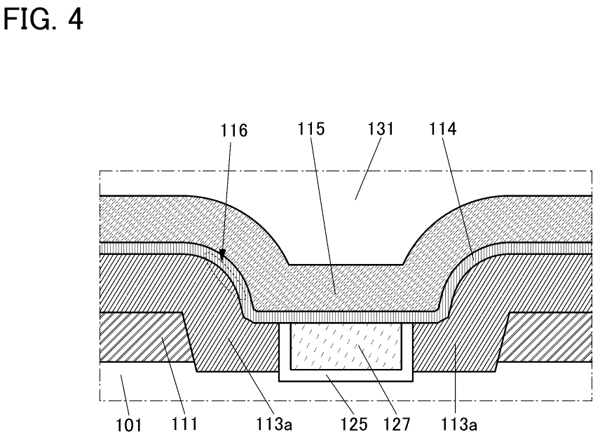

FIG. 4 is a modification example of the structure illustrated in FIG. 3A, in which the end portion of the pixel electrode 111 has a tapered shape and the end portion of the EL layer 113 is positioned outward from (i.e., is closer to the insulating layer 125 than) the end portion of the pixel electrode 111. The EL layer 113 illustrated in FIG. 4 is provided over the pixel electrode 111 and the layer 101 including transistors so as to cover the end portions of the pixel electrode 111. Since the end portion of the pixel electrode 111 has a tapered shape, the EL layer 113 includes a tapered portion 116 in a cross-sectional view. Specifically, the EL layer 113 includes the tapered portion 116 between the pixel electrode 111 and the insulating layer 125.

In the case where the EL layer 113 is provided so as to cover the end portion of the pixel electrode 111, the tapered shape of the end portion of the pixel electrode 111 can increase the coverage of the pixel electrode 111 with the EL layer 113. This inhibits disconnection and local thinning from being generated in the EL layer 113. Thus, the display device 100 can have high reliability.

FIG. 4 illustrates an example in which the lowermost surface of the insulating layer 125 is positioned below the lowermost surface of the EL layer 113a and the lowermost surface of the EL layer 113a is positioned below the lowermost surface of the pixel electrode 111. For example, the layer 101 including transistors can have a structure with a depressed portion between the EL layers 113. Although details are described later, the depressed portion is formed in formation of the EL layers 113.

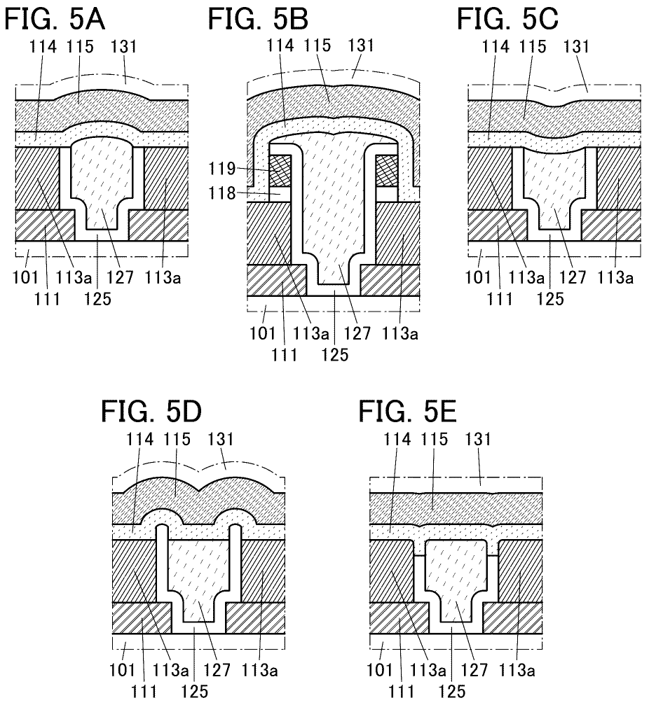

FIG. 5A to FIG. 5E are modification examples of the structure illustrated in FIG. 3A. In the structure illustrated in FIG. 5A, the level of the top surface of the insulating layer 127 is higher than that of the top surface of the EL layer 113. In that case, the top surface of the insulating layer 127 can have a shape that is bulged in the center and its vicinity, i.e., a shape with a convex curved surface, in the cross-sectional view.

In FIG. 5B, the top surface of the insulating layer 127 has a shape that is gently bulged toward the center, i.e., a convex curved surface, and has a shape that is recessed in the center and its vicinity, i.e., a concave curved surface, in the cross-sectional view. The insulating layer 127 has a region whose level is higher than that of the top surface of the EL layer 113. The display device 100 having the structure illustrated in FIG. 5B includes at least one of a sacrificial layer 118 and a sacrificial layer 119 that will be described later; the insulating layer 127 has a region whose level is higher than that of the top surface of the EL layer 113; and the region is positioned over at least one of the sacrificial layer 118 and the sacrificial layer 119.

In this specification and the like, a sacrificial layer may be referred to as a mask layer, and a sacrificial film may be referred to as a mask film.

In FIG. 5C, a top surface of the insulating layer 127 includes a region that is at a lower level than a top surface of the EL layer 113. Moreover, in the cross-sectional view, the top surface of the insulating layer 127 has a shape that is recessed in the center and its vicinity, i.e., has a concave curved surface.

In FIG. 5D, a top surface of the insulating layer 125 includes a region that is at a higher level than the top surface of the layer 113. That is, the insulating layer 125 protrudes from the formation surface of the common layer 114 and forms a projecting portion.

In formation of the insulating layer 125, for example, when the insulating layer 125 is formed so as to be level with or substantially level with the sacrificial layer, a protruding portion of the insulating layer 125 may be formed as illustrated in FIG. 5D.

In FIG. 5E, the top surface of the insulating layer 125 includes a region that is at a lower level than the top surface of the EL layer 113. That is, the insulating layer 125 forms a depressed portion on the formation surface of the common layer 114.

As described above, the insulating layer 125 and the insulating layer 127 can have a variety of shapes.

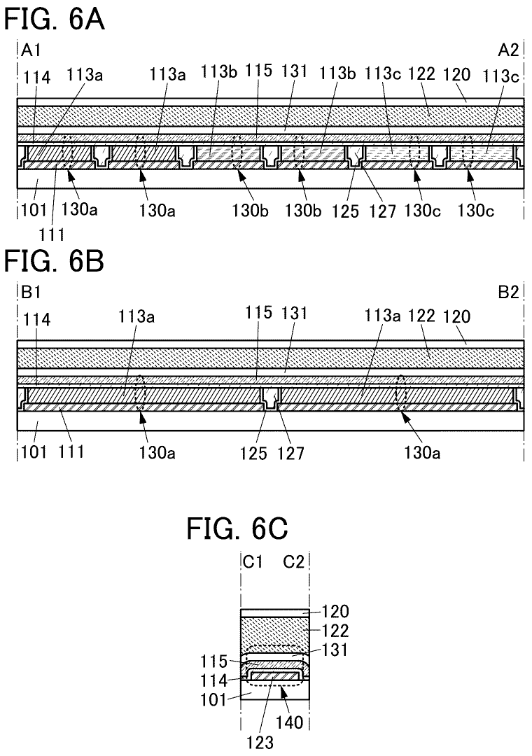

FIG. 6A, FIG. 6B, and FIG. 6C are modification examples of the structures illustrated in FIG. 2A, FIG. 2B, and FIG. 2C, respectively. The structures illustrated in FIG. 6A to FIG. 6C are different from those illustrated in FIG. 2A to FIG. 2C in that the insulating layer 121 is not provided.

The structure in which the insulating layer 121 is not provided in the display device 100 allows the light-emitting region to be extended to the end portions of the pixel electrode 111, so that the display device 100 can have a high aperture ratio.

### Manufacturing Method Example 1 of Display Device

Next, an example of a method for manufacturing the display device 100 having the structure illustrated in FIG. 1 and FIG. 2A to FIG. 2C is described. In the cross-sectional views showing the manufacturing method example, a cross-sectional view along the dashed-dotted line A1-A2 and a cross-sectional view along C1-C2 in FIG. 1 are shown side by side.

Thin films that form the display device (insulating films, semiconductor films, conductive films, and the like) can be formed by a sputtering method, a CVD method, a vacuum evaporation method, a pulsed laser deposition (PLD) method, an ALD method, or the like. Examples of a CVD method include a plasma-enhanced chemical vapor deposition (PECVD) method and a thermal CVD method. As an example of the thermal CVD method, a metal organic chemical vapor deposition (MOCVD) method can be given.

The thin films that form the display device (insulating films, semiconductor films, conductive films, and the like) can be formed by a method such as spin coating, dipping, spray coating, ink-jetting, dispensing, screen printing, offset printing, doctor blade coating, slit coating, roll coating, curtain coating, or knife coating.

Thin films that form the display device can be processed by, for example, a photolithography method. Alternatively, thin films may be processed by a nanoimprinting method, a sandblasting method, a lift-off method, or the like. Alternatively, island-shaped thin films may be directly formed by a deposition method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Alternatively, ultraviolet light, KrF laser light, ArF laser light, or the like can be used. In addition, light exposure may be performed by liquid immersion exposure technique. As the light used for the light exposure, extreme ultraviolet (EUV) light or X-rays may be used. Furthermore, instead of the light used for the light exposure, an electron beam can also be used. It is preferable to use extreme ultraviolet light, X-rays, or an electron beam because they can perform extremely fine processing. Note that a photomask is not needed when light exposure is performed by scanning with a beam such as an electron beam.

For etching of thin films, a dry etching method, a wet etching method, a sandblasting method, or the like can be used.

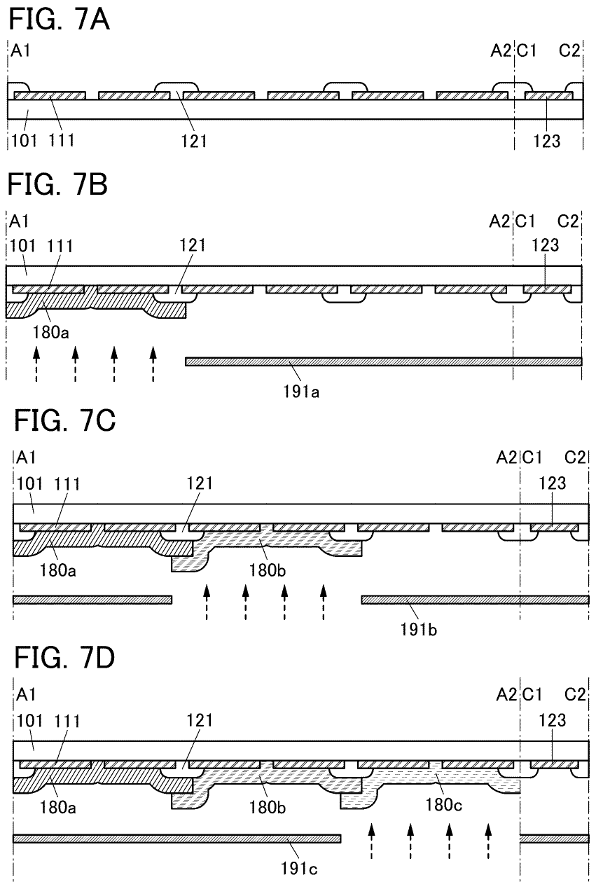

First, the pixel electrode 111 and the connection electrode 123 are formed over the layer 101 including transistors. Next, the insulating layer 121 is formed to cover end portions of the pixel electrode 111 and end portions of the connection electrode 123 (FIG. 7A). The pixel electrode 111 can be formed by, for example, a spin coating method, a spray coating method, or a screen printing method. The insulating layer 121 can be formed by a sputtering method, a vacuum evaporation method, a CVD method, or a sputtering method.

Next, an EL film 180a that is to be the EL layer 113a later is formed on the pixel electrode 111 and the layer 101 including transistors (FIG. 7B). The EL film 180a can be formed using an FMM 191a; for example, an evaporation method using the FMM 191a, specifically, a vacuum evaporation method can be used. FIG. 7B illustrates a state of what is called face-down deposition, in which deposition is performed with the substrate turned upside down so that the film formation surface is placed face down. Other drawings also illustrate the state of face-down deposition in the case where an FMM is used for deposition.

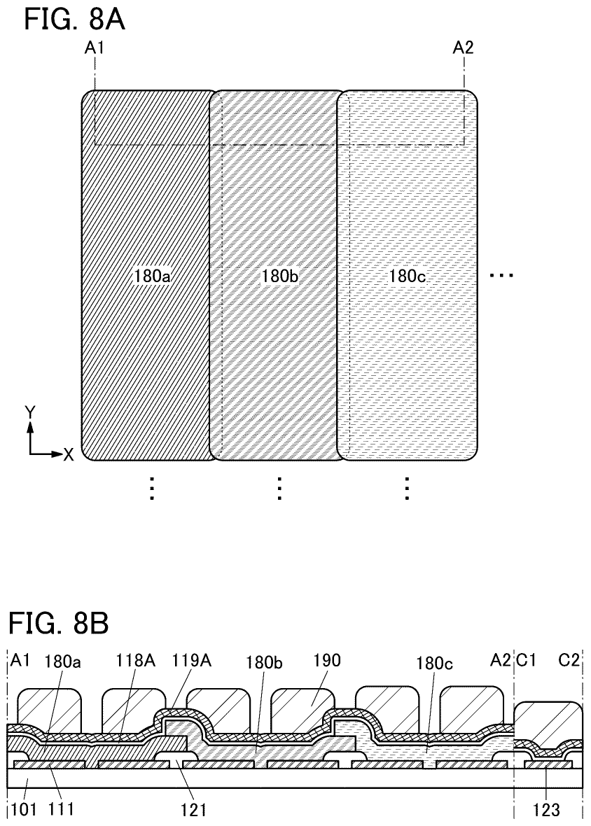

An EL film 180b that is to be the EL layer 113b later is formed on the pixel electrode 111 and the layer 101 including transistors (FIG. 7C). Furthermore, an EL film 180c that is to be the EL layer 113c later is formed on the pixel electrode 111 and the layer 101 including transistors (FIG. 7D). FIG. 8A is a top view in which the EL film 180a, the EL film 180b, and the EL film 180c are formed. In FIG. 8A, a region where two kinds of films overlap with each other is indicated by a dotted line, for example. The same applies to the other top views.

As illustrated in FIG. 7C, FIG. 7D, FIG. 8A, and the like, an end portion of the EL film 180b overlaps with the EL film 180a and an end portion of the EL film 180c overlaps with the EL film 180b. Note that the EL film 180b and the EL film 180a do not necessarily overlap with each other, and the EL film 180c and the EL film 180b do not necessarily overlap with each other.

The EL film 180b and the EL film 180c can be formed by a method similar to that for the EL film 180a. For example, the EL film 180b can be formed by an evaporation method using an FMM 191b and the EL film 180c can be formed by an evaporation method using an FMM 191c. In the case where the EL film 180 is formed using the FMM 191, providing the insulating layer 121 can prevent the FMM 191 from being in contact with the pixel electrode 111.

In the case where the EL film 180 is formed by an evaporation method, the EL film 180 can include a low molecular compound. The EL film 180 includes at least a film containing a light-emitting compound (a light-emitting film). The EL film 180 preferably includes a light-emitting film and a film functioning as a carrier-transport layer over the light-emitting film. Accordingly, the light-emitting film is inhibited from being exposed on the outermost surface in the fabrication process of the display device 100, so that damage to the light-emitting film can be reduced. Thus, the reliability of the display device 100 can be increased.

The EL film 180 can have a structure in which one or more of films functioning as a hole-injection layer, a hole-transport layer, a hole-blocking layer, an electron-blocking layer, an electron-transport layer, and an electron-injection layer are stacked. For example, the EL film 180 can have a structure in which a film functioning as a hole-injection layer, a film functioning as a hole-transport layer, the light-emitting film, and a film functioning as an electron-transport layer are stacked in this order. Alternatively, the EL film 180 can have a structure in which a film functioning as an electron-injection layer, a film functioning as an electron-transport layer, the light-emitting film, and a film functioning as a hole-transport layer are stacked in this order.

A hole-injection layer is a layer injecting holes from an anode to a hole-transport layer, and a layer containing a material with a high hole-injection property. Examples of the material with a high hole-injection property include an aromatic amine compound and a composite material containing a hole-transport material and an acceptor material (electron-accepting material).

A hole-transport layer is a layer transporting holes, which are injected from an anode by a hole-injection layer, to a light-emitting layer. The hole-transport layer is a layer containing a hole-transport material. As the hole-transport material, a substance having a hole mobility greater than or equal to 1× 10⁻⁶ cm²/Vs is preferable. Note that other substances can also be used as long as the substances have a hole-transport property higher than an electron-transport property. As the hole-transport material, a material having a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The light-emitting layer is a layer containing a light-emitting substance. The light-emitting layer can include one or more kinds of light-emitting substances. As the light-emitting substance, a substance that exhibits an emission color of blue, violet, bluish violet, green, yellowish green, yellow, orange, red, or the like is used as appropriate. As the light-emitting substance, a substance that emits near-infrared light can also be used. For example, the light-emitting layer included in the EL film 180a can contain a substance that emits red light. The light-emitting layer included in the EL film 180b can contain a substance that emits green light. The light-emitting layer included in the EL film 180c can contain a substance that emits blue light.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton; an organometallic complex (in particular, an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of a light-emitting element can be achieved at the same time.

An electron-transport layer is a layer transporting electrons, which are injected from a cathode by an electron-injection layer, to a light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as the substances have an electron-transport property higher than a hole-transport property. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

An electron-injection layer is a layer injecting electrons from a cathode to an electron-transport layer, and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate, for example. In addition, the electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, or a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

Next, over the EL film 180, the insulating layer 121, and the connection electrode 123, a sacrificial film 118A that is to be the sacrificial layer 118 and a sacrificial film 119A that is to be the sacrificial layer 119 are sequentially formed. As the sacrificial film 118A and the sacrificial film 119A, a film that is highly resistant to the processing conditions for the EL film 180, specifically, a film having high etching selectivity with the EL film 180 is used.

The sacrificial film 118A and the sacrificial film 119A can be formed by a sputtering method, an ALD method (a thermal ALD method and a PEALD method), a CVD method, or a vacuum evaporation method, for example. The sacrificial film 118A, which is formed over and in contact with the EL film 180, is preferably formed by a formation method that causes less damage to the EL film 180 than a formation method for the sacrificial film 119A. For example, the sacrificial film 118A is preferably formed by an ALD method or a vacuum evaporation method rather than a sputtering method. The sacrificial film 118A and the sacrificial film 119A are formed at a temperature lower than the upper temperature limit of the EL film 180. The typical substrate temperatures in formation of the sacrificial film 118A and the sacrificial film 119A are each lower than or equal to 200° C., preferably lower than or equal to 150° C., further preferably lower than or equal to 120° C., still further preferably lower than or equal to 100° C., and yet still further preferably lower than or equal to 80° C.

The sacrificial film 118A and the sacrificial film 119A are preferably films that can be removed by a wet etching method. Using a wet etching method can reduce damage to the EL film 180 in processing of the sacrificial film 118A and the sacrificial film 119A, compared to the case of using a dry etching method.

The sacrificial film 118A is preferably a film having high etching selectivity with the sacrificial film 119A.

In the method for manufacturing a display device of this embodiment, it is desirable that the layers (e.g., the hole-injection layer, the hole-transport layer, the light-emitting layer, and the electron-transport layer) included in the EL film not be easily processed in the step of processing the sacrificial layers, and that the sacrificial layers not be easily processed in the steps of processing the layers included in the EL film. In consideration of the above, the materials and a processing method for the sacrificial layers and processing methods for the EL layer are desirably selected.

Although this embodiment describes an example where the sacrificial layer is formed to have a two-layer structure of the sacrificial film 118A and the sacrificial film 119A, the sacrificial layer may have a single-layer structure or a stacked-layer structure of three or more layers.

As the sacrificial film 118A and the sacrificial film 119A, it is preferable to use an inorganic film such as a metal film, an alloy film, a metal oxide film, a semiconductor film, or an inorganic insulating film, for example.

For each of the sacrificial film 118A and the sacrificial film 119A, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet light for one or both of the sacrificial film 118A and the sacrificial film 119A is preferable, in which case the EL layer can be inhibited from being irradiated with ultraviolet light and deteriorating.

For each of the sacrificial film 118A and the sacrificial film 119A, a metal oxide such as In—Ga—Zn oxide can be used. As the sacrificial film 118A or the sacrificial film 119A, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Alternatively, indium tin oxide containing silicon or the like can also be used.

In addition, in place of gallium described above, the element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used. In particular, M is preferably one or more kinds selected from gallium, aluminum, and yttrium.

As each of the sacrificial film 118A and the sacrificial film 119A, any of a variety of inorganic insulating films that can be used as the protective layer 131 can be used. In particular, an oxide insulating film is preferable because its adhesion to the EL layer is higher than that of a nitride insulating film. For example, an inorganic insulating material such as aluminum oxide, hafnium oxide, or silicon oxide can be used for each of the sacrificial film 118A and the sacrificial film 119A. As the sacrificial film 118A or the sacrificial film 119A, an aluminum oxide film can be formed by an ALD method, for example. The use of an ALD method is preferable, in which case damage to a base (in particular, the EL layer) can be reduced.

For example, an inorganic insulating film (e.g., an aluminum oxide film) formed by an ALD method can be used as the sacrificial film 118A, and an inorganic film (e.g., an In—Ga—Zn oxide film, an aluminum film, or a tungsten film) formed by a sputtering method can be used as the sacrificial film 119A.

Note that the same inorganic insulating film can be used for both the sacrificial film 118A and the insulating layer 125 that is to be formed later. For example, an aluminum oxide film formed by an ALD method can be used for both the sacrificial film 118A and the insulating layer 125. For the sacrificial film 118A and the insulating layer 125, the same deposition condition may be used or different deposition conditions may be used. For example, when the sacrificial film 118A is formed under conditions similar to those of the insulating layer 125, the sacrificial film 118A can be an insulating layer having a high barrier property against at least one of water and oxygen. Meanwhile, the sacrificial film 118A is a layer almost or all of which is to be removed in a later step, and thus is preferably easy to process. Therefore, the sacrificial film 118A is preferably formed under a condition where the substrate temperature in formation is lower than that for the insulating layer 125.

A material dissolvable in a solvent that is chemically stable may be used for one or both of the sacrificial film 118A and the sacrificial film 119A. Specifically, a material that can be dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the EL film can be reduced accordingly.

The sacrificial film 118A and the sacrificial film 119A may each be formed by a wet film formation method such as spin coating, dipping, spray coating, ink-jetting, dispensing, screen printing, offset printing, a doctor knife method, slit coating, roll coating, curtain coating, or knife coating.

The sacrificial film 118A and the sacrificial film 119A may each be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

Next, a resist mask 190 is formed over the sacrificial film 119A (FIG. 8B). The resist mask 190 can be formed by application of a photosensitive resin (photoresist), light exposure, and development.

The resist mask may be formed using either a positive resist material or a negative resist material.

The resist mask 190 is provided at a position overlapping with the pixel electrode 111. One island-shaped pattern is preferably provided for one subpixel 110 as the resist mask 190.

Then, part of the sacrificial film 119A is removed using the resist mask 190, so that the sacrificial layer 119 is formed. The sacrificial layer 119 remains over the pixel electrode 111 and the connection electrode 123.

In etching the sacrificial film 119A, an etching condition with high selectivity is preferably employed so that the sacrificial film 118A is not removed by the etching. Since the EL film 180 is not exposed in processing the sacrificial film 119A, the range of choices of the processing method is wider than that for processing the sacrificial film 118A. Specifically, deterioration of the EL film 180 can be further inhibited even when a gas containing oxygen is used as an etching gas in processing the sacrificial film 119A.

After that, the resist mask 190 is removed. The resist mask 190 can be removed by ashing using oxygen plasma, for example. Alternatively, an oxygen gas and any of CF₄, C₄F₈, SF₆, CHF₃, Cl₂, H₂O, BCl₃, and a noble gas (also referred to as rare gas) such as He may be used. Alternatively, the resist mask 190 may be removed by wet etching. At this time, the sacrificial film 118A is positioned on the outermost surface and the EL film 180 is not exposed; thus, the EL film 180 can be inhibited from being damaged in the step of removing the resist mask 190. In addition, the range of choices of the method for removing the resist mask 190 can be widened.

Next, part of the sacrificial film 118A is removed using the sacrificial layer 119 as a mask (also referred to as a hard mask), so that the sacrificial layer 118 is formed.

The sacrificial film 118A and the sacrificial film 119A can be processed by a wet etching method or a dry etching method. The sacrificial film 118A and the sacrificial film 119A are preferably processed by anisotropic etching.

Using a wet etching method can reduce damage to the EL film 180 in processing the sacrificial film 118A and the sacrificial film 119A, as compared with the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example.

In the case of using a dry etching method, deterioration of the EL film 180 can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a noble gas (also referred to as a rare gas) such as He as the etching gas, for example.

For example, when an aluminum oxide film formed by an ALD method is used as the sacrificial film 118A, the sacrificial film 118A can be processed by a dry etching method using CHF₃ and He. In the case where an In—Ga—Zn oxide film formed by a sputtering method is used as the sacrificial film 119A, the sacrificial film 119A can be processed by a wet etching method using diluted phosphoric acid. Alternatively, the sacrificial film 119A may be processed by a dry etching method using CH₄ and Ar. Alternatively, the sacrificial film 119A can be processed by a wet etching method using diluted phosphoric acid. In the case where a tungsten film formed by a sputtering method is used as the sacrificial film 119A, the sacrificial film 119A can be processed by a dry etching method using SF₆, a combination of CF₄ and O₂, or a combination of CF₄, Cl₂, and O₂.

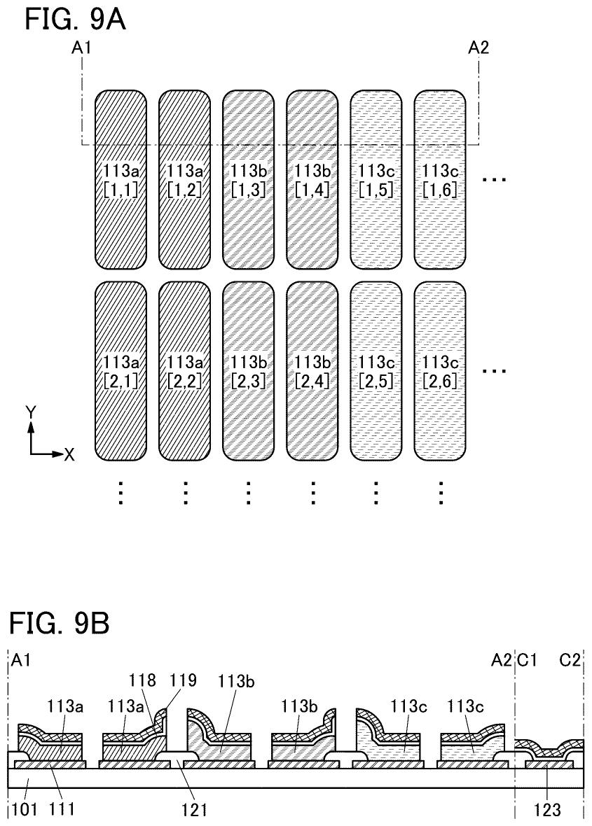

Next, the EL film 180 is processed to form the EL layer 113. For example, part of the EL film 180 is removed using the sacrificial layer 119 and the sacrificial layer 118 as hard masks, so that the EL layer 113 is formed (FIG. 9A and FIG. 9B). Specifically, the EL film 180a is removed to form the EL layer 113a, the EL film 180b is removed to form the EL layer 113b, and the EL film 180c is removed to form the EL layer 113c. Note that part of the EL film 180b remains over the EL layer 113a in some cases. Part of the EL film 180c remains over the EL layer 113b in some cases.

As illustrated in FIG. 8A and FIG. 9A, a plurality of EL layers 113 can be formed by processing the EL film 180. That is, the EL film 180 can be divided into a plurality of EL layers 113. FIG. 8A and FIG. 9A illustrate an example in which the EL film 180a is divided into the EL layers 113a of two rows and two columns, the EL film 180b is divided into the EL layers 113b of two rows and two columns, and the EL film 180c is divided into the EL layers 113c of two rows and two columns; however, one embodiment of the present invention is not limited thereto. For example, the EL film 180 may be divided into the EL layers 113 of three or more rows and divided into the EL layers 113 of three or more columns. Note that the EL film 180 does not need to be divided in both the row direction and the column direction. In that case, the EL layer 113 can have a belt-like shape.

The EL film 180 is preferably processed by anisotropic etching. Anisotropic dry etching is particularly preferable. Alternatively, wet etching may be used. Note that at the time of etching the EL film 180, for example, a top surface of the insulating layer positioned on the outermost surface of the layer 101 including transistors is etched in some cases. This might result in the formation of a depressed portion in the layer 101 including transistors.

In the case of using a dry etching method, deterioration of the EL film 180 can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the EL film 180 can be inhibited. Furthermore, a defect such as attachment of a reaction product generated at the etching can be inhibited.

In the case of using a dry etching method, it is preferable to use a gas containing at least one kind of H₂, CF₄, C+F₈, SF₆, CHF₃, Cl₂, H₂O, BCl₃, and a noble gas (also referred to as a rare gas) such as He or Ar as the etching gas, for example. Alternatively, a gas containing oxygen and at least one kind of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas.

As described above, in one embodiment of the present invention, the sacrificial layer 119 is formed in the following manner: the resist mask 190 is formed over the sacrificial film 119A; and part of the sacrificial film 119A is removed with use of the resist mask 190. After that, part of the EL film 180 is removed with use of the sacrificial layer 119 as a hard mask, so that the EL layer 113 is formed. In other words, the EL layer 113 is formed by processing the EL film 180 by a photolithography method. Note that part of the EL film 180 may be removed using the resist mask 190, and then the resist mask 190 may be removed.

As described above, a fine pattern is difficult to obtain with a vacuum evaporation method using a metal mask, for example. Hence, the resolution of the display device is difficult to increase when the EL layer 113 is to be formed without using a photolithography method. Meanwhile, in the manufacturing method of a display device of one embodiment of the present invention, for example, after the EL film 180 is formed by a vacuum evaporation method using a metal mask, the EL film 180 is divided by a photolithography method to form the EL layer 113. Accordingly, the EL layer 113 can have a fine pattern. This offers fine subpixels 110, thereby offering fine pixels 103. As a result, the display device 100 can have a substantially high resolution. In addition, the display device 100 can display a high-definition image.

When the EL film 180 is processed to form the EL layer 113, the EL films 180 with different colors can overlap with each other. This allows the EL layer 113 to have a fine pattern while a wide alignment margin of the FMM 191 is maintained.

As described above, in the case where a layer is formed by a vacuum evaporation method using a metal mask, the thickness of an end portion of the layer is made thinner than that of a center portion of the layer. Meanwhile, in the manufacturing method of a display device of one embodiment of the present invention, at least part of the end portion of the EL film 180 can be removed by processing using a photolithography method. Accordingly, the display device 100 can be a display device in which the EL layer 113 has a uniform thickness, specifically, the difference in thickness of the EL layer 113 between the center portion and the end portion is small.

Note that the EL film 180 can be processed by, for example, performing a photolithography method directly on a light-emitting film included in the EL film 180. In that case, damage to the light-emitting layer (e.g., processing damage) might be caused to significantly degrade the reliability. Thus, when the display device 100 is manufactured, the sacrificial layer 118 and the sacrificial layer 119 are formed over a film (e.g., a film functioning as a carrier-transport layer or a carrier-injection layer, more specifically an electron-transport layer, a hole-transport layer, an electron-injection layer, or a hole-injection layer) positioned above the light-emitting film, and then, the light-emitting film is processed. Thus, the display device 100 can have high reliability.

Next, an insulating film 125A that is to be the insulating layer 125 later is formed to cover the EL layer 113, the sacrificial layer 118, and the sacrificial layer 119.

As the insulating film 125A, for example, an insulating film is preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° ° C. to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

As the insulating film 125A, for example, an aluminum oxide film is preferably formed by an ALD method.

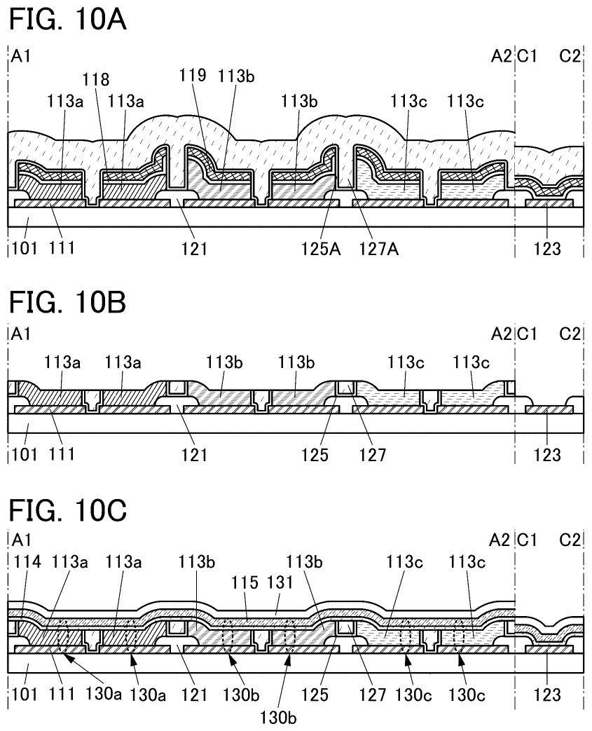

Then, an insulating film 127A is formed over the insulating film 125A (FIG. 10A). A photosensitive material, for example, a photosensitive resin, can be used for the insulating film 127A. The insulating film 127A can be formed by a wet film formation method such as spin coating, dipping, spray coating, ink-jetting, dispensing, screen printing, offset printing, a doctor knife method, slit coating, roll coating, curtain coating, or knife coating. In particular, an organic insulating film to be the insulating layer 127 is preferably formed by spin coating.

The insulating film 125A and the insulating layer 127A are preferably formed by a formation method that causes less damage to the EL layer 113. In particular, the insulating film 125A, which is formed in contact with the side surface of the EL layer 113, is preferably formed by a formation method that causes less damage to the EL layer 113 than the method for forming the insulating layer 127A. In addition, the insulating film 125A and the insulating layer 127A are each formed at a temperature lower than the upper temperature limit of the EL layer 113. Typical substrate temperatures in formation of the insulating film 125A and the insulating layer 127A are each lower than or equal to 200° C., preferably lower than or equal to 180° C., further preferably lower than or equal to 160° C., still further preferably lower than or equal to 150° C., and yet still further preferably lower than or equal to 140° C. As the insulating film 125A, for example, an aluminum oxide film can be formed by an ALD method. The use of an ALD method is preferable, in which case damage by the deposition is reduced and a film with good coverage can be deposited.

Next, the insulating film 127A is processed to form the insulating layer 127. For example, in the case where a photosensitive material is used as the insulating film 127A, exposure and development are performed on the insulating film 127A, whereby the insulating layer 127 can be formed. Note that etching may be performed so that the surface level of the insulating layer 127 is adjusted. The insulating layer 127 may be processed by ashing using oxygen plasma, for example.

Next, at least part of the insulating film 125A is removed, so that the insulating layer 125 is formed. In addition, the sacrificial layer 119 and the sacrificial layer 118 are removed (FIG. 10B). Accordingly, at least part of the top surface of the EL layer 113 and the top surface of the connection electrode 123 are exposed.

The insulating film 125A is preferably processed by a dry etching method. The insulating film 125A is preferably processed by anisotropic etching. The insulating film 125A can be processed using an etching gas that can be used for processing the sacrificial layers.

The sacrificial layers are preferably removed by a wet etching method. Thus, damage given to the EL layer 113 in removal of the sacrificial layers can be reduced as compared with the case where the sacrificial layers are removed by a dry etching method, for example.

The sacrificial layers may be removed by being dissolved in a solvent such as water or alcohol. Examples of alcohol include ethyl alcohol, methyl alcohol, isopropyl alcohol (IPA), and glycerin.

After the sacrificial layers are removed, drying treatment may be performed to remove water included in the EL layer and water adsorbed on the surface of the EL layer. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., and further preferably higher than or equal to 70° C. and lower than or equal to 120° C. Employing a reduced-pressure atmosphere is preferable, in which case drying at a lower temperature is possible.

Next, the common layer 114 is formed over the insulating layer 125, the insulating layer 127, and the EL layer 113. Then, the common electrode 115 is formed over the common layer 114.

The common layer 114 can be formed by a method such as an evaporation method (including a vacuum evaporation method), a transfer method, a printing method, an inkjet method, or a coating method. As described above, the common layer 114 can include an electron-injection layer or a hole-injection layer, for example.

The common electrode 115 can be formed by a sputtering method or a vacuum evaporation method, for example. Alternatively, a film formed by an evaporation method and a film formed by a sputtering method may be stacked.

After that, the protective layer 131 is formed over the common electrode 115 (FIG. 10C). Furthermore, the substrate 120 is bonded to the protective layer 131 with the resin layer 122, whereby the display device 100 illustrated in FIG. 2A and FIG. 2C can be fabricated.

Examples of methods for depositing the protective layer 131 include a vacuum evaporation method, a sputtering method, a CVD method, and an ALD method. The protective layer 131 may have a single-layer structure or a stacked-layer structure.

### Manufacturing Method Example 2 of Display Device

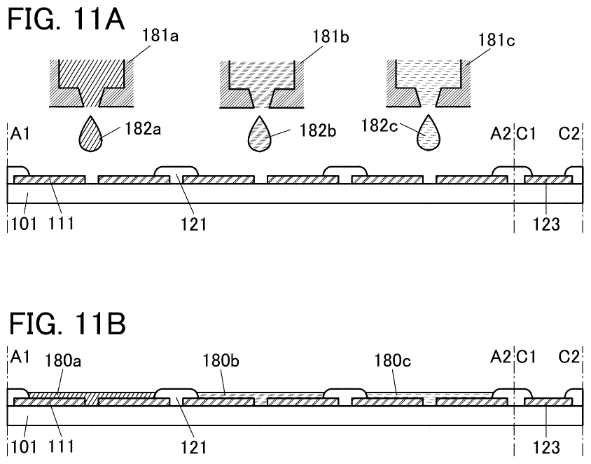

Although an example in which the EL film 180 is formed by an evaporation method is described in Manufacturing method example 1 above, one embodiment of the present invention is not limited thereto. FIG. 11A and FIG. 11B are cross-sectional views illustrating an example of forming the EL film 180 by a wet process, specifically, an inkjet method.

FIG. 11A illustrates a state where a droplet 182a that is to be the EL film 180a, a droplet 182b to be the EL film 180b, and a droplet 182c to be the EL film 180c are dropped by an inkjet method. Nozzles (a nozzle 181a, a nozzle 181b, and a nozzle 181c) of an inkjet apparatus are placed to face the layer 101 including transistors, and the droplets (the droplet 182a, the droplet 182b, and the droplet 182c) are dropped from the nozzle 181a, the nozzle 181b, and the nozzle 181c, respectively, onto the layer 101 including transistors. The droplet 182a, the droplet 182b, and the droplet 182c are preferably dropped at the same time for high productivity; alternatively, for example, a curing step may be provided between the dropping of the droplet 182a and the dropping of the droplet 182b. This might prevent the droplet dropped first from being mixed with the droplet dropped later.

The droplet 182a, the droplet 182b, and the droplet 182c each include any one kind of organic compounds used for the EL film 180. For example, in the case where a light-emitting substance used for the EL film 180 is dropped, the droplet 182a includes an organic compound, a solvent, and the like related to a red light-emitting substance. The droplet 182b includes an organic compound, a solvent, and the like related to a green light-emitting substance. The droplet 182c includes an organic compound, a solvent, and the like related to a blue light-emitting substance. Examples of the organic compound used for the EL film 180 include a hole-injection material, a hole-transport material, a light-emitting substance, and an electron-transport material. In other words, the droplet 182a, the droplet 182b, and the droplet 182c can each include any one of a hole-injection material, a hole-transport material, a light-emitting substance, and an electron-transport material. Note that the droplet 182a, the droplet 182b, and the droplet 182c may each include an electron-injection material.

The nozzle 181a, the nozzle 181b, and the nozzle 181c are moved relatively to the layer 101 including transistors, so that the EL film 180a, the EL film 180b, and the EL film 180c are formed as illustrated in FIG. 11B. Here, the EL film 180 may be subjected to a drying step, for example, whereby a solvent included in each droplet is volatilized. Heat may be added after the drying step.

At least a surface of the EL film 180 is preferably cured through a light irradiation step, for example. As the light, ultraviolet light or infrared light can be used.

### [Driving Method Example of Display Device]

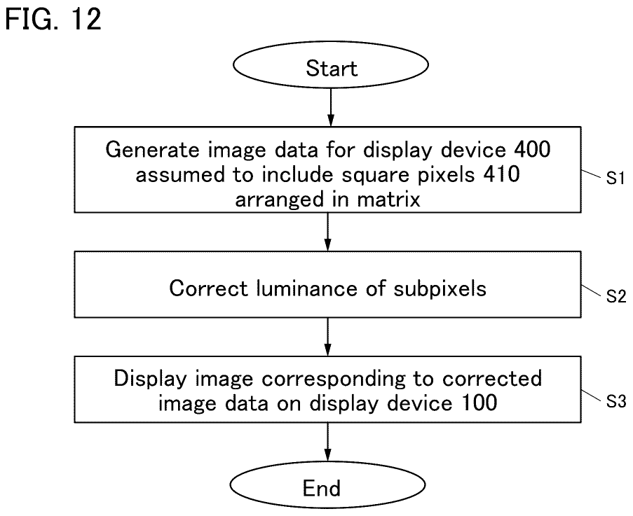

FIG. 12 is a flowchart showing an example of a method for driving the display device 100. Specifically, the flowchart shows an example in which image data generated by the display device 100 or an electronic device including the display device 100 is corrected in a processing unit or the like in the display device 100 or the electronic device, and the corrected image data is used to display an image on the display device 100.

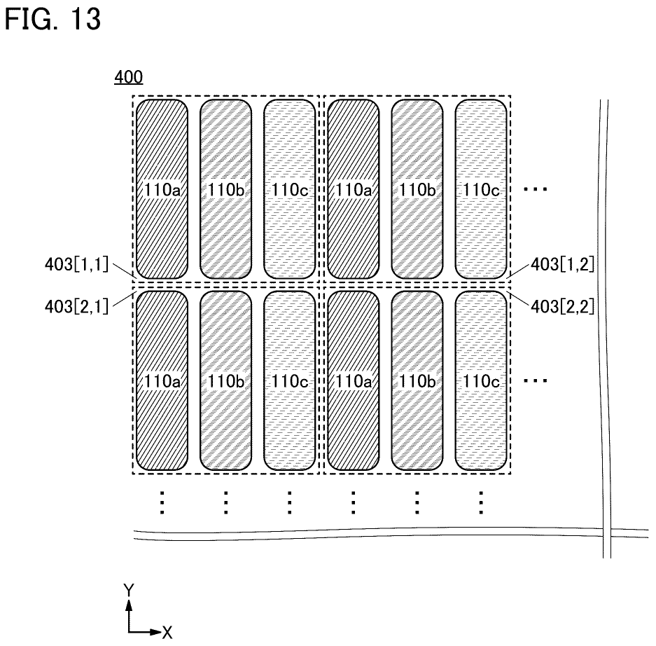

First, image data for a display device 400 illustrated in FIG. 13 is generated by the display device 100 or the electronic device including the display device 100 (Step S1). The image data has a value indicating the luminance of light emitted from each of the subpixels 110. The value is also referred to as a luminance value or a gray scale value. The luminance value can be a digital value, for example. In the case where one luminance value is represented by 8-bit digital data, for example, the luminance value can be any of 0 to 255. For example, as the luminance value is increased, the luminance of light emitted from the subpixel 110 can be increased. The following description is made under the condition where the luminance of light emitted from the subpixel 110 is increased as the luminance value is increased. However, the following description can be employed even when the luminance of light emitted from the subpixel 110 is decreased as the luminance value is increased, which is caused by, for example, reversing the magnitude relationship of luminance values.

FIG. 13 is a top view illustrating a structure example of the display device 400. The display device 400 includes square pixels 403 arranged in a matrix. In the pixel 403, the subpixel 110a, the subpixel 110b, and the subpixel 110c are provided in this order in the X direction. FIG. 13 illustrates a pixel 403[1,1], a pixel 403[1,2], a pixel 403[2,1], and a pixel 403[2,2]. In the case where the display device 100 includes the pixels 103 of m rows and n columns (m and n are each an integer greater than or equal to 1), the display device 400 is assumed to include the pixels 403 of m rows and n columns.

The display device 100 illustrated in FIG. 1 and the display device 400 illustrated in FIG. 13 are compared. Specifically, the pixel 103[1,1] and the pixel 103[1,2] included in the display device 100 and the pixel 403[1,1] and the pixel 403[1,2] included in the display device 400 are compared.

In both the display device 100 and the display device 400, the subpixel in the first row and the first column is the subpixel 110a. Meanwhile, the subpixel in the first row and the second column is the subpixel 110a in the display device 100, whereas that is the subpixel 110b in the display device 400. The subpixel in the first row and the third column is the subpixel 110b in the display device 100, whereas that is the subpixel 110c in the display device 400. The subpixel in the first row and the fourth column is the subpixel 110b in the display device 100, whereas that is the subpixel 110a in the display device 400. The subpixel in the first row and the fifth column is the subpixel 110c in the display device 100, whereas that is the subpixel 110b in the display device 400. In both the display device 100 and the display device 400, the subpixel in the first row and the sixth column is the subpixel 110c.

As described above, in terms of colors of light emitted from the subpixels, some coordinates of the display device 100 do not match those of the display device 400. Therefore, the coordinates for luminance values included in image data that is assumed to be for the display device 400 are required to be changed into the coordinates for the display device 100.

For example, the luminance value in the first row and the second column in the display device 100 is preferably changed into the luminance value in the first row and the fourth column in the display device 400. Likewise, the luminance value in the first row and the third column, the luminance value in the first row and the fourth column, and the luminance value in the first row and the fifth column in the display device 100 are preferably changed into the luminance value in the first row and the second column, the luminance value in the first row and the fifth column, and the luminance value in the first row and the third column, respectively, in the display device 400.

However, in some cases, a change occurs in an image to be displayed due to a difference in pixel layout when the coordinates for luminance values are just changed, which might cause a user of the display device 100 to feel uncomfortable. Thus, it is preferable to correct the luminance values of subpixels whose coordinates greatly change between the display device 100 and the display device 400. As a result, anti-aliasing can be performed in the display device 100, for example, which makes jaggies less noticeable. Thus, high-quality images can be displayed on the display device 100.

The subpixel 110a[1,2] in the display device 100 can be regarded as being placed at the first row and the fourth column in the display device 400. In other words, the subpixel 110a[1,2] can be regarded as moving forward the X direction by two. Furthermore, the subpixel 110b[1,3] can be regarded as being placed at the first row and the second column in the display device 400. In other words, the subpixel 110b[1,3] can be regarded as moving backward the X direction by one. Furthermore, the subpixel 110b[1,4] can be regarded as being placed at the first row and the fifth column in the display device 400. In other words, the subpixel 110b[1,4] can be regarded as moving forward the X direction by one. Furthermore, the subpixel 110c[1,5] can be regarded as being placed at the first row and the third column in the display device 400. In other words, the subpixel 110c[1,5] can be regarded as moving backward the X direction by two.

From the above, the following can be found: no shift of coordinates occurs in the subpixel 110a[1,1] and the subpixel 110c[1,6]; shift in X-coordinate by one occurs in the subpixel 110b[1,3] and the subpixel 110b[1,4]; and shift in X-coordinate by two occurs in the subpixel 110a[1,2] and the subpixel 110c[1,5]. The same applies to the subpixels 110 in the two and subsequent rows.

Next, the luminance of the subpixels 110 whose coordinates are regarded as being shifted to a certain extent or more according to the comparison between the display device 400 and the display device 100 is corrected (Step S2). Specifically, the luminance value included in the image data is corrected in the processing unit or the like included in the display device 100 or the electronic device. For example, the luminance of the subpixel 110 whose coordinates are shifted by two or more according to the comparison between the display device 400 and the display device 100 is corrected. Note that the luminance of the subpixel 110 whose coordinates are shifted by one or more may be corrected.

Note that the step of correcting the luminance of the subpixel 110 whose coordinates are regarded to be shifted to a certain extent or more (Step S2) can be called a step of controlling brightness. That is, the driving method of the display device of one embodiment of the present invention has a function of controlling the brightness of the subpixel, a function of controlling color tone of the subpixel, or a function of varying the brightness of the subpixel.

The following description is made for correction of the luminance of the subpixel 110 whose coordinates are regarded to be shifted by two according to the comparison between the display device 400 and the display device 100. That is, for example, a luminance value corresponding to light emitted from the subpixel 110a in the first row and the fourth column in the display device 400 is corrected to be a luminance value corresponding to light emitted from the subpixel 110a[1,2] in the display device 100. As another example, a luminance value corresponding to light emitted from the subpixel 110c in the first row and the third column in the display device 400 is corrected to be a luminance value corresponding to light emitted from the subpixel 110c[1,5] in the display device 100.

For example, a luminance value corresponding to light emitted from the subpixel 110a in the first row and the fourth column in the display device 400 can be corrected on the basis of the luminance value and a luminance value corresponding to light emitted from the subpixel 110a in the first row and the first column in the display device 400. In other words, on the basis of the luminance values, a luminance value corresponding to light emitted from the subpixel 110a[1,2] in the display device 100 can be generated. For example, a luminance value corresponding to light emitted from the subpixel 110c in the first row and the third column in the display device 400 can be corrected on the basis of the luminance value and a luminance value corresponding to light emitted from the subpixel 110c in the first row and the sixth column in the display device 400. In other words, on the basis of the luminance values, a luminance value corresponding to light emitted from the subpixel 110c[1,5] in the display device 100 can be generated.

As described above, the luminance value of each subpixel 110 in the display device 100 can be determined on the basis of both of the luminance value of the subpixel 110 with corresponding coordinates in the display device 400 and the luminance value of its neighboring subpixel 110 emitting the same color light.

For example, a luminance value corresponding to light emitted from the subpixel 110a[1,2] in the display device 100 can be represented by the following formula (1). Here, a₁ and b₁ each denotes a coefficient (weight). In addition, L_{400[i,j]} (i and j are each an integer greater than or equal to 1) denotes a luminance value corresponding to light emitted from the subpixel 110 in the i-th row and the j-th column in the display device 400.

$$[ Formula 1 ]$$

$${a}_{1} \cdot {L}_{400 [ 1 , 1 ]} + {b}_{1} \cdot {L}_{400 [ 1 , 4 ]} \qquad ( 1 )$$

For example, “a₁+b₁” can be 1, and a₁ can be a value greater than b₁. Note that “a₁+b₁” may be greater than 1 or smaller than 1, and a₁ may be a value smaller than b₁. In the case of the formula (1), the subpixel 110a in the first row and the fourth column in the display device 400 corresponds to the subpixel 110a[1,2] in the display device 100. A neighboring subpixel 110a of the subpixel 110a[1,2] in the display device 100 is the subpixel 110a[1,1], which corresponds to the subpixel 110a in the first row and the first column in the display device 400.

Likewise, a luminance value corresponding to light emitted from the subpixel 110c[1,5] in the display device 100 can be represented by the following formula (2).

$$[ Formula 2 ]$$

$${a}_{2} \cdot {L}_{400 [ 1 , 3 ]} + {b}_{2} \cdot {L}_{400 [ 1 , 6 ]} \qquad ( 2 )$$

For example, “a₂+b₂” can be 1, and az can be a value smaller than b₂. Note that “a₂+b₂” may be greater than 1 or smaller than 1, and az may be a value greater than b₂. In the case of the formula (2), the subpixel 110c in the first row and the third column in the display device 400 corresponds to the subpixel 110c[1,5] in the display device 100. A neighboring subpixel 110c of the subpixel 110c[1,5] in the display device 100 is the subpixel 110c[1,6], which corresponds to the subpixel 110c in the first row and the sixth column in the display device 400.

Accordingly, the weight of the luminance value of the subpixel 110 whose coordinates are greatly shifted according to the comparison between the display device 400 and the display device 100 can be made small, for example. Note that in the formula (1) and the formula (2), a constant may be added.

With the above-described method, the image data can be corrected in accordance with the pixel layout of the display device of one embodiment of the present invention.

Next, an image corresponding to the corrected image data is displayed on the display device 100 (Step S3). Specifically, the subpixel 110 in the display device 100 emits light with luminance corresponding to the luminance value included in the image data, whereby an image can be displayed on the display portion of the display device 100. The above is an example of the driving method of the display device 100.

Although the pixel 103 in the display device 100 illustrated in FIG. 1 has a shape more complicated than a square shape, the display device 100 enables high-quality images to be displayed when the display device 100 is driven with the driving method example described above.

In the case where image data is written to the subpixels 110 in the display device 100 so that an image is displayed, for example, the display device 100 may be driven with a progressive method in which image data is written to the subpixels 110 in the second row immediately after image data is written to the subpixels 110 in the first row, and image data is written to the subpixels 110 sequentially up to the last row (m-th row). Alternatively, the display device 100 may be driven with an interlaced method in which image data is not written to some rows of the subpixels 110. In the interlaced method, for example, after writing image data to the subpixels 110 in the first row, writing image data to the subpixels 110 in the second row is skipped, and image data is written to the subpixels 110 in the third row. In this manner, the image data is written sequentially up to the subpixels 110 in the (m−1)-th row. Then, after writing image data to the subpixels 110 in the second row, image data is written to the subpixels 110 in the fourth row. In this manner, the image data is written sequentially up to the subpixels 110 in the m-th row. In other words, after image data is written to the subpixels 110 in all odd-numbered rows, image data is written to the subpixels 110 in all even-numbered rows, for example. Note that when the display device 100 is driven with an interlaced method, this method is not limited to the above example where image data is written to the subpixels 110 in every other row, image data may be written to the subpixels 110 in every third or more row.

When the display device 100 is driven with a progressive method, the display device 100 can display an image with few flickers. On the other hand, when the display device 100 is driven with an interlaced method, a pseudo increase in frame frequency can be achieved to display a moving image smoothly.

Note that the driving method may be optionally switched between the progressive method and the interlaced method by a user of the display device 100. With such a structure, an image according to the user's preference can be displayed.

### Structure Example 2 of Display Device

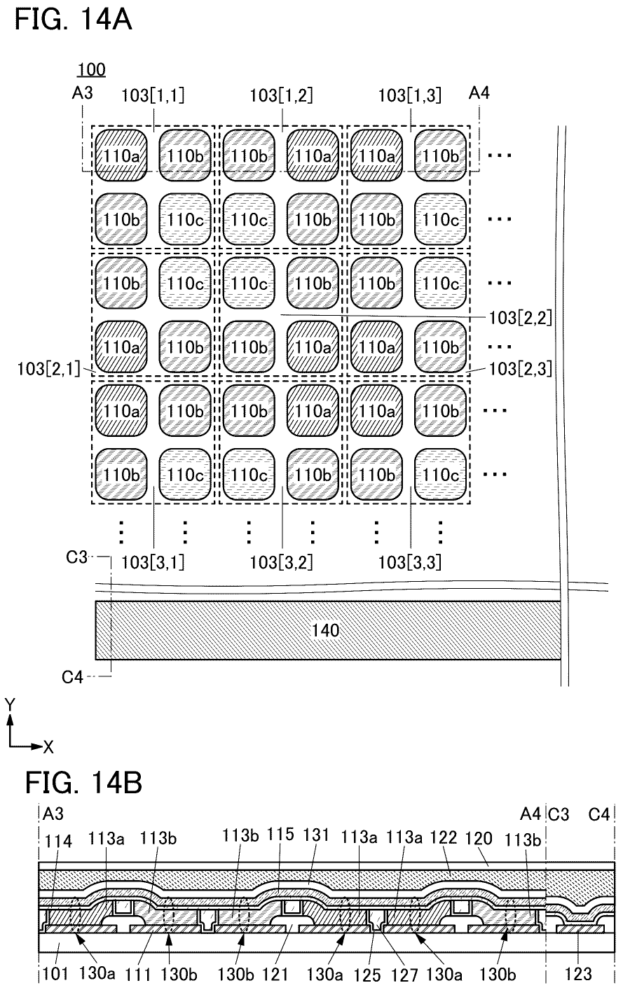

Although pixel arrangement of the display device 100 illustrated in FIG. 1 is stripe arrangement, one embodiment of the present invention is not limited thereto. FIG. 14A is a top view illustrating a structure example of the display device 100 whose pixel arrangement is Bayer arrangement.

FIG. 14A illustrates the subpixels 110 in the first row and the first column to the sixth row and the sixth column. These subpixels 110 constitute the pixels 103 of three rows and three columns. Note that FIG. 14A illustrates an example in which the pixel 103 includes two subpixels 110b.

As illustrated in FIG. 14A, for example, the subpixels 110 in the second row and the second column, in the second row and the third column, in the third row and the second column, and in the third row and the third column are each the subpixel 110c. For example, the subpixels 110 in the second row and the fourth column, in the second row and the fifth column, in the third row and the fourth column, and in the third row and the fifth column are each the subpixel 110b. For example, the subpixels 110 in the fourth row and the fourth column, in the fourth row and the fifth column, in the fifth row and the fourth column, and in the fifth row and the fifth column are each the subpixel 110a. That is, the subpixels 110 emitting light of the same color are arranged at least in two rows and two columns to be adjacent to each other. Note that the subpixels 110 emitting light of the same color may be arranged in three or more rows to be adjacent to each other or arranged in three or more columns to be adjacent to each other.

FIG. 14B is a cross-sectional view showing a structure example along the dashed-dotted line A3-A4 and along the dashed-dotted line C3-C4 in FIG. 14A. The cross-sectional view along the dashed-dotted line A3-A4 includes the light-emitting element 130a and the light-emitting element 130b, and the cross-sectional view along the dashed-dotted line C3-C4 includes the connection portion 140. The connection portion 140 illustrated in FIG. 14B has a structure similar to that of the connection portion 140 illustrated in FIG. 2C.

### Manufacturing Method Example 3 of Display Device

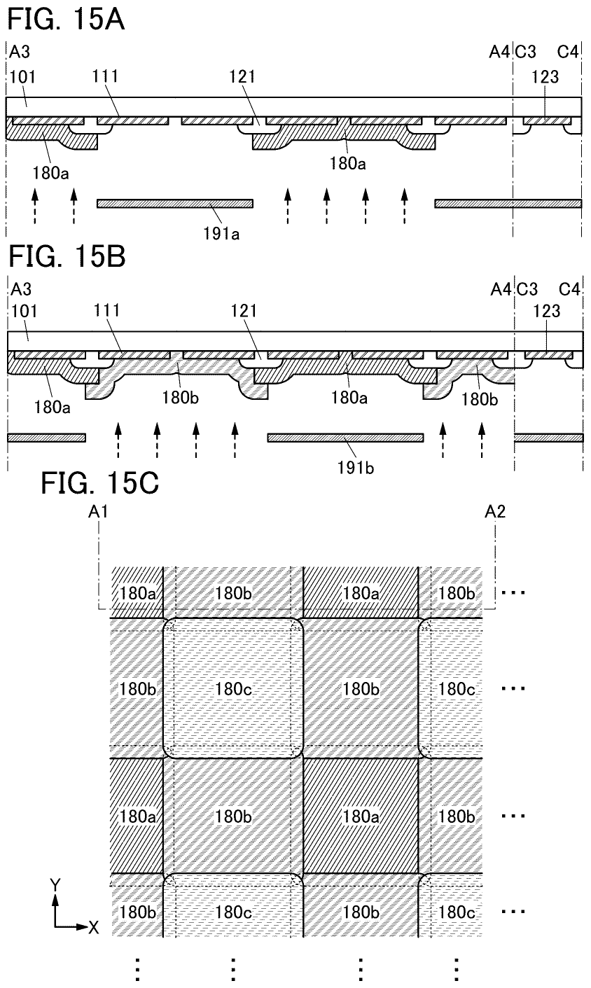

FIG. 15A and FIG. 15B are cross-sectional views illustrating an example of a method for manufacturing the display device 100 illustrated in FIG. 14B. FIG. 15A illustrates a method for forming the EL film 180a and FIG. 15B illustrates a method for forming the EL film 180b. The EL film 180a can be formed by an evaporation method using the FMM 191a as in the method illustrated in FIG. 7B. The EL film 180b can be formed by an evaporation method using the FMM 191b as in the method illustrated in FIG. 7C. Although not illustrated, the EL film 180c can be formed by an evaporation method using the FMM 191c as in the method illustrated in FIG. 7D.

FIG. 15C is a top view in which the EL film 180a, the EL film 180b, and the EL film 180c are formed. After the EL film 180a, the EL film 180b, and the EL film 180c are formed, the EL film 180a, the EL film 180b, and the EL film 180c are processed by a photolithography method as illustrated in FIG. 8B and FIG. 9B, so that the EL layer 113a, the EL layer 113b, and the EL layer 113c can be formed.

### Structure Example 3 of Display Device

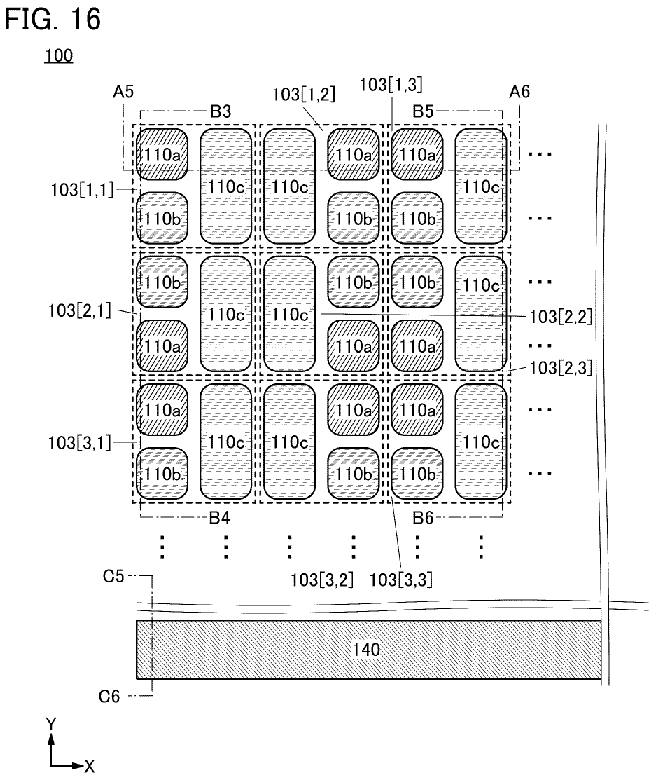

FIG. 16 is a top view illustrating a structure example of the display device 100 whose pixel arrangement is S-stripe arrangement.

FIG. 16 illustrates the pixel 103[1,1] to a pixel 103[3,3]. The subpixels 110 in the first column, the fourth column, and the fifth column are the subpixels 110a and the subpixels 110b, and the subpixels 110 in the second column, the third column, and the sixth column are the subpixels 110c.

As illustrated in FIG. 16, for example, the subpixels 110 in the second row and the fourth column, in the second row and the fifth column, in the third row and the fourth column, and in the third row and the fifth column are each the subpixel 110b. For example, the subpixels 110 in the fourth row and the fourth column, in the fourth row and the fifth column, in the fifth row and the fourth column, and in the fifth row and the fifth column are each the subpixel 110a. That is, the subpixels 110a are arranged at least in two rows and two columns to be adjacent to each other, and the subpixels 110b are arranged at least in two rows and two columns to be adjacent to each other. In addition, as described above, the subpixels 110c in the second column and the third column are the subpixels 110c; accordingly, the subpixels 110c are arranged at least in two columns to be adjacent to each other. Note that the subpixels 110a may be arranged in three or more rows to be adjacent to each other, and the subpixels 110b may be arranged in three or more rows to be adjacent to each other. Furthermore, the subpixels 110a may be arranged in three or more columns to be adjacent to each other, the subpixels 110b may be arranged in three or more columns to be adjacent to each other, and the subpixels 110c may be arranged in three or more columns to be adjacent to each other.

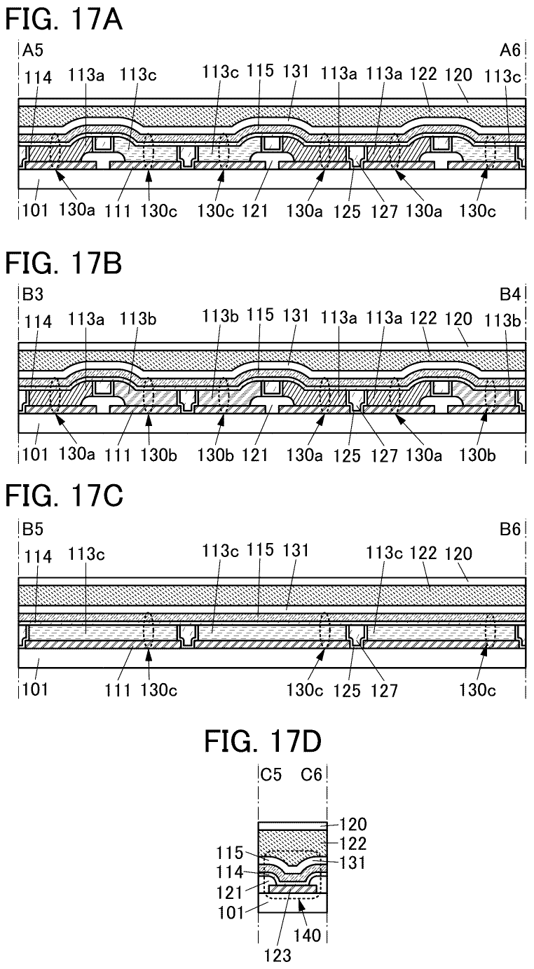

FIG. 17A is a cross-sectional view illustrating a structure example along the dashed-dotted line A5-A6 in FIG. 16. FIG. 17B is a cross-sectional view illustrating a structure example along the dashed-dotted line B3-B4 in FIG. 16. FIG. 17C is a cross-sectional view illustrating a structure example along the dashed-dotted line B5-B6 in FIG. 16. FIG. 17D is a cross-sectional view illustrating a structure example along the dashed-dotted line C5-C6 in FIG. 16. The cross-sectional view along the dashed-dotted line A5-A6 includes the light-emitting element 130a and the light-emitting element 130c, the cross-sectional view along the dashed-dotted line B3-B4 includes the light-emitting element 130a and the light-emitting element 130b, and the cross-sectional view along the dashed-dotted line B5-B6 includes the light-emitting element 130c. The connection portion 140 illustrated in FIG. 17D has a structure similar to that of the connection portion 140 illustrated in FIG. 2C.

The EL film 180a to be the EL layer 113a can be formed by an evaporation method using the FMM 191a as in the method illustrated in FIG. 7B. The EL film 180b to be the EL layer 113b can be formed by an evaporation method using the FMM 191b as in the method illustrated in FIG. 7C. The EL film 180c to be the EL layer 113c can be formed by a wet method, e.g., an inkjet method, as in the method illustrated in FIG. 11A and FIG. 11B. Note that the EL film 180c may be formed by an evaporation method using the FMM 191c as in the method illustrated in FIG. 7D.

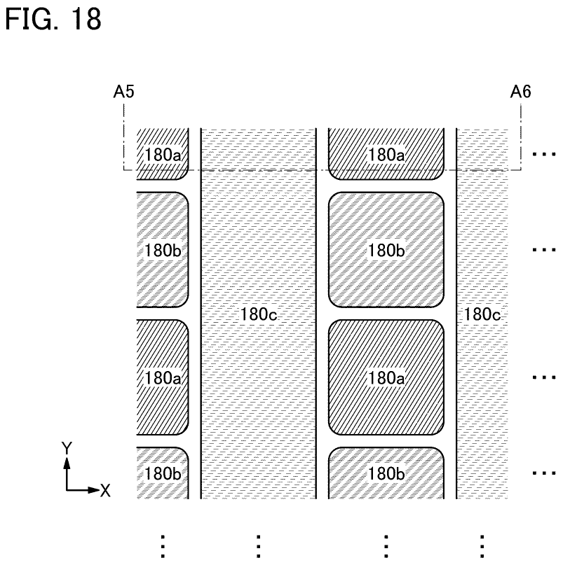

FIG. 18 is a top view in which the EL film 180a, the EL film 180b, and the EL film 180c are formed. After the EL film 180a, the EL film 180b, and the EL film 180c are formed, the EL film 180a, the EL film 180b, and the EL film 180c are processed by a photolithography method as illustrated in FIG. 8B and FIG. 9B, so that the EL layer 113a, the EL layer 113b, and the EL layer 113c can be formed.

### Structure Example 4 of Display Device

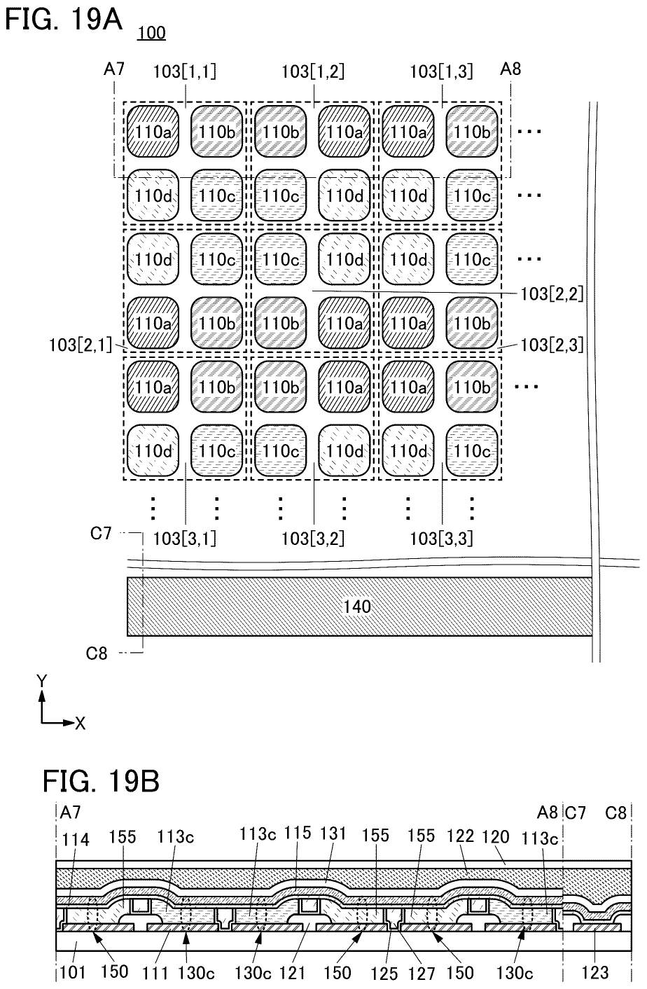

FIG. 19A is a modification example of the display device 100 illustrated in FIG. 14A, which illustrates a structure in which the pixel 103 includes a subpixel 110d besides the subpixel 110a, the subpixel 110b, and the subpixel 110c. Note that FIG. 19A illustrates a structure in which the pixel 103 includes one subpixel 110a, one subpixel 110b, one subpixel 110c, and one subpixel 110d.

The subpixel 110d includes a light-receiving element (also referred to as a light-receiving device). Thus, when the subpixel 110d is provided in the display portion of the display device 100, the display device 100 can have one or both of an image capturing function and a sensing function in addition to an image display function. Such a display portion included in the display device 100 can be used as an image sensor or a touch sensor. That is, by detecting light with the display portion, an image can be captured or an approach or touch of an object (e.g., a finger, a hand, or a pen) can be detected. Furthermore, the display device 100 with the structure illustrated in FIG. 19A can utilize the light-emitting element 130 as a light source of a sensor. Accordingly, a light-receiving portion and a light source do not need to be provided separately from the display device 100; hence, the number of components of an electronic device including the display device 100 can be reduced. For example, a fingerprint authentication device or a capacitive touch panel for scroll operation or the like does not need to be provided separately from the electronic device. Thus, the use of the display device 100 with the structure illustrated in FIG. 19A can provide an electronic device at a low manufacturing cost as compared with the case where a touch panel is provided separately from the display device 100.

In the display device 100 with the structure illustrated in FIG. 19A, when an object reflects (or scatters) light emitted from the light-emitting element 130, the light-receiving element can sense the reflected light (or the scattered light); thus, image capturing or touch sensing is possible even in a dark place.

When the light-receiving element is used as an image sensor, the display device 100 can capture an image using the light-receiving element. For example, the display device 100 with the structure illustrated in FIG. 19A can be used as a scanner.

For example, data on biological information such as a fingerprint or a palm print can be obtained with the use of the image sensor. That is, a biometric authentication sensor can be incorporated in the display device 100. When the display device 100 incorporates a biological authentication sensor, the number of components of an electronic device including the display device 100 can be reduced as compared with the case where the biological authentication sensor is provided separately from the display device 100; thus, the size and weight of the electronic device can be reduced.

When the light-receiving element is used as the touch sensor, the display device 100 with the structure illustrated in FIG. 19A can detect the approach or contact of an object with the use of the light-receiving element.

As illustrated in FIG. 19A, for example, the subpixels 110 in the second row and the second column, in the second row and the third column, in the third row and the second column, and in the third row and the third column are each the subpixel 110c. For example, the subpixels 110 in the second row and the fourth column, in the second row and the fifth column, in the third row and the fourth column, and in the third row and the fifth column are each the subpixel 110d. For example, the subpixels 110 in the fourth row and the second column, in the fourth row and the third column, in the fifth row and the second column, and in the fifth row and the third column are each the subpixel 110b. For example, the subpixels 110 in the fourth row and the fourth column, in the fourth row and the fifth column, in the fifth row and the fourth column, and in the fifth row and the fifth column are each the subpixel 110a. That is, the subpixels 110a are arranged at least in two rows and two columns to be adjacent to each other, the subpixels 110b are arranged at least in two rows and two columns to be adjacent to each other, the subpixels 110c are arranged at least in two rows and two columns to be adjacent to each other, and the subpixels 110d are arranged at least in two rows and two columns to be adjacent to each other. Note that the subpixels 110a may be arranged in three or more rows or three or more columns to be adjacent to each other, the subpixels 110b may be arranged in three or more rows or three or more columns to be adjacent to each other, the subpixels 110c may be arranged in three or more rows or three or more columns to be adjacent to each other, and the subpixels 110d may be arranged in three or more rows or three or more columns to be adjacent to each other.

FIG. 19B is a cross-sectional view showing a structure example along the dashed-dotted line A7-A8 and along the dashed-dotted line C7-C8 in FIG. 19A. The cross-sectional view along the dashed-dotted line A7-A8 includes the light-emitting element 130c and a light-receiving element 150, and the cross-sectional view along the dashed-dotted line C7-C8 includes the connection portion 140. The connection portion 140 illustrated in FIG. 19B has a structure similar to that of the connection portion 140 illustrated in FIG. 2C.

The light-receiving element 150 includes the pixel electrode 111 over the layer 101 including transistors, an island-shaped PD layer 155 over the pixel electrode 111, the common layer 114 over the PD layer 155, and the common electrode 115 over the common layer 114. The PD layer 155 includes at least an active layer. Note that the active layer is also referred to as a light-receiving layer. The PD layer 155 may include one or more of a hole-transport layer, a hole-blocking layer, an electron-blocking layer, and an electron-transport layer. For example, the PD layer 155 can have a structure in which a hole-transport layer, an active layer, and an electron-transport layer are stacked in this order. In this case, the pixel electrode 111 can function as an anode and the common electrode 115 can function as a cathode. The PD layer 155 can have a structure in which an electron-transport layer, an active layer, and a hole-transport layer are stacked in this order. In this case, the pixel electrode 111 can function as a cathode and the common electrode 115 can function as an anode.

Here, the common layer 114 has functions different in the light-emitting element 130 and the light-receiving element 150 in some cases. In this specification and the like, the name of a component is sometimes based on its function in the light-emitting element. For example, a hole-injection layer functions as a hole-injection layer in the light-emitting element and functions as a hole-transport layer in the light-receiving element. Similarly, an electron-injection layer functions as an electron-injection layer in the light-emitting element and functions as an electron-transport layer in the light-receiving element. A layer shared by the light-receiving element and the light-emitting element may have the same functions in the light-emitting element and the light-receiving element. For example, a hole-transport layer functions as a hole-transport layer in both of the light-emitting element and the light-receiving element, and an electron-transport layer functions as an electron-transport layer in both of the light-emitting element and the light-receiving element.

The active layer included in the PD layer 155 includes a semiconductor. Examples of the semiconductor include an inorganic semiconductor such as silicon and an organic semiconductor including an organic compound. This embodiment shows an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ or C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When T-electron conjugation (resonance) spreads in a plane as in benzene, an electron-donating property (donor property) usually increases; however, having a spherical shape, fullerene has a high electron-accepting property even when π-electron conjugation widely spreads therein. The high electron-accepting property efficiently causes rapid charge separation and is useful for a light-receiving element. Both C₆₀ and C₇₀ have a wide absorption band in a visible light region, and C₇₀ is particularly preferable because of having a larger π-electron conjugation system and a wider absorption band in a long wavelength region than C₆₀. Other examples of the fullerene derivative include [6,6]-phenyl-C71-butyric acid methyl ester (abbreviation: PC71BM), [6,6]-phenyl-C61-butyric d methyl ester (abbreviation: PC61BM), and 1′,1″,4′,4″-tetrahydro-di[1,4]methanonaphthaleno[1,2:2′,3′,56,60:2″,3″][5,6]fullerene-C60 (abbreviation: ICBA).

Another example of the n-type semiconductor material is a perylenetetracarboxylic derivative such as N,N′-dimethyl-3,4,9,10-perylenetetracarboxylic diimide (abbreviation: Me-PTCDI).

Another example of the n-type semiconductor material is 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material included in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Other examples of the p-type semiconductor material include a carbazole derivative, a thiophene derivative, a furan derivative, and a compound having an aromatic amine skeleton. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, and a tetracene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the active layer is preferably formed by co-evaporation of an n-type semiconductor and a p-type semiconductor. Alternatively, the active layer may be formed by stacking an n-type semiconductor and a p-type semiconductor.

The active layer may contain a mixture of three or more kinds of materials. For example, a third material may be mixed with an n-type semiconductor material and a p-type semiconductor material in order to expand the wavelength range. In that case, the third material may be a low molecular compound or a high molecular compound.

The hole-transport layer, the hole-blocking layer, the electron-blocking layer, the electron-transport layer, and the like that can be provided in the PD layer 155 can include materials similar to those for the hole-transport layer, the hole-blocking layer, the electron-blocking layer, the electron-transport layer, and the like that can be provided in the EL layer 113.

The PD layer 155 can be formed by a method similar to that for the EL layer 113. For example, a film to be the PD layer 155 is formed and processed by a photolithography method, whereby the PD layer 155 can be formed. The film to be the PD layer 155 can be formed by, for example, an evaporation method using a metal mask. Alternatively, the film to be the PD layer 155 can be formed by a wet method such as an inkjet method.

### Structure Example 5 of Display Device

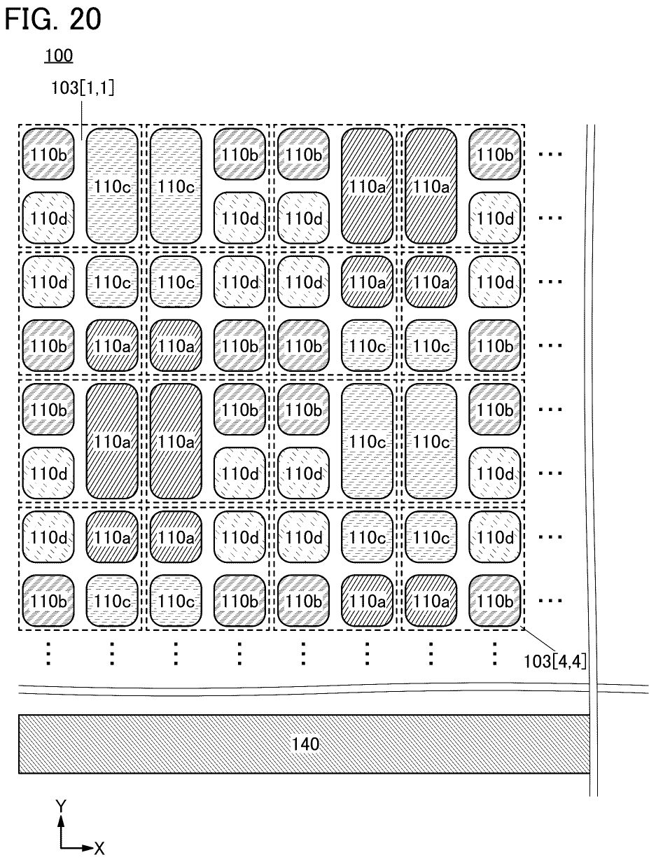

FIG. 20 is a top view illustrating a structure example of the display device 100. The display device 100 illustrated in FIG. 20 includes the subpixel 110d capable of receiving light, and has an S-stripe arrangement as the pixel arrangement. FIG. 20 illustrates the pixel 103[1,1] to a pixel 103[4,4].

As illustrated in FIG. 20, for example, the subpixels 110 in the fourth row and the second column to the seventh row and the third column are each the subpixel 110a. For example, the subpixels 110 in the fourth row and the fourth column, in the fourth row and the fifth column, in the fifth row and the fourth column, and in the fifth row and the fifth column are each the subpixel 110b. For example, the subpixels 110 in the fourth row and the sixth column to the seventh row and the seventh column are each the subpixel 110c. Furthermore, the subpixels 110 in the sixth row and the fourth column, in the sixth row and the fifth column, in the seventh row and the fourth column, and in the seventh row and the fifth column are each the subpixel 110d. That is, for example, the subpixels 110a are arranged in four rows and two columns to be adjacent to each other, and the subpixels 110c are arranged in four rows and two column to be adjacent to each other. For example, the subpixels 110b are arranged in two rows and two columns to be adjacent to each other, and the subpixels 110d are arranged in two rows and two column to be adjacent to each other. Note that the subpixels 110a may be arranged in five or more rows to be adjacent to each other and the subpixels 110c may be arranged in five or more rows to be adjacent to each other. The subpixels 110b may be arranged in two or more rows to be adjacent to each other and the subpixels 110d may be arranged in two or more rows to be adjacent to each other. Furthermore, the subpixels 110a may be arranged in three or more columns to be adjacent to each other, the subpixels 110b may be arranged in three or more columns to be adjacent to each other, the subpixels 110c may be arranged in three or more columns to be adjacent to each other, and the subpixels 110d may be arranged in three or more columns to be adjacent to each other.

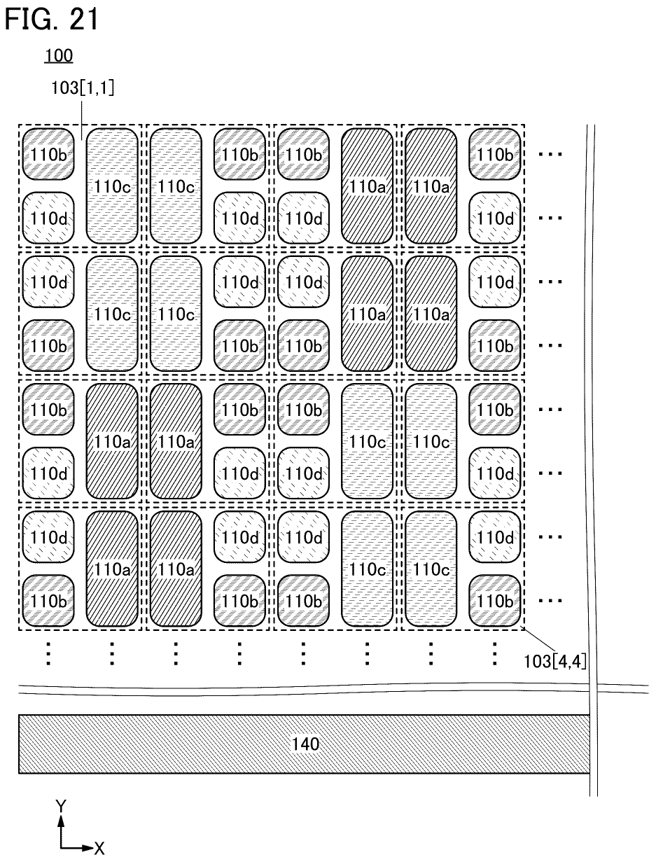

FIG. 21 is a top view illustrating a structure example of the display device 100 and is a modification example of the display device 100 illustrated in FIG. 20. The display device 100 illustrated in FIG. 20 includes the pixel 103 including three subpixels 110, and the pixel 103 including four subpixels 110. Meanwhile, in the display device 100 illustrated in FIG. 21, all the pixels 103 include three subpixels 110.

This embodiment can be combined with the other embodiments as appropriate.

### Embodiment 2

In this embodiment, a display device of one embodiment of the present invention will be described with reference to drawings.

The display device of one embodiment of the present invention can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display and a glasses-type AR device.

The display device of one embodiment of the present invention can be a high-definition display device or a large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

### Structure Example 1 of Display Module

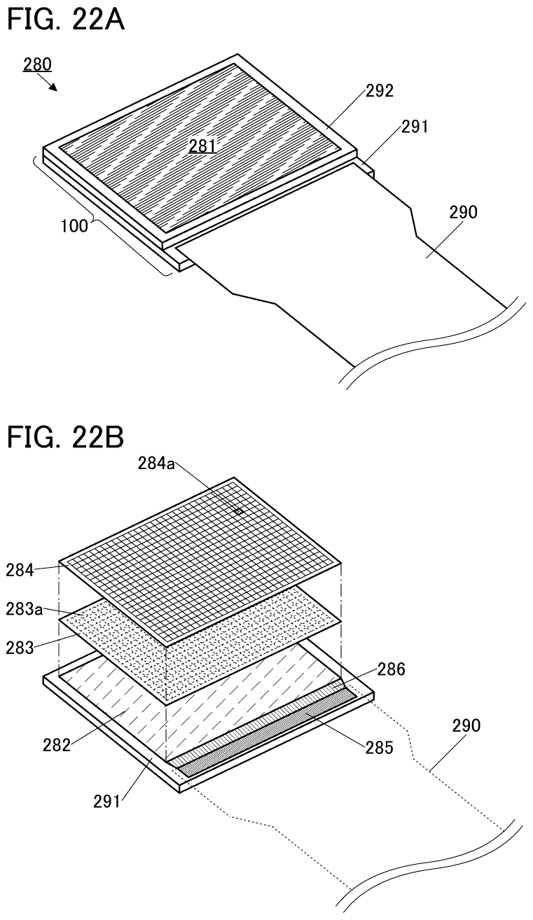

FIG. 22A is a perspective view of a display module 280. The display module 280 includes the display device 100 and an FPC 290.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 22B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 which does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. The pixel 284a includes the light-emitting element described in Embodiment 1. Note that the pixel 284a may include the light-receiving element described in Embodiment 1.

The pixel circuit portion 283 includes a plurality of pixel circuits 283a arranged periodically.

One pixel circuit 283a is a circuit that controls driving of a plurality of elements included in one pixel 284a. For example, the pixel circuit 283a can include at least one selection transistor, one current control transistor (driving transistor), and a capacitor for one light-emitting element. In this case, a gate signal is input to a gate of the selection transistor, and a video signal is input to a source of the selection transistor. With such a structure, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device, such as a wrist watch.

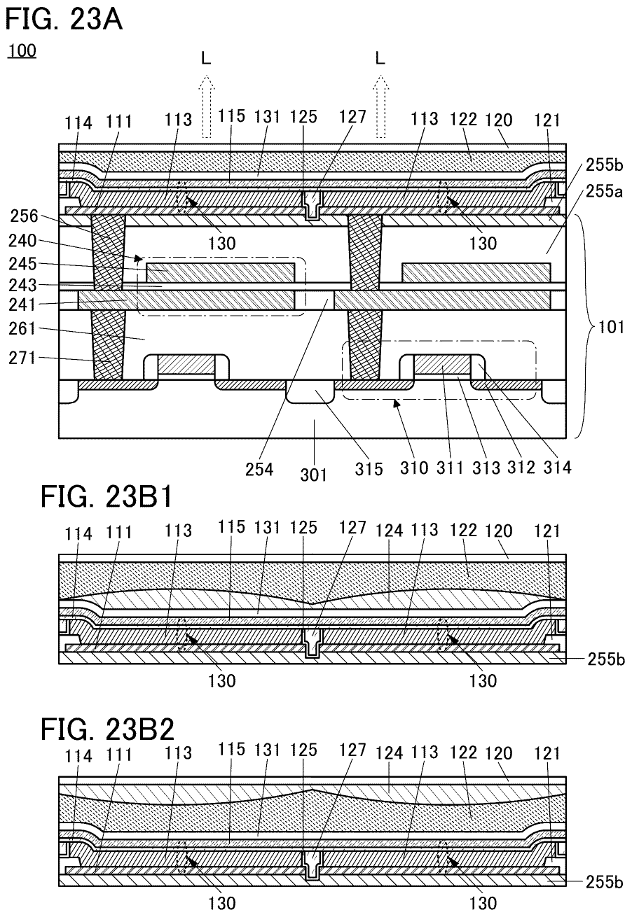

The display device 100 illustrated in FIG. 23A includes a substrate 301, the light-emitting element 130, a capacitor 240, and a transistor 310.

The substrate 301 corresponds to the substrate 291 in FIG. 22A and FIG. 22B. A stacked-layer structure including the substrate 301 and the components thereover up to an insulating layer 255b corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, and the insulating layer 255b is provided over the insulating layer 255a.

As each of the insulating layer 255a and the insulating layer 255b, a variety of inorganic insulating films such as an oxide insulating film, a nitride insulating film, an oxynitride insulating film, and a nitride oxide insulating film can be suitably used. As the insulating layer 255a, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as the insulating layer 255a and a silicon nitride film be used as the insulating layer 255b. The insulating layer 255b preferably has a function of an etching protective film. Alternatively, a nitride insulating film or a nitride oxide insulating film may be used as the insulating layer 255a, and an oxide insulating film or an oxynitride insulating film may be used as the insulating layer 255b. Although this embodiment shows an example where a depressed portion is provided in the insulating layer 255b, a depressed portion is not necessarily provided in the insulating layer 255b.

The light-emitting element 130 is provided over the insulating layer 255b. The light-emitting element 130 can have, for example, the structure illustrated in FIG. 2A. For details of the light-emitting element 130, Embodiment 1 can be referred to. In a region between adjacent light-emitting elements 130, the insulating layer 125 and the insulating layer 127 over the insulating layer 125 are provided.

The pixel electrode 111 of the light-emitting element 130 is electrically connected to one of the source and the drain of the transistor 310 through a plug 256 embedded in the insulating layer 243, the insulating layer 255a, and the insulating layer 255b, the conductive layer 241 embedded in the insulating layer 254, and the plug 271 embedded in the insulating layer 261. For example, the pixel electrode 111 includes a region in contact with the plug 256. For example, a bottom surface of the pixel electrode 111 includes a region in contact with a top surface of the plug 256. A top surface of the insulating layer 255b and the top surface of the plug 256 are level with or substantially level with each other. A variety of conductive materials can be used for the plugs.

The protective layer 131 is provided over the light-emitting element 130. The substrate 120 is bonded to the protective layer 131 with the resin layer 122. Embodiment 1 can be referred to for details of the light-emitting element 130 and the components thereover up to the substrate 120. The substrate 120 corresponds to the substrate 292 illustrated in FIG. 22A.

FIG. 23B1 and FIG. 23B2 are cross-sectional views each illustrating a structure example of layers above the insulating layer 255a illustrated in FIG. 23A, which is a modification example of the structure illustrated in FIG. 23A. In FIG. 23B1 and FIG. 23B2, a microlens array 124 is provided between the protective layer 131 and the substrate 120.

The microlens array 124 can have, for example, a plano-convex shape. In the example illustrated in FIG. 23B1, the microlens array 124 has an upward convex shape, and the microlens array 124 and the substrate 120 are bonded to each other with the resin layer 122. In the example illustrated in FIG. 23B2, the microlens array 124 has a downward convex shape, and the microlens array 124 and the protective layer 131 are bonded to each other with the resin layer 122.

When the refractive index of the resin layer 122 is lower than the refractive index of a microlens included in the microlens array 124, the microlens can condense light emitted from the EL layer 113. When light emitted from the EL layer 113 is condensed, a user of the display device 100 can look at bright images when the user sees a display surface of the display device 100 from the front of the display surface. Thus, for example, in the case where the display device 100 is used for an AR device or a VR device, the microlens array 124 is preferably provided in the display device 100 as illustrated in FIG. 23B1 or FIG. 23B2.

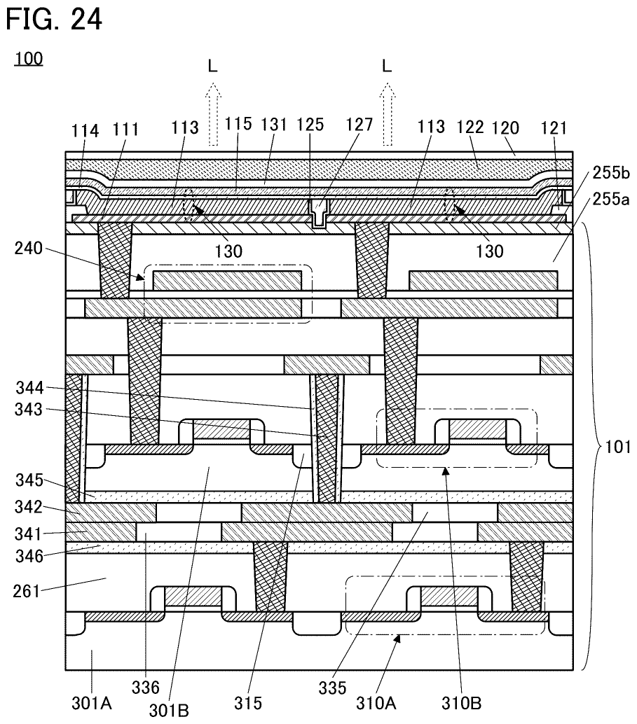

The display device 100 illustrated in FIG. 24 has a structure in which a transistor 310A and a transistor 310B in each of which a channel is formed in a semiconductor substrate are stacked. Note that in the description of the display device below, portions similar to those of the above-mentioned display device are not described in some cases.

The display device 100 has a structure in which a substrate 301B provided with the transistor 310B, the capacitor 240, and the light-emitting element 130 is bonded to a substrate 301A provided with the transistor 310A.

Here, an insulating layer 345 is preferably provided on a bottom surface of the substrate 301B. An insulating layer 346 is preferably provided over the insulating layer 261 provided over the substrate 301A. The insulating layer 345 and the insulating layer 346 are insulating layers functioning as protective layers and can inhibit diffusion of impurities into the substrate 301B and the substrate 301A. For the insulating layer 345 and the insulating layer 346, an inorganic insulating film that can be used for the protective layer 131 can be used.

The substrate 301B is provided with a plug 343 that penetrates the substrate 301B and the insulating layer 345. An insulating layer 344 is preferably provided to cover a side surface of the plug 343. The insulating layer 344 is an insulating layer functioning as a protective layer and can inhibit diffusion of impurities into the substrate 301B. For the insulating layer 344, an inorganic insulating film that can be used for the protective layer 131 can be used.

A conductive layer 342 is provided under the insulating layer 345 on the rear surface of the substrate 301B (the surface opposite to the substrate 301A). The conductive layer 342 is preferably provided to be embedded in the insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 over the substrate 301A. The conductive layer 341 is preferably provided to be embedded in the insulating layer 336. Top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting copper (Cu) pads).

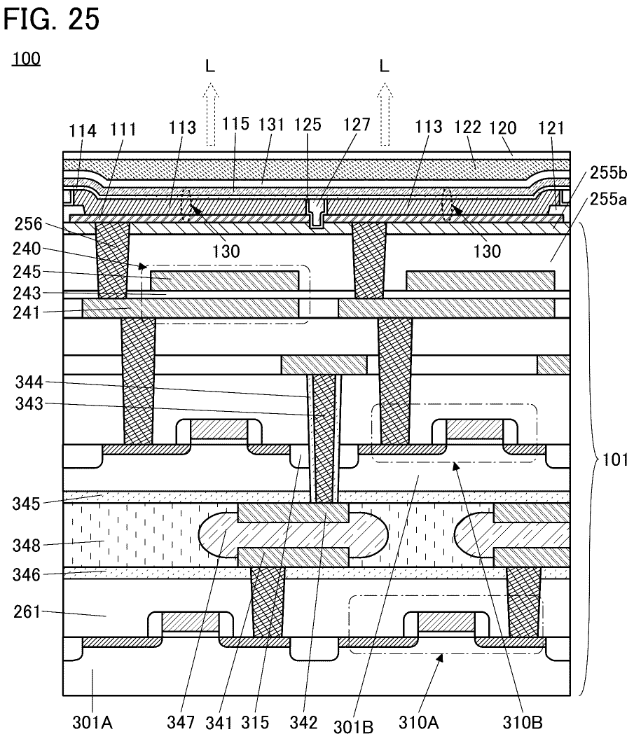

The display device 100 illustrated in FIG. 25 has a structure in which the conductive layer 341 and the conductive layer 342 are bonded to each other with a bump 347.

As illustrated in FIG. 25, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

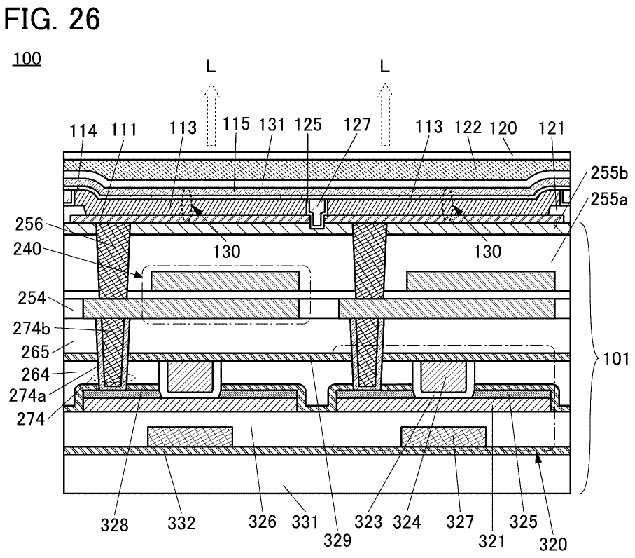

The display device 100 illustrated in FIG. 26 differs from the display device 100 illustrated in FIG. 23A mainly in a structure of a transistor.

A transistor 320 is a transistor (OS transistor) in which a metal oxide (also referred to as an oxide semiconductor) is used in a semiconductor layer in which a channel is formed.

Alternatively, a transistor (a Si transistor) using silicon in its channel formation region may be used as the transistor 320. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display device can be simplified, and component cost and mounting cost can be reduced.

An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, the power consumption of the display device can be reduced with the use of an OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting element included in the pixel circuit, the amount of current fed through the light-emitting element needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through the light-emitting element even when the current-voltage characteristics of the light-emitting element vary, for example. In other words, when the OS transistor operates in the saturation region, the source-drain current hardly changes with an increase in the source-drain voltage; hence, the emission luminance of the light-emitting element can be stable.

With the use of an OS transistor as a driving transistor included in the pixel circuit, it is possible to achieve “inhibition of black floating”, “increase in emission luminance”, “increase in gray level”, “inhibition of variation in light-emitting elements”, and the like.

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used for the semiconductor layer.

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. When the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. When the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

The transistors included in the circuit portion 282 and the pixel circuit portion 283 illustrated in FIG. 22B may have the same structure or different structures. One structure or two or more types of structures may be employed for a plurality of transistors included in the circuit portion 282. Similarly, one structure or two or more types of structures may be employed for a plurality of transistors included in the pixel circuit portion 283.

All of the transistors included in the pixel circuit portion 283 may be OS transistors or all of the transistors included in the pixel circuit portion 283 may be Si transistors; alternatively, some of the transistors included in the pixel circuit portion 283 may be OS transistors and the others may be Si transistors.

For example, when both an LTPS transistor and an OS transistor are used in the pixel circuit portion 283, the display device can have low power consumption and high drive capability. A structure where an LTPS transistor and an OS transistor are used in combination is referred to as LTPO in some cases. Note that as a further suitable example, it is preferable to use an OS transistor as a transistor functioning as a switch for controlling electrical continuity between wirings and an LTPS transistor as a transistor for controlling current.

For example, one of the transistors included in the pixel circuit portion 283 functions as a transistor for controlling a current flowing through the light-emitting element and can be referred to as a driving transistor. One of a source and a drain of the driving transistor is electrically connected to the pixel electrode of the light-emitting element. An LTPS transistor is preferably used as the driving transistor. Accordingly, the amount of current flowing through the light-emitting element can be increased in the pixel circuit.

Another transistor included in the pixel circuit portion 283 functions as a switch for controlling selection and non-selection of the pixel and can be referred to as a selection transistor. A gate of the selection transistor is electrically connected to a gate line, and one of a source and a drain thereof is electrically connected to a signal line. An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display device of one embodiment of the present invention can have all of a high aperture ratio, high resolution, high display quality, and low power consumption. The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 22A and FIG. 22B. A stacked-layer structure including the substrate 331 and components thereover up to the insulating layer 255b corresponds to the layer 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film through which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a metal oxide film having semiconductor characteristics. The pair of conductive layers 325 are provided over and in contact with the semiconductor layer 321 and function as a source electrode and a drain electrode.

An insulating layer 328 is provided to cover top and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with side surfaces of the insulating layer 264, the insulating layer 328, and the conductive layer 325 and a top surface of the semiconductor layer 321, and the conductive layer 324 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are subjected to planarization treatment so that their levels are equal to or substantially equal to each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, the insulating layer 264, and the insulating layer 328. Here, the plug 274 preferably includes a conductive layer 274a that covers a side surface of an opening in the insulating layer 265, the insulating layer 329, the insulating layer 264, and the insulating layer 328 and part of a top surface of the conductive layer 325, and a conductive layer 274b in contact with a top surface of the conductive layer 274a. In this case, a conductive material through which hydrogen and oxygen are less likely to diffuse is preferably used for the conductive layer 274a.

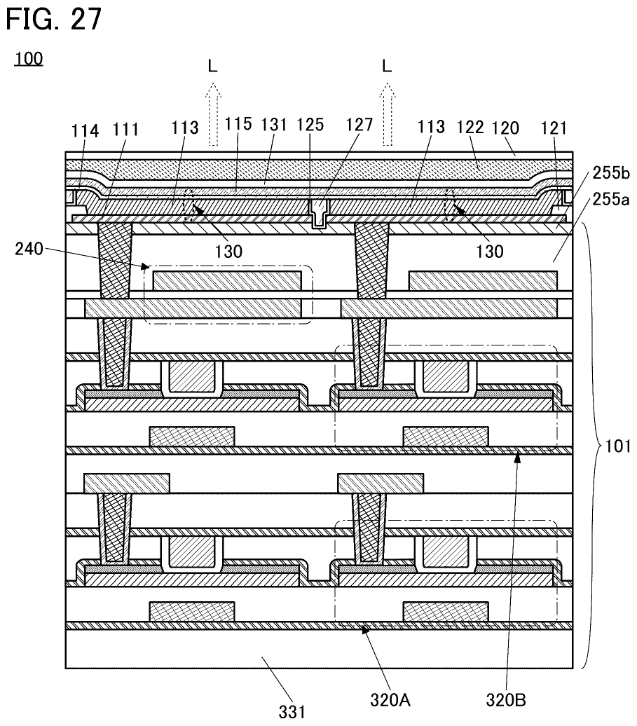

The display device 100 illustrated in FIG. 27 has a structure in which a transistor 320A and a transistor 320B each including an oxide semiconductor in a semiconductor where a channel is formed are stacked.

The description of the display device 100 illustrated in FIG. 26 can be referred to for the transistor 320A, the transistor 320B, and the components around them.

Although the structure where two transistors including an oxide semiconductor are stacked is described, the present invention is not limited thereto. For example, three or more transistors may be stacked.

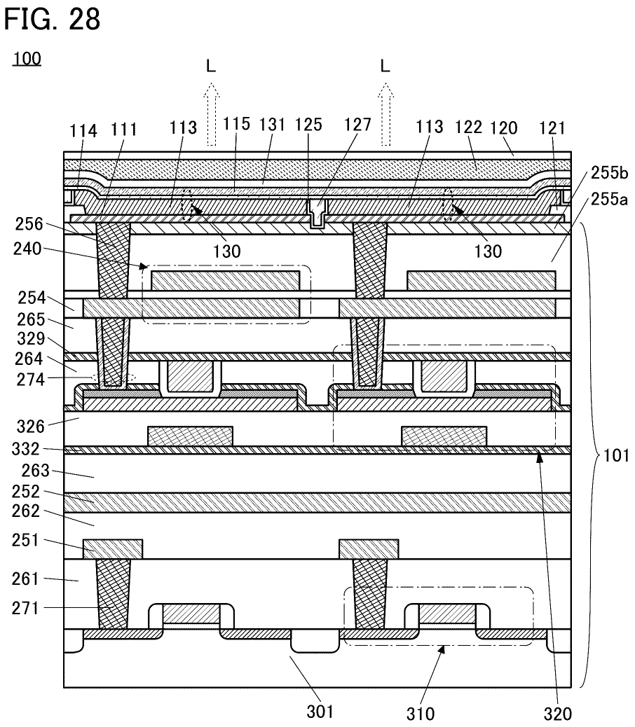

The display device 100 illustrated in FIG. 28 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can also be used as transistors included in a variety of circuits such as an arithmetic circuit and a memory circuit.

With such a structure, not only the pixel circuit but also the driver circuit can be formed directly under the light-emitting element; thus, the display device can be downsized as compared with the case where a driver circuit is provided around a display region.

### Structure Example 2 of Display Module

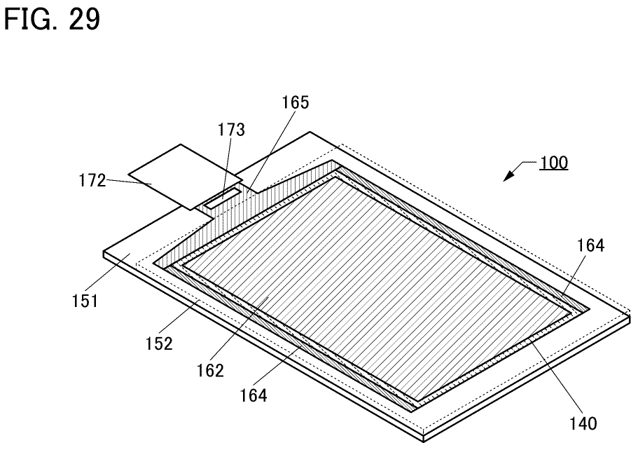

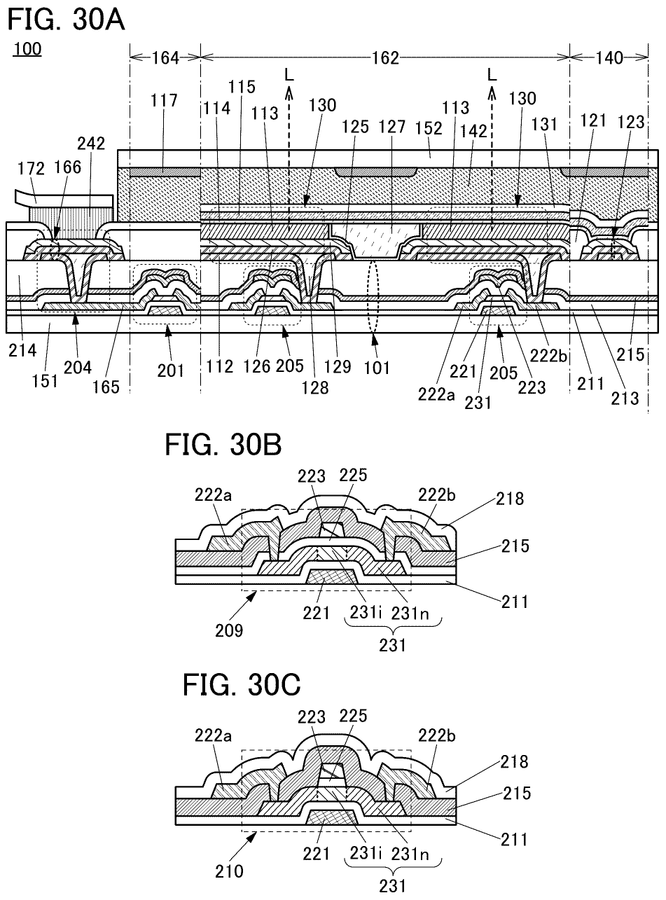

FIG. 29 is a perspective view of the display device 100, and FIG. 30A is a cross-sectional view of the display device 100.

In the display device 100, a substrate 152 and a substrate 151 are bonded to each other. In FIG. 29, the substrate 152 is denoted by a dashed line.

The display device 100 includes the display portion 162, the connection portion 140, a circuit portion 164, a wiring 165, and the like. FIG. 29 illustrates an example where an IC 173 and an FPC 172 are mounted on the display device 100. Thus, the structure illustrated in FIG. 29 can be regarded as a display module including the display device 100, the IC (integrated circuit), and the FPC.

The connection portion 140 is provided outside the display portion 162. The connection portion 140 can be provided along one or more sides of the display portion 162. The number of connection portions 140 can be one or more. FIG. 29 illustrates an example where the connection portion 140 is provided to surround the four sides of the display portion. A common electrode of a light-emitting element is electrically connected to a conductive layer in the connection portion 140, so that a potential can be supplied to the common electrode.

As the circuit portion 164, a scan line driver circuit can be used, for example.

The wiring 165 has a function of supplying a signal and power to the display portion 162 and the circuit portion 164. The signal and power are input to the wiring 165 from the outside through the FPC 172 or input to the wiring 165 from the IC 173.

FIG. 29 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display device 100 and the display module are not necessarily provided with an IC. The IC may be mounted on the FPC by a COF method or the like.

FIG. 30A illustrates an example of cross sections of part of a region including the FPC 172, part of the circuit portion 164, part of the display portion 162, part of the connection portion 140, and part of a region including an end portion of the display device 100.

The display device 100 illustrated in FIG. 30A includes a transistor 201, a transistor 205, the light-emitting elements 130, and the like between the substrate 151 and the substrate 152.

The light-emitting elements 130 can have the same structure as the structure illustrated in FIG. 2A, for example, except the structure of the pixel electrode. Embodiment 1 can be referred to for the details of the light-emitting elements 130. In a region between adjacent light-emitting elements 130, the insulating layer 125 and the insulating layer 127 over the insulating layer 125 are provided.

The light-emitting element 130 includes a conductive layer 112, a conductive layer 126 over the conductive layer 112, a conductive layer 129 over the conductive layer 126, and the EL layer 113 over the conductive layer 129. All of the conductive layer 112, the conductive layer 126, and the conductive layer 129 can be referred to as pixel electrodes, or one or two of them can be referred to as pixel electrodes.

The conductive layer 112 is connected to the conductive layer 222b included in the transistor 205 through an opening provided in the insulating layer 214, the insulating layer 215, and the insulating layer 213. An end portion of the conductive layer 126 is positioned outward from an end portion of the conductive layer 112. The end portion of the conductive layer 126 and an end portion of the conductive layer 129 are aligned or substantially aligned with each other. For example, a conductive layer functioning as a reflective electrode can be used as the conductive layer 112 and the conductive layer 126, and a conductive layer functioning as a transparent electrode can be used as the conductive layer 129.

A depressed portion is formed in the conductive layer 112 so as to cover an opening provided in the insulating layer 214, the insulating layer 215, and the insulating layer 213. A layer 128 is embedded in the depressed portion.

The layer 128 has a planarization function for the depressed portion of the conductive layer 112. The conductive layer 126 electrically connected to the conductive layer 112 is provided over the conductive layer 112 and the layer 128. Thus, a region overlapping with the depressed portion of the conductive layer 112 can also be used as a light-emitting region, increasing the aperture ratio of the pixel.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive photosensitive material or a negative photosensitive material can be used.

When a photosensitive resin is used, the layer 128 can be formed through only light-exposure and development steps, reducing the influence of dry etching, wet etching, or the like on the surface of the conductive layer 112. When the layer 128 is formed using a negative photosensitive resin, the layer 128 can sometimes be formed using the same photomask (light-exposure mask) as the photomask used for forming the opening in the insulating layer 214.

The protective layer 131 is provided over the light-emitting element 130. The protective layer 131 and the substrate 152 are bonded to each other with an adhesive layer 142. A solid sealing structure, a hollow sealing structure, or the like can be employed to seal the light-emitting element 130. In FIG. 30A, a solid sealing structure is employed in which a space between the substrate 152 and the protective layer 131 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting element 130. The space may be filled with a resin other than the frame-shaped adhesive layer 142.

The connection electrode 123 is provided over the insulating layer 214 in the connection portion 140. In the example shown here, the connection electrode 123 has a stacked-layer structure of a conductive layer obtained by processing the same conductive film as the conductive layers 112; a conductive layer obtained by processing the same conductive film as the conductive layer 126; and a conductive layer obtained by processing the same conductive film as the conductive layer 129. An end portion of the connection electrode 123 is covered with the insulating layer 121. The common layer 114 is provided over the connection electrode 123, and the common electrode 115 is provided over the common layer 114. The connection electrode 123 and the common electrode 115 are electrically connected to each other through the common layer 114. Note that the common layer 114 is not necessarily formed in the connection portion 140. In this case, the connection electrode 123 and the common electrode 115 are in direct contact with each other to be electrically connected to each other.

The display device 100 has a top-emission structure. Light L emitted from the light-emitting element 130 is emitted toward the substrate 152. For the substrate 152, a material having a high property of transmitting visible light is preferably used. The pixel electrode contains a material that reflects visible light, and a counter electrode (the common electrode 115) contains a material that transmits visible light.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same material in the same step.

An insulating layer 211, the insulating layer 213, the insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of a display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The uppermost layer of the insulating layer 214 preferably has a function of an etching protective layer. Accordingly, a depressed portion can be inhibited from being formed in the insulating layer 214 at the time of processing the conductive layer 112, the conductive layer 126, the conductive layer 129, or the like. Alternatively, a depressed portion may be formed in the insulating layer 214 at the time of processing the conductive layer 112, the conductive layer 126, the conductive layer 129, or the like.

Each of the transistor 201 and the transistor 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure where the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide. That is, a transistor including a metal oxide in its channel formation region (hereinafter, referred to as an OS transistor) is preferably used for the display device of this embodiment.

As the oxide semiconductor having crystallinity, a CAAC (c-axis-aligned crystalline)-OS, an nc (nanocrystalline)-OS, and the like can be given.

FIG. 30B and FIG. 30C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 30B illustrates an example of the transistor 209 in which the insulating layer 225 covers top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 30C, the insulating layer 225 overlaps with the channel formation region 231i of the semiconductor layer 231 and does not overlap with the low-resistance regions 231n. The structure illustrated in FIG. 30C can be formed by processing the insulating layer 225 with the conductive layer 223 as a mask, for example. In FIG. 30C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 that does not overlap with the substrate 152. In the connection portion 204, the wiring 165 is electrically connected to the FPC 172 through a conductive layer 166 and a connection layer 242. In the example shown here, the conductive layer 166 has a stacked-layer structure of a conductive film obtained by processing the same conductive film as the conductive layer 112, a conductive film obtained by processing the same conductive film as the conductive layer 126, and a conductive film obtained by processing the same conductive film as the conductive layer 129. The conductive layer 166 is exposed on a top surface of the connection portion 204. Thus, the connection portion 204 and the FPC 172 can be electrically connected to each other through the connection layer 242.

A light-blocking layer 117 is preferably provided on a surface of the substrate 152 that faces the substrate 151. The light-blocking layer 117 can be provided between adjacent light-emitting elements 130, in the connection portion 140, and in the circuit portion 164, for example. A variety of optical members can be arranged on the outer surface of the substrate 152.

The protective layer 131 covering the light-emitting element 130 can inhibit an impurity such as water from entering the light-emitting element 130, and increase the reliability of the light-emitting element 130.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

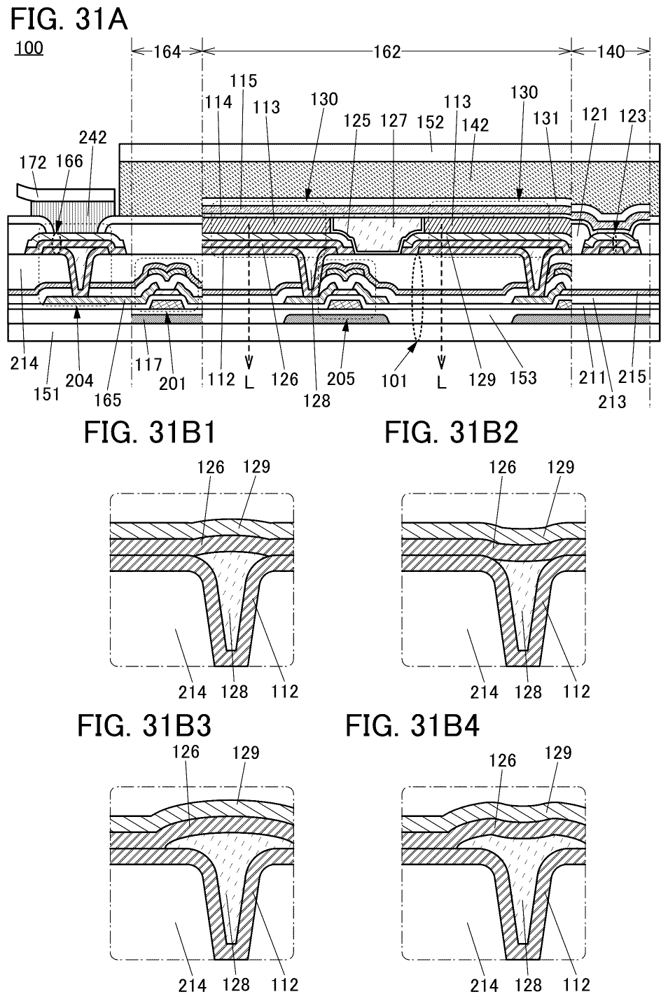

The display device 100 illustrated in FIG. 31A is different from the display device 100 illustrated in FIG. 30A mainly in having a bottom-emission structure.

Light emitted from the light-emitting element 130 is emitted toward the substrate 151. For the substrate 151, a material having a high property of transmitting visible light is preferably used. On the other hand, there is no limitation on the light-transmitting property of a material used for the substrate 152.

The light-blocking layer 117 is preferably formed between the substrate 151 and the transistor 201 and between the substrate 151 and the transistor 205. FIG. 31A illustrates an example where the light-blocking layer 117 is provided over the substrate 151, an insulating layer 153 is provided over the light-blocking layer 117, and the transistor 201, the transistor 205, and the like are provided over the insulating layer 153.

A material having a high property of transmitting visible light is used for each of the conductive layer 112, the conductive layer 126, and the conductive layer 129. A material reflecting visible light is preferably used for the common electrode 115.

In FIG. 30A and FIG. 31A, a top surface of the layer 128 and a top surface of the conductive layer 112 are substantially aligned with each other; however, one embodiment of the present invention is not limited thereto. FIG. 31B1 to FIG. 31B4 are enlarged views of a region including the layer 128 and its periphery, and show variation examples of the structures in FIG. 30A and FIG. 31A.

FIG. 31B1 illustrates an example in which the level of the top surface of the layer 128 is higher than that of the top surface of the conductive layer 112. In the example illustrated in FIG. 31B1, the top surface of the layer 128 has a convex shape that is gently bulged toward the center.

FIG. 31B2 illustrates an example in which the level of the top surface of the layer 128 is lower than that of the top surface of the conductive layer 112. In the example illustrated in FIG. 31B2, the top surface of the layer 128 has a convex shape that is gently bulged toward the center.

FIG. 31B3 illustrates an example in which the level of the top surface of the layer 128 is higher than that of the top surface of the conductive layer 112 and the upper portion of the layer 128 is formed to be wider than the depressed portion of the conductive layer 112. In the example illustrated in FIG. 31B3, part of the layer 128 may be formed to cover part of a substantially flat region of the conductive layer 112.

FIG. 31B4 illustrates an example in which a recessed portion is also formed on part of the top surface of the layer 128 in the example illustrated in FIG. 31B3. The depressed portion has a shape that is gently recessed toward the center.

This embodiment can be combined with the other embodiments as appropriate.

### Embodiment 3

In this embodiment, light-emitting elements that can be used in a display device of one embodiment of the present invention will be described.

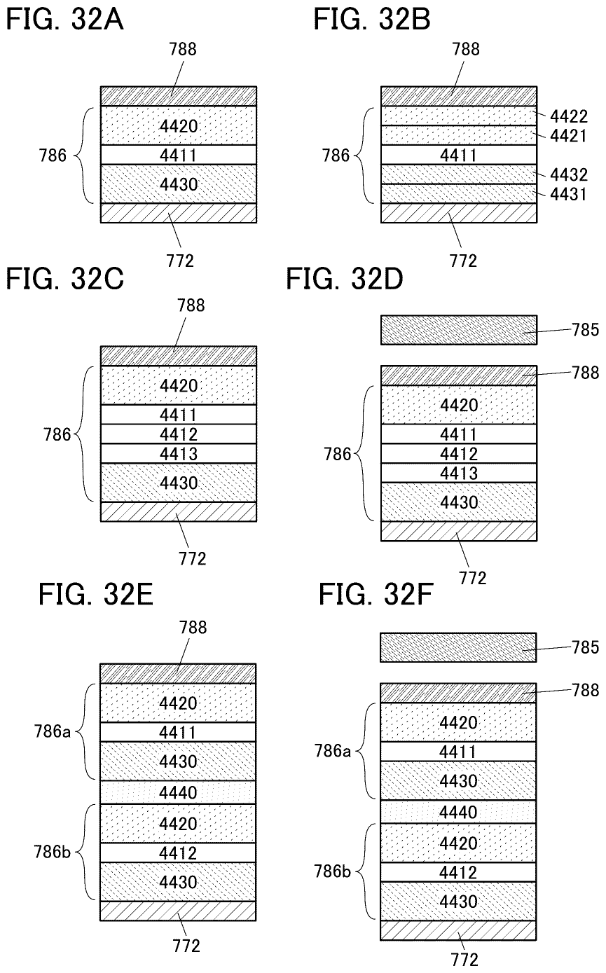

As illustrated in FIG. 32A, a light-emitting element includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance having a high electron-injection property (an electron-injection layer) and a layer containing a substance having a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can serve as a single light-emitting unit, and the structure in FIG. 32A is referred to as a single structure in this specification.

FIG. 32B illustrates a modification example of the EL layer 786 included in the light-emitting element illustrated in FIG. 32A. Specifically, the light-emitting element illustrated in FIG. 32B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. For example, when the lower electrode 772 functions as an anode and the upper electrode 788 functions as a cathode, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 functions as a cathode and the upper electrode 788 functions as an anode, the layer 4431 functions as an electron-injection layer, the layer 4432 functions as an electron-transport layer, the layer 4421 functions as a hole-transport layer, and the layer 4422 functions as the hole-injection layer. With such a layered structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 32C and FIG. 32D is a variation of the single structure.

A structure in which a plurality of light-emitting units (an EL layer 786a and an EL layer 786b) are connected in series with a charge-generation layer 4440 therebetween as illustrated in FIG. 32E and FIG. 32F is referred to as a tandem structure in this specification. Note that a tandem structure may be referred to as a stack structure. Note that the tandem structure enables a light-emitting element to emit light at high luminance.

In FIG. 32C and FIG. 32D, light-emitting substances that emit light of the same color, or moreover, the same substance may be used for the light-emitting layer 4411, the light-emitting layer 4412, and the light-emitting layer 4413. For example, a light-emitting substance that emits blue light may be used for the light-emitting layer 4411, the light-emitting layer 4412, and the light-emitting layer 4413. A color conversion layer may be provided as a layer 785 illustrated in FIG. 32D.

Alternatively, light-emitting substances that emit light of different colors may be used for the light-emitting layer 4411, the light-emitting layer 4412, and the light-emitting layer 4413. White light can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 32D. When white light passes through a color filter, light of a desired color can be obtained.

In FIG. 32E and FIG. 32F, light-emitting substances that emit light of the same color, or moreover, the same light-emitting substance may be used for the light-emitting layer 4411 and the light-emitting layer 4412. Alternatively, light-emitting substances that emit light of different colors may be used for the light-emitting layer 4411 and the light-emitting layer 4412. White light can be obtained when the light-emitting layer 4411 and the light-emitting layer 4412 emit light of complementary colors. FIG. 32F illustrates an example in which the layer 785 is further provided. One or both of a color conversion layer and a color filter (coloring layer) can be used as the layer 785.

In FIG. 32C, FIG. 32D, FIG. 32E, and FIG. 32F, the layer 4420 and the layer 4430 may each have a stacked-layer structure of two or more layers as in FIG. 32B.

A structure in which light-emitting elements that emit light of different colors (e.g., blue (B), green (G), and red (R)) are separately formed is referred to as an SBS (Side By Side) structure in some cases.

The emission color of the light-emitting element can be red, green, blue, cyan, magenta, yellow, white, or the like depending on the material that constitutes the EL layer 786. Furthermore, the color purity can be further increased when the light-emitting element has a microcavity structure.

The light-emitting element that emits white light preferably contains two or more kinds of light-emitting substances in the light-emitting layer. To obtain white light emission, two or more light-emitting substances are selected such that their emission colors are complementary colors. For example, when the emission color of a first light-emitting layer and the emission color of a second light-emitting layer have a relationship of complementary colors, it is possible to obtain a light-emitting element which emits white light as a whole. The same applies to a light-emitting element including three or more light-emitting layers.

The light-emitting layer preferably contains two or more kinds of light-emitting substances that emit light of R (red), G (green), B (blue), Y (yellow), O (orange), and the like.

This embodiment can be combined with the other embodiments as appropriate.

### Embodiment 4

In this embodiment, electronic devices of one embodiment of the present invention will be described with reference to drawings.

The display device of one embodiment of the present invention can have substantially high resolution, and thus can be used for an electronic device having a relatively small display portion. Examples of such an electronic device include a watch-type or a bracelet-type information terminal device (wearable device), and a wearable device worn on a head, such as a device for VR such as a head mounted display, a glasses-type device for AR, and a device for MR.

In addition, a high-definition image can be displayed on the display device of one embodiment of the present invention. Thus, the display device of one embodiment of the present invention can be favorably used for an electronic device having a relatively large screen, such as a television device, a desktop or laptop personal computer, a monitor of a computer or the like, digital signage, and a large game machine like a pachinko machine. The display device of one embodiment of the present invention can also be used for an electronic device such as a digital camera, a digital video camera, a digital photo frame, a mobile phone, a portable game console, a portable information terminal, and an audio reproducing device

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680× 4320). In particular, the definition is preferably 4K, 8K, or higher. Furthermore, the pixel density (resolution) of the display device of one embodiment of the present invention is preferably higher than or equal to 100 ppi, higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With the use of such a display device with one or more of high definition and high resolution, the electronic device can have higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

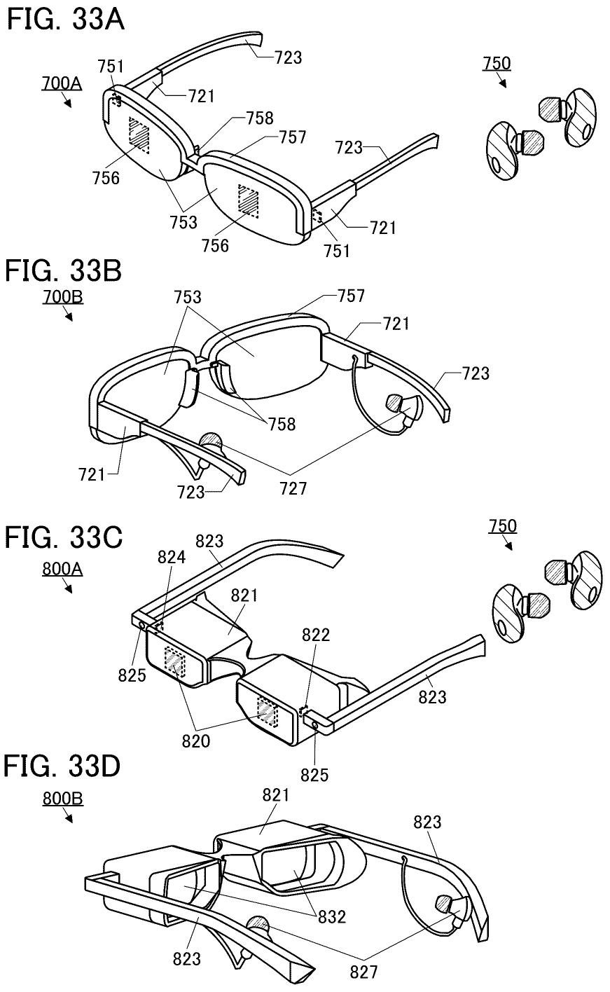

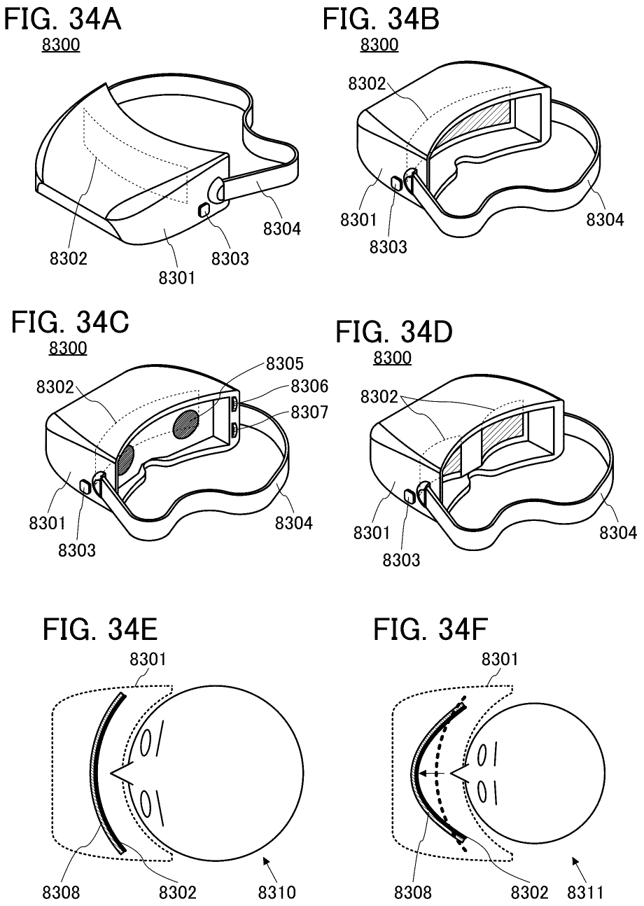

Examples of head-mounted wearable devices are described with reference to FIG. 33A to FIG. 33D, and FIG. 34A to FIG. 34F. These wearable devices have one or both of a function of displaying AR contents and a function of displaying VR contents. Note that these wearable devices may have a function of displaying SR or MR contents, in addition to AR and VR contents. The electronic device having a function of displaying contents of AR, VR, SR, MR, or the like enables the user to reach a higher level of immersion.

An electronic device 700A illustrated in FIG. 33A and an electronic device 700B illustrated in FIG. 33B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panel 751. Thus, the electronic device can display an image that appears in extremely high resolution.

The electronic device 700A and the electronic device 700B can each project an image displayed on the display panel 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display region 756.

The communication portion includes a wireless communication device, and a video signal and the like can be supplied by the wireless communication device. Note that instead of or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module. An electronic device 800A illustrated in FIG. 33C and an electronic device 800B illustrated in FIG. 33D each include a pair of display portions 820, a housing 821, a communication portion 822, a pair of wearing portions 823, a control portion 824, a pair of image capturing portions 825, and a pair of lenses 832.

A display device of one embodiment of the present invention can be used in the display portions 820. Thus, the electronic device can display an image that appears in extremely high resolution. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 33C or the like illustrates an example in which the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 33A has a function of transmitting information to the earphones 750 with the wireless communication function. As another example, the electronic device 800A illustrated in FIG. 33C has a function of transmitting information to the earphones 750 with the wireless communication function.

The electronic device may include an earphone portion. The electronic device 700B illustrated in FIG. 33B includes earphone portions 727. For example, a structure in which the earphone portions 727 and the control portion are connected to each other by wire may be employed. Part of a wiring that connects the earphone portions 727 and the control portion may be positioned inside the housing 721 or the wearing portion 723.

Similarly, the electronic device 800B illustrated in FIG. 33D includes earphone portions 827. For example, a structure in which the earphone portions 827 and the control portion 824 are connected to each other by wire may be employed. Part of a wiring that connects the earphone portions 827 and the control portion 824 may be positioned inside the housing 821 or the wearing portion 823. The earphone portions 827 and the wearing portion 823 may include magnets. This is preferable because the earphone portions 827 can be fixed to the wearing portion 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

FIG. 34A and FIG. 34B each illustrate an appearance of an electronic device 8300 that is a head-mounted display.

The electronic device 8300 includes a housing 8301, a display portion 8302, an operation button 8303, and a band-shaped fixing unit 8304.

The operation button 8303 functions as a power button, for example. The electronic device 8300 may include a button other than the operation button 8303.

As illustrated in FIG. 34C, lenses 8305 may be included between the display portion 8302 and the positions of the user's eyes. The user can see magnified images on the display portion 8302 through the lenses 8305, leading to a higher realistic sensation. In this case, a dial 8306 for changing the positions of the lenses and adjusting visibility may be included as illustrated in FIG. 34C.

The display device of one embodiment of the present invention can be used for the display portion 8302. Thus, the electronic device 8300 can display an image that appears in extremely high resolution. Accordingly, it is possible to display a more realistic image that does not allow the user to perceive pixels even when the image is magnified using the lenses 8305 as illustrated in FIG. 34C.

FIG. 34A to FIG. 34C illustrate an example where one display portion 8302 is provided. Such a structure can reduce the number of components.

The display portion 8302 can display an image for the right eye and an image for the left eye side by side on a right region and a left region, respectively. Thus, a three-dimensional image using binocular disparity can be displayed.

One image which can be seen by both eyes may be displayed on the entire display portion 8302. A panorama image can thus be displayed from end to end of the field of view, which can provide a stronger sense of reality.

Here, the electronic device 8300 preferably has, for example, a mechanism for changing the curvature of the display portion 8302 to an optimal value in accordance with the size of the user's head, the position of the user's eyes, and the like. For example, the user himself or herself may adjust the curvature of the display portion 8302 by operating a dial 8307 for adjusting the curvature of the display portion 8302. Alternatively, the housing 8301 may include a sensor for detecting the size of the user's head, the position of the user's eyes, or the like (e.g., a camera, a contact sensor, and a noncontact sensor) to provide a mechanism for adjusting the curvature of the display portion 8302 on the basis of data detected by the sensor.

In the case where the lenses 8305 are used, a mechanism for adjusting the position and angle of the lenses 8305 in synchronization with the curvature of the display portion 8302 is preferably provided. Alternatively, the dial 8306 may have a function of adjusting the angle of the lenses.

FIG. 34E and FIG. 34F illustrate an example where a driver portion 8308 controlling the curvature of the display portion 8302 is provided. The driver portion 8308 is fixed to at least a part of the display portion 8302. The driver portion 8308 has a function of changing the shape of the display portion 8302 when the part of the driver portion 8308 that is fixed to the display portion 8302 changes in shape or moves.

FIG. 34E is a schematic diagram illustrating the case where a user 8310 having a relatively large head wears the housing 8301. In this case, the driver portion 8308 adjusts the shape of the display portion 8302 so that the curvature is relatively small (the radius of curvature is large).

By contrast, FIG. 34F illustrates the case where a user 8311 having a smaller head than the user 8310 wears the housing 8301. The user 8311 has a shorter distance between the eyes than the user 8310. In this case, the driver portion 8308 adjusts the shape of the display portion 8302 so that the curvature of the display portion 8302 is large (the radius of curvature is small). In FIG. 34F, the position and shape of the display portion 8302 in FIG. 34E are denoted by a dashed line.

When the electronic device 8300 has such a mechanism for adjusting the curvature of the display portion 8302, an optimal display can be offered to a variety of users of all ages and genders.

When the curvature of the display portion 8302 is changed in accordance with contents displayed on the display portion 8302, the user can have a more realistic sensation. For example, shaking can be expressed by fluctuating the curvature of the display portion 8302. In this way, it is possible to produce various effects depending on the scene in contents, and provide the user with new experiences. A further realistic display can be provided when the display portion 8302 operates in conjunction with a vibration module provided in the housing 8301.

Note that the electronic device 8300 may include two display portions 8302 as illustrated in FIG. 34D.

Since the two display portions 8302 are included, the user's eyes can see their respective display portions. This allows a high-definition image to be displayed even when three-dimensional display using parallax or the like is performed. In addition, the display portion 8302 is curved around an arc with the user's eye as an approximate center. This allows a uniform distance between the user's eye and the display surface of the display portion; thus, the user can see a more natural image. Even when the luminance or chromaticity of light from the display portion is changed depending on the angle at which the user see it, since the user's eye is positioned in a normal direction of the display surface of the display portion, the influence of the change can be substantially ignorable and thus a more realistic image can be displayed.

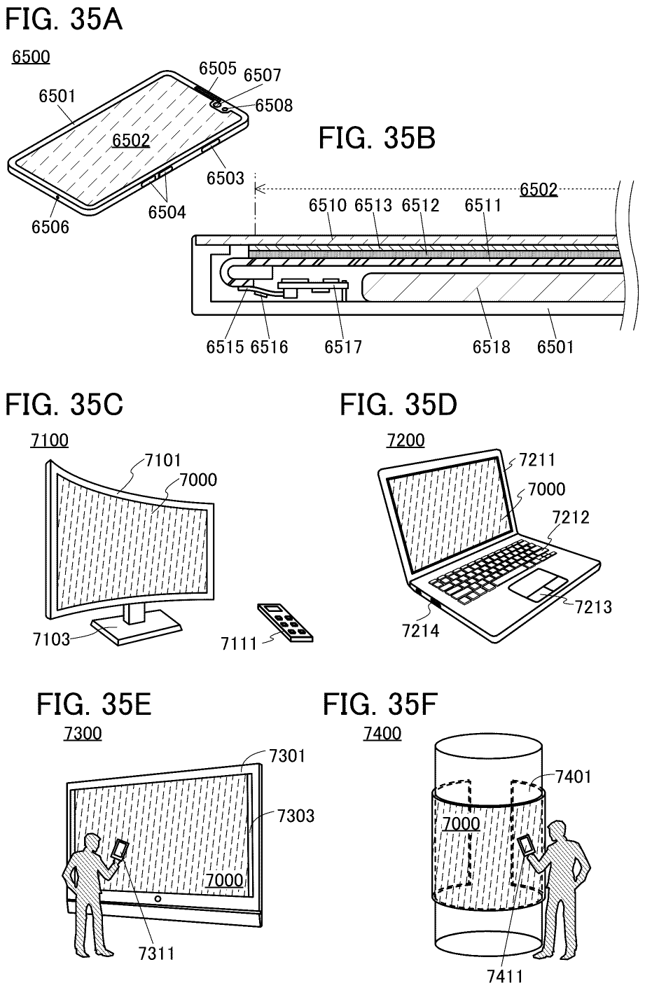

An electronic device 6500 illustrated in FIG. 35A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 35B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be achieved.

FIG. 35C illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 35C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 35D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 35E and FIG. 35F illustrate examples of digital signage.

Digital signage 7300 illustrated in FIG. 35E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 35F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 35E and FIG. 35F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 35E and FIG. 35F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

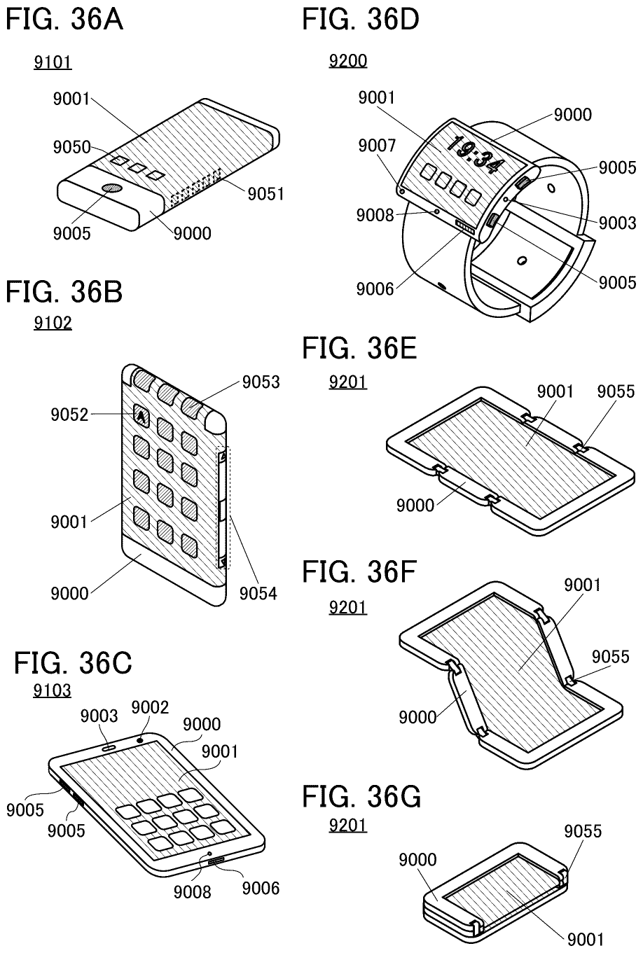

Electronic devices illustrated in FIG. 36A to FIG. 36G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 36A to FIG. 36G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 36A to FIG. 36G are described in detail below.

FIG. 36A is a perspective view showing a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 36A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 36B is a perspective view showing a portable information terminal 9102. The portable information terminal 9102 has a function of displaying information on three or more surfaces of the display portion 9001. Shown here is an example in which information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 36C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000

FIG. 36D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 36E to FIG. 36G are perspective views illustrating a foldable portable information terminal 9201. FIG. 36E is a perspective view of an opened state of the portable information terminal 9201, FIG. 36G is a perspective view of a folded state thereof, and FIG. 36F is a perspective view of a state in the middle of change from one of FIG. 36E and FIG. 36G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

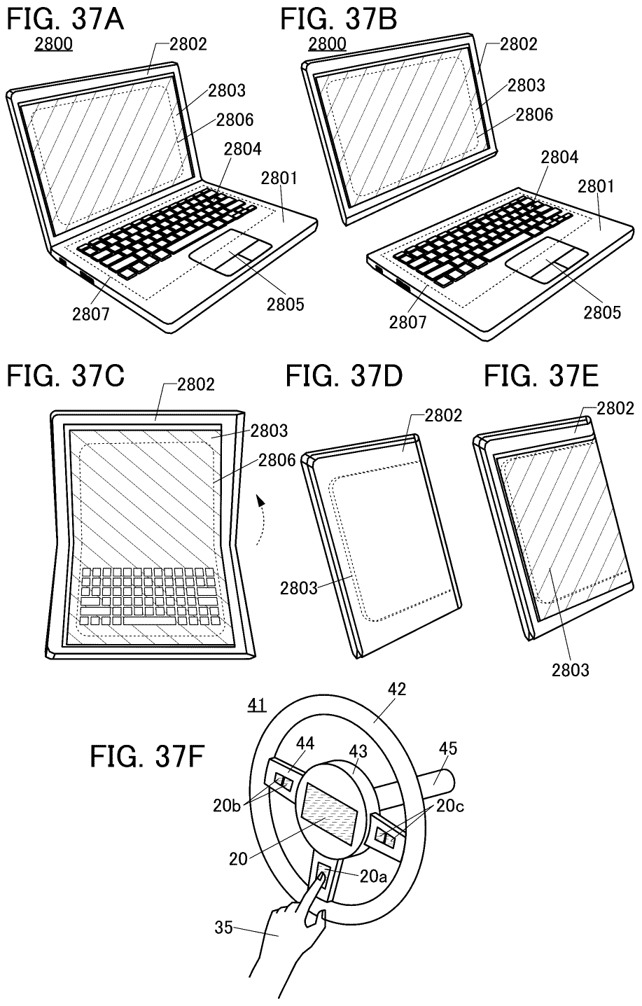

A personal computer 2800 illustrated in FIG. 37A includes a housing 2801, a housing 2802, a display portion 2803, a keyboard 2804, a pointing device 2805, and the like. A secondary battery 2807 is provided inside the housing 2801, and a secondary battery 2806 is provided inside the housing 2802. The display portion 2803 includes the display device of one embodiment of the present invention, and has a touch panel function. As illustrated in FIG. 37B, the housing 2801 and the housing 2802 of the personal computer 2800 can be detached and the housing 2802 can be used alone as a tablet terminal.

In a modification example of a personal computer illustrated in FIG. 37C, a flexible display is employed for the display portion 2803. With use of a flexible film as an exterior body, the secondary battery 2806 can be a bendable secondary battery. Accordingly, the housing 2802, the display portion 2803, and the secondary battery 2806 can be used in a bent state as illustrated in FIG. 37C. In that case, part of the display portion 2803 can be used as a keyboard as illustrated in FIG. 37C.

Furthermore, the housing 2802 can be folded such that the display portion 2803 is placed inward as illustrated in FIG. 37D, and the housing 2802 can be folded such that the display portion 2803 faces outward as illustrated in FIG. 37E.

FIG. 37F is a perspective view of a steering wheel of a vehicle. A steering wheel 41 includes a rim 42, a hub 43, spokes 44, a shaft 45, and the like. A display portion 20 is provided on the surface of the hub 43. The number of spokes 44 here is three. The spoke 44 located on the lower side is provided with a light-receiving and light-emitting portion 20a; the spoke 44 located on the left side is provided with a plurality of light-receiving and light-emitting portions 20b; and the spoke 44 located on the right side is provided with a plurality of light-receiving and light-emitting portions 20c. When a driver holds a finger of a hand 35 over the light-receiving and light-emitting portion 20a, information on a fingerprint of the driver is obtained, and user authentication can be performed with the information. Touching the light-receiving and light-emitting portions 20b, the light-receiving and light-emitting portions 20c, and the like, the driver can operate a navigation system, an audio system, a call system, and the like included in the vehicle. In addition, a variety of operations such as adjustment of a rearview mirror and a sideview mirror, turning on/off of an interior light, adjustment of luminance, and opening/closing a window are possible.

This embodiment can be combined with the other embodiments as appropriate.

### Example 1

Described in this example are the results of reproducing the display device shown in Embodiment 1 by simulation and displaying images on the display device.

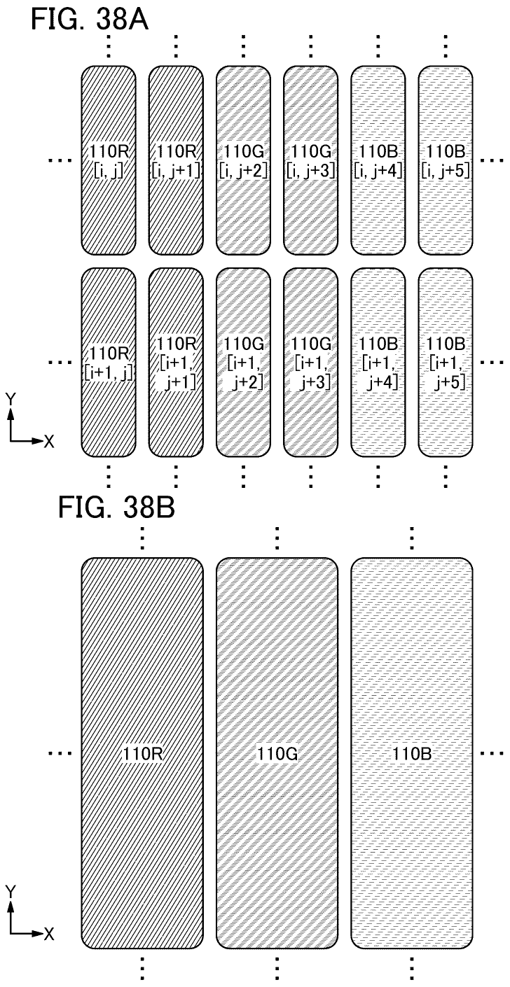

FIG. 38A and FIG. 38B are top views each illustrating a structure of the display device reproduced in this example. The display device illustrated in FIG. 38A corresponds to the display device 100 illustrated in FIG. 1 of Embodiment 1. FIG. 38A illustrates subpixels 110 in the i-th row and the j-th column to the (i+1)-th row and the (j+5)-th column (here, i is an integer of 1 or more and j is 1 or 1+a multiple of 6). In the display device illustrated in FIG. 38B, one subpixel 110 consists of the subpixels 110 of two rows and two columns with the same color in FIG. 38A. It is assumed that the display device illustrated in FIG. 38A includes EL films divided by a photolithography method or the like, and the display device illustrated in FIG. 38B includes EL films not divided.

In FIG. 38A and FIG. 38B, a subpixel 110R denotes the subpixel 110 emitting red light, a subpixel 110G denotes the subpixel 110 emitting green light, and a subpixel 110B denotes the subpixel 110 emitting blue light. The same applies to the following drawings.

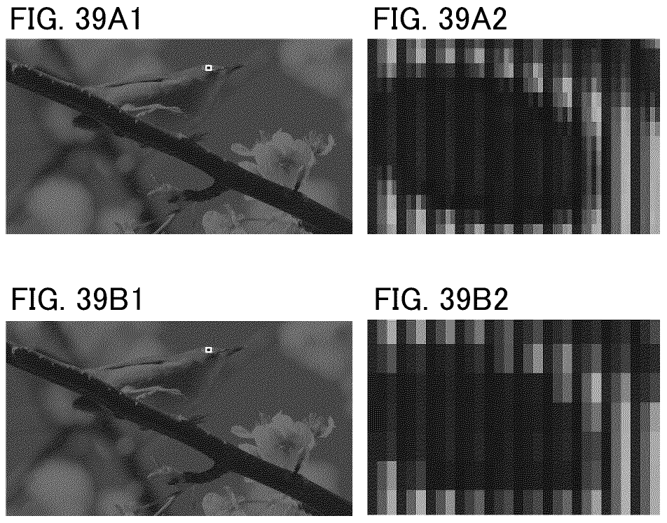

FIG. 39A1 shows an image displayed on the display device illustrated in FIG. 38A that was reproduced by simulation. FIG. 39A2 is an enlarged view of a portion indicated by a white square in FIG. 39A1. FIG. 39B1 shows an image displayed on the display device illustrated in FIG. 38B that was reproduced by simulation. FIG. 39B2 is an enlarged view of a portion indicated by a white square in FIG. 39B1.

As shown in FIG. 39A2, FIG. 39B2, and the like, the display device illustrated in FIG. 38A was found to display by simulation an image that appears in higher resolution than an image displayed on the display device illustrated in FIG. 38B.

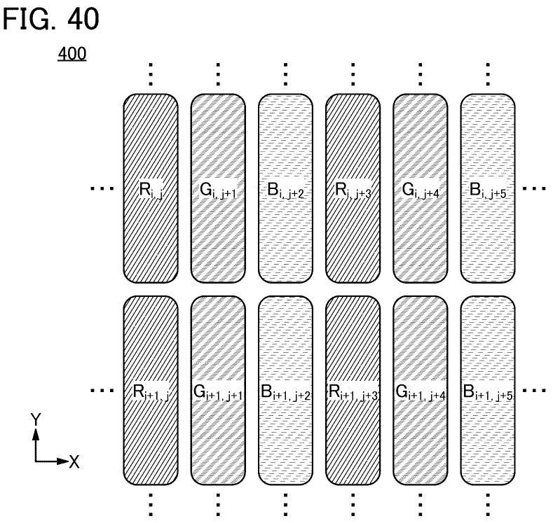

This example also verified by simulation the results of displaying an image on the display device illustrated in FIG. 38A in the case where the display device is driven by the method shown in FIG. 12 of Embodiment 1. First, the display device 400 is assumed to have the structure illustrated in FIG. 40 (Step S1). In FIG. 40, R denotes a subpixel emitting red light, G denotes a subpixel emitting green light, and B denotes a subpixel emitting blue light.

Here, the luminance value of a subpixel 110R[i, j], the luminance value of a subpixel 110G[i, j+2], the luminance value of a subpixel 110G[i, j+3], and the luminance value of a subpixel 110B[i, j+5] illustrated in FIG. 38A are equal to the luminance value of R_{i,j}, the luminance value of G_{i,j+1}, the luminance value of G_{i,j+4}, and the luminance value of B_{i,j+5}, respectively, illustrated in FIG. 40. The luminance value of a subpixel 110R[i+1, j], the luminance value of a subpixel 110G[i+1, j+2], the luminance value of a subpixel 110G[i+1, j+3], and the luminance value of a subpixel 110B[i+1, j+5] are equal to the luminance value of R_{i+1,j}, the luminance value of G_{i+1,j+1}, the luminance value of G_{i+1,j+4}, and the luminance value of B_{i+1,j+5}, respectively, illustrated in FIG. 40.

The luminance value of a subpixel 110R[i, j+1] illustrated in FIG. 38A was calculated from the following formula (3) and the luminance value of a subpixel 110B[i, j+4] was calculated from the following formula (4) (Step S2). Here, L(R_{i,j}), L(R_{i,j}+3), L(B_{i,j+2}), and L(B_{i,j+5}) denote the luminance value of R_{i,j}, the luminance value of R_{i,j+3}, the luminance value of B_{i,j+2}, and the luminance value of B_{i,j+5}, respectively, illustrated in FIG. 40.

$$[ Formula 3 ]$$

$$\frac{2 \cdot L ( {R}_{i , j} ) + L ( {R}_{i , j + 3} )}{3} \qquad ( 3 )$$

$$[ Formula 4 ]$$

$$\frac{L ( {B}_{i , j + 2} ) + 2 \cdot L ( {B}_{i , j + 5} )}{3} \qquad ( 4 )$$

The luminance value of a subpixel 110R[i+1, j+1] was calculated by substituting i+1 for i in the above formula (3). The luminance value of a subpixel 110B[i+1, j+4] was calculated by substituting i+1 for i in the above formula (4).

An image based on the aforementioned luminance values was displayed by simulation (Step S3).

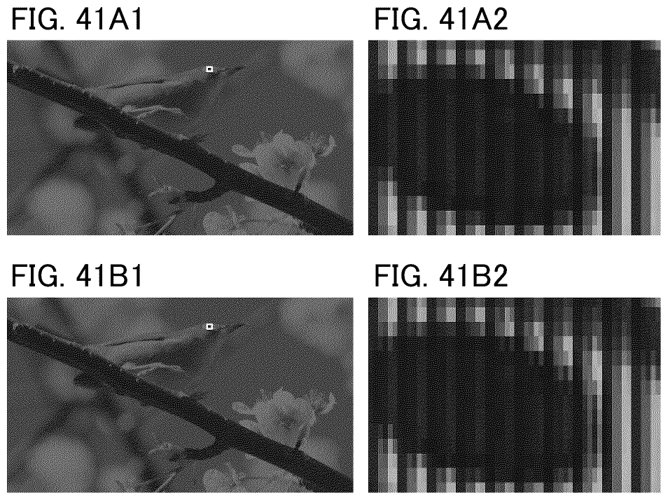

FIG. 41A1 shows an image displayed on the display device illustrated in FIG. 38A that was reproduced by simulation to be driven by the method shown in FIG. 12. FIG. 41A2 is an enlarged view of a portion indicated by a white square in FIG. 41A1. FIG. 41B1 shows the same image as that in FIG. 39B1, which is displayed on the display device illustrated in FIG. 38A that was reproduced by simulation without correction of a luminance value by the method shown in FIG. 12. FIG. 41B2 is an enlarged view of a portion indicated by a white square in FIG. 41B1 and shows the same image as that in FIG. 39B2.

As shown in FIG. 41A2, FIG. 41B2, and the like, an image with a smooth edge portion was found to be displayed by correcting a luminance value by the method shown in FIG. 12.

### Example 2

Described in this example are the results of reproducing the display device shown in Embodiment 1 by simulation and displaying images on the display device.

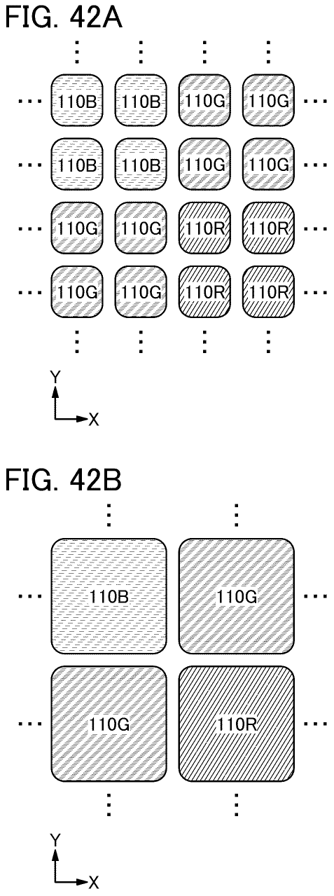

FIG. 42A and FIG. 42B are top views each illustrating a structure of the display device reproduced in this example. The display device illustrated in FIG. 42A corresponds to the display device 100 illustrated in FIG. 14A of Embodiment 1. In the display device illustrated in FIG. 42B, one subpixel 110 consists of the subpixels 110 of two rows and two columns with the same color in FIG. 42A. It is assumed that the display device illustrated in FIG. 42A includes EL films divided by a photolithography method or the like, and the display device illustrated in FIG. 42B includes EL films not divided.

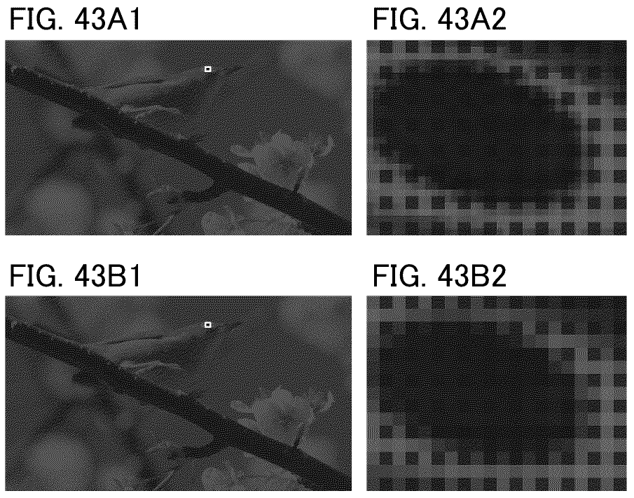

FIG. 43A1 shows an image displayed on the display device illustrated in FIG. 42A that was reproduced by simulation. FIG. 43A2 is an enlarged view of a portion indicated by a white square in FIG. 43A1. FIG. 43B1 shows an image displayed on the display device illustrated in FIG. 42B that was reproduced by simulation. FIG. 43B2 is an enlarged view of a portion indicated by a white square in FIG. 43B1.

As shown in FIG. 43A2, FIG. 43B2, and the like, the display device illustrated in FIG. 42A was found to display by simulation an image that appears in higher resolution than an image displayed on the display device illustrated in FIG. 42B.

### Example 3

Described in this example are the results of reproducing the display device shown in Embodiment 1 by simulation and displaying images on the display device.

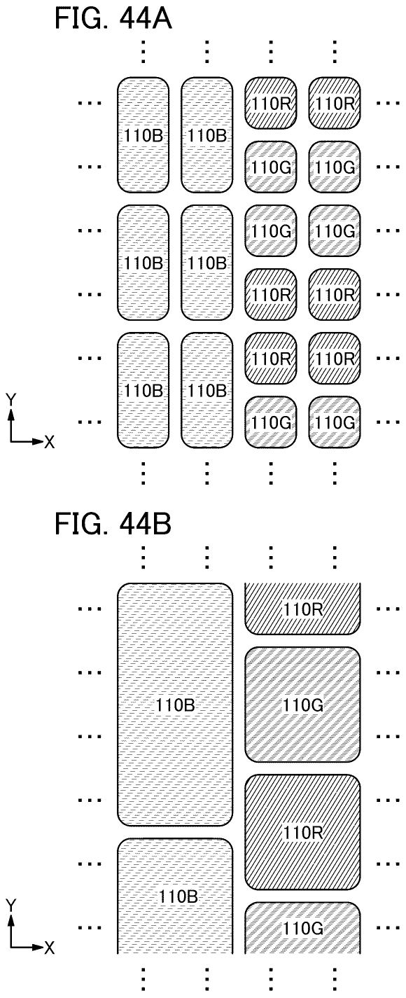

FIG. 44A and FIG. 44B are top views each illustrating a structure of the display device reproduced in this example. The display device illustrated in FIG. 44A corresponds to the display device 100 illustrated in FIG. 16 of Embodiment 1. In the display device illustrated in FIG. 44B, one subpixel 110 consists of the subpixels 110 of two rows and two columns with the same color in FIG. 44A. It is assumed that the display device illustrated in FIG. 44A includes EL films divided by a photolithography method or the like, and the display device illustrated in FIG. 44B includes EL films not divided.

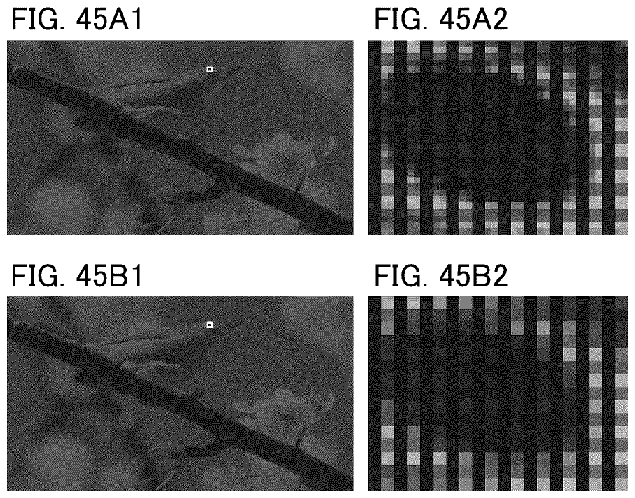

FIG. 45A1 shows an image displayed on the display device illustrated in FIG. 44A that was reproduced by simulation. FIG. 45A2 is an enlarged view of a portion indicated by a white square in FIG. 45A1. FIG. 45B1 shows an image displayed on the display device illustrated in FIG. 44B that was reproduced by simulation. FIG. 45B2 is an enlarged view of a portion indicated by a white square in FIG. 45B1.

As shown in FIG. 45A2, FIG. 45B2, and the like, the display device illustrated in FIG. 44A was found to display by simulation an image that appears in higher resolution than an image displayed on the display device illustrated in FIG. 44B.

### Example 4

Described in this example are the results of reproducing the display device shown in Embodiment 1 by simulation and displaying images on the display device.

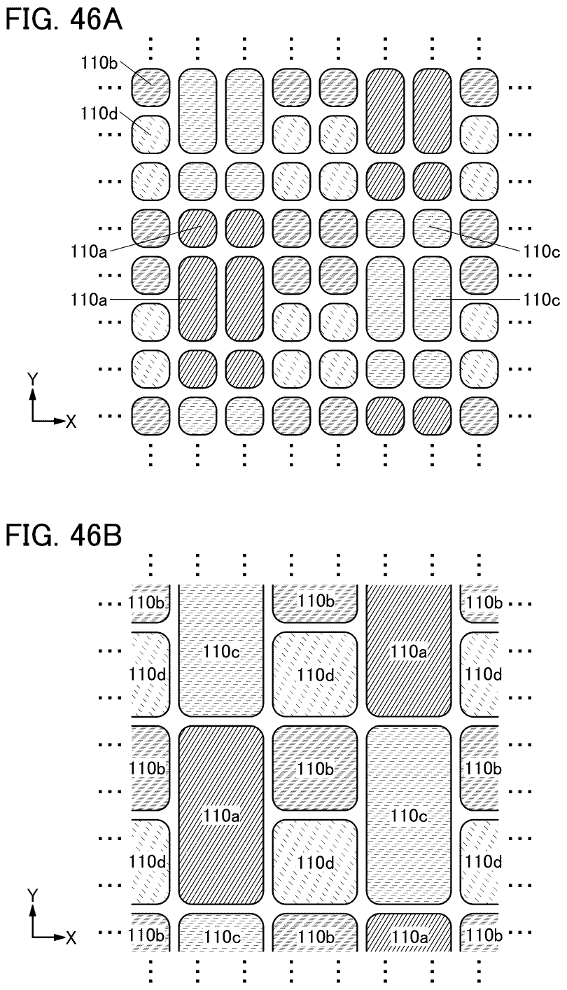

FIG. 46A and FIG. 46B are top views each illustrating a structure of the display device reproduced in this example. The display device illustrated in FIG. 46A corresponds to the display device 100 illustrated in FIG. 20 of Embodiment 1. In the display device illustrated in FIG. 46B, one subpixel 110a consists of the subpixels 110a of four rows and two columns in FIG. 46A, and one subpixel 110c consists of the subpixels 110c of four rows and two columns in FIG. 46A. In the display device illustrated in FIG. 46B, one subpixel 110b consists of the subpixels 110b of two rows and two columns in FIG. 46A, and one subpixel 110d consists of the subpixels 110d of two rows and two columns in FIG. 46A. It is assumed that the display device illustrated in FIG. 46A includes EL films divided by a photolithography method or the like, and the display device illustrated in FIG. 46B includes EL films not divided.

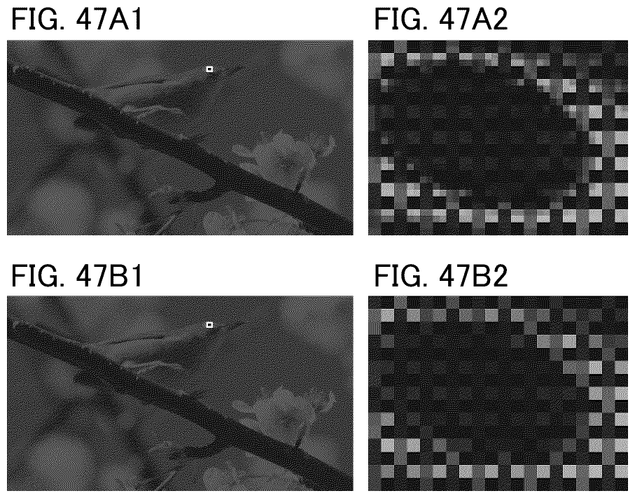

FIG. 47A1 shows an image displayed on the display device illustrated in FIG. 46A that was reproduced by simulation. FIG. 47A2 is an enlarged view of a portion indicated by a white square in FIG. 47A1. FIG. 47B1 shows an image displayed on the display device illustrated in FIG. 46B that was reproduced by simulation. FIG. 47B2 is an enlarged view of a portion indicated by a white square in FIG. 47B1.

As shown in FIG. 47A2, FIG. 47B2, and the like, the display device illustrated in FIG. 46A was found to display by simulation an image that appears in higher resolution than an image displayed on the display device illustrated in FIG. 46B.

### Example 5

Described in this example are the results of reproducing the display device shown in Embodiment 1 by simulation and displaying images on the display device.

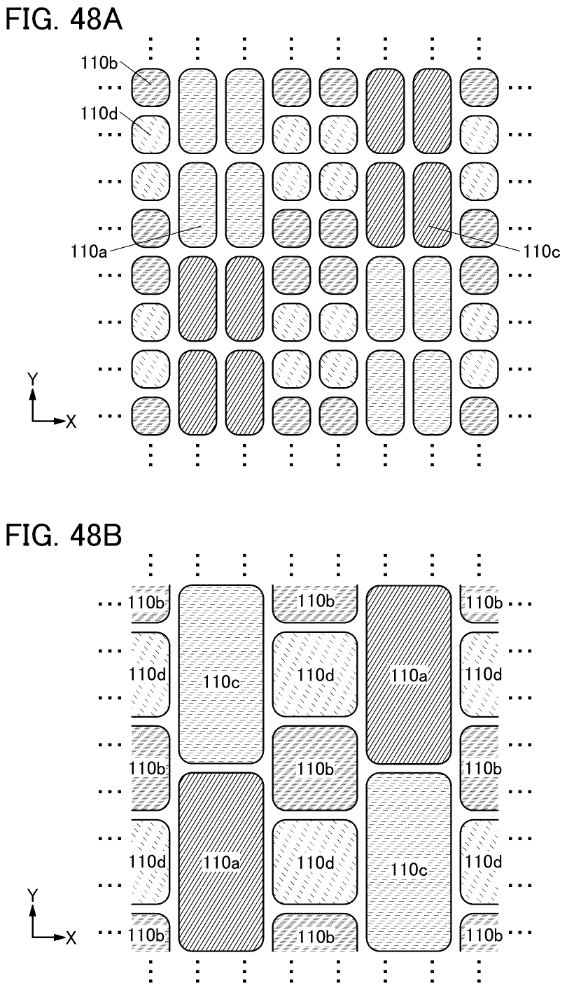

FIG. 48A and FIG. 48B are top views each illustrating a structure of the display device reproduced in this example. The display device illustrated in FIG. 48A corresponds to the display device 100 illustrated in FIG. 21 of Embodiment 1. In the display device illustrated in FIG. 48B, one subpixel 110a consists of the 2×2 subpixels 110a in FIG. 48A, and one subpixel 110c consists of the 2×2 subpixels 110c in FIG. 48A. In the display device illustrated in FIG. 48B, one subpixel 110b consists of the subpixels 110b of two rows and two columns in FIG. 48A, and one subpixel 110d consists of the subpixels 110d of two rows and two columns in FIG. 48A. It is assumed that the display device illustrated in FIG. 48A includes EL films divided by a photolithography method or the like, and the display device illustrated in FIG. 48B includes EL films not divided.

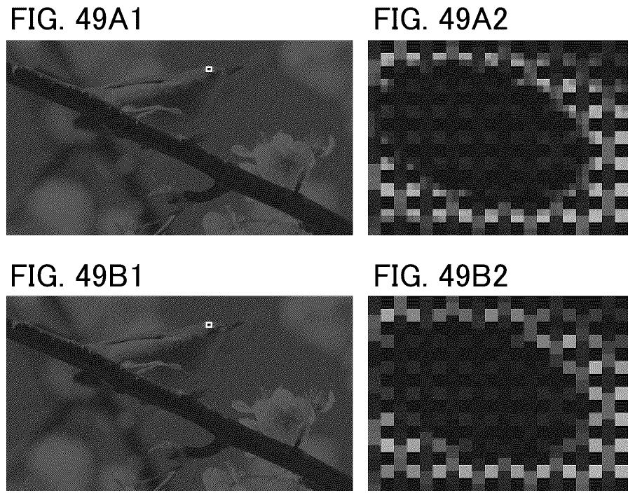

FIG. 49A1 shows an image displayed on the display device illustrated in FIG. 48A that was reproduced by simulation. FIG. 49A2 is an enlarged view of a portion indicated by a white square in FIG. 49A1. FIG. 49B1 shows an image displayed on the display device illustrated in FIG. 48B that was reproduced by simulation. FIG. 49B2 is an enlarged view of a portion indicated by a white square in FIG. 49B1.

As shown in FIG. 49A2, FIG. 49B2, and the like, the display device illustrated in FIG. 48A was found to display by simulation an image that appears in higher resolution than an image displayed on the display device illustrated in FIG. 48B.

### REFERENCE NUMERALS

20a: light-receiving and light-emitting portion, 20b: light-receiving and light-emitting portion, 20c: light-receiving and light-emitting portion, 20: display portion, 35: hand, 41: steering wheel, 42: rim, 43: hub, 44: spoke, 45: shaft, 100: display device, 101: layer, 103[1,1]: pixel, 103[1,2]: pixel, 103[2,1]: pixel, 103[2,2]: pixel, 103[3,3]: pixel, 103[4,4]: pixel, 103: pixel, 110a: subpixel, 110a[1,1]: subpixel, 110a[1,2]: subpixel, 110a[2,1]: subpixel, 110a[2,2]: subpixel, 110B: subpixel, 110b: subpixel, 110b[1,3]: subpixel, 110b[1,4]: subpixel, 110b[2,3]: subpixel, 110b[2,4]: subpixel, 110B[i+1, j+4]: subpixel, 110B[i+1, j+5]: subpixel, 110B[i, j+4]: subpixel, 110B[i, j+5]: subpixel, 110c: subpixel, 110c[1,5]: subpixel, 110c[1,6]: subpixel, 110c[2,5]: subpixel, 110c[2,6]: subpixel, 110d: subpixel, 110G: subpixel, 110G[i+1, j+2]: subpixel, 110G[i+1, j+3]: subpixel, 110G[i, j+2]: subpixel, 110G[i, j+3]: subpixel, 110R: subpixel, 110R[i+1, j+1]: subpixel, 110R[i+1, j]: subpixel, 110R[i, j+1]: subpixel, 110R[i, j]: subpixel, 110: subpixel, 111: pixel electrode, 112: conductive layer, 113a: EL layer, 113b: EL layer, 113c: EL layer, 113: EL layer, 114: common layer, 115: common electrode, 116: tapered portion, 117: light-blocking layer, 118A: sacrificial film, 118: sacrificial layer, 119A: sacrificial film, 119: sacrificial layer, 120: substrate, 121: insulating layer, 122: resin layer, 123: connection electrode, 124: microlens array, 125A: insulating film, 125: insulating layer, 126: conductive layer, 127A: insulating film, 127: insulating layer, 128: layer, 129: conductive layer, 130a: light-emitting element, 130b: light-emitting element, 130c: light-emitting element, 130: light-emitting element, 131: protective layer, 140: connection portion, 142: adhesive layer, 150: light-receiving element, 151: substrate, 152: substrate, 153: insulating layer, 155: PD layer, 162: display portion, 164: circuit portion, 165: wiring, 166: conductive layer, 172: FPC, 173: IC, 180a: EL film, 180b: EL film, 180c: EL film, 180: EL film, 181a: nozzle, 181b: nozzle, 181c: nozzle, 182a: droplet, 182b: droplet, 182c: droplet, 190: resist mask, 191a: FMM, 191b: FMM, 191c: FMM, 191: FMM, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 400: display device, 403[1, 1]: pixel, 403[1,2]: pixel, 403[2,1]: pixel, 403[2,2]: pixel, 403: pixel, 700A: electronic device, 700B: electronic device, 721: housing, 723: wearing portion, 727: earphone portion, 750: earphone, 751: display panel, 753: optical member, 756: display region, 757: frame, 758: nose pad, 772: lower electrode, 785: layer, 786a: EL layer, 786b: EL layer, 786: EL layer, 788: upper electrode, 800A: electronic device, 800B: electronic device, 820: display portion, 821: housing, 822: communication portion, 823: wearing portion, 824: control portion, 825: image capturing portion, 827: earphone portion, 832: lens, 2800: personal computer, 2801: housing, 2802: housing, 2803: display portion, 2804: keyboard, 2805: pointing device, 2806: secondary battery, 2807: secondary battery, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 8300: electronic device, 8301: housing, 8302: display portion, 8303: operation button, 8304: fixing unit, 8305: lens, 8306: dial, 8307: dial, 8308: driver portion, 8310: user, 8311: user, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first pixel electrode;
a second pixel electrode;
a third pixel electrode;
a fourth pixel electrode;
a first EL layer over the first pixel electrode;
a second EL layer over the second pixel electrode;
a third EL layer over the third pixel electrode;
a fourth EL layer over the fourth pixel electrode;
an insulating layer between the first EL layer and the second EL layer, between the second EL layer and the third EL layer, and between the third EL layer and the fourth EL layer;
a common layer over the first EL layer, the second EL layer, the third EL layer, the fourth EL layer, and the insulating layer; and
a common electrode layer over the common layer,
wherein the first EL layer, the second EL layer, the third EL layer, and the fourth EL layer are arranged in this order to be adjacent to each other in one direction,
wherein the first EL layer and the second EL layer emit light of the same color,
wherein the third EL layer and the fourth EL layer emit light of the same color, and
wherein the first EL layer and the second EL layer emit light of a color different from the color of the light emitted from the third EL layer and the fourth EL layer.

2. The display device according to claim 1, further comprising a first transistor, a second transistor, a third transistor, and a fourth transistor,
wherein one of a source and a drain of the first transistor is electrically connected to the first pixel electrode,
wherein one of a source and a drain of the second transistor is electrically connected to the second pixel electrode,
wherein one of a source and a drain of the third transistor is electrically connected to the third pixel electrode,
wherein one of a source and a drain of the fourth transistor is electrically connected to the fourth pixel electrode, and
wherein at least one of the first to fourth transistors include a metal oxide in a channel formation region.

3-4. (canceled)

5. The display device according to claim 1,
wherein the insulating layer comprises a photosensitive material.

6. The display device according to claim 1,
wherein the common layer comprises at least one of a hole-injection layer, a hole-transport layer, a hole-blocking layer, an electron-blocking layer, an electron-transport layer, and an electron-injection layer.

7. A method for manufacturing a display device, comprising:
forming a first pixel electrode, a second pixel electrode, a third pixel electrode, and a fourth pixel electrode;
forming a first EL film over the first pixel electrode and the second pixel electrode and a second EL film over the third pixel electrode and the fourth pixel electrode;
processing the first EL film to form a first EL layer over the first pixel electrode and a second EL layer over the second pixel electrode;
processing the second EL film to form a third EL layer over the third pixel electrode and a fourth EL layer over the fourth pixel electrode;
forming an insulating film to cover the first EL layer, the second EL layer, the third EL layer, and the fourth EL layer; and
processing the insulating film to form an insulating layer between the first EL layer and the second EL layer, between the second EL layer and the third EL layer, and between the third EL layer and the fourth EL layer,
wherein the first EL layer, the second EL layer, the third EL layer, and the fourth EL layer are arranged in this order to be adjacent to each other in one direction.

8. The method for manufacturing a display device, according to claim 7,
wherein the first EL layer and the second EL layer emit light of the same color,
wherein the third EL layer and the fourth EL layer emit light of the same color, and
wherein the first EL layer and the second EL layer emit light of a color different from the color of the light emitted from the third EL layer and the fourth EL layer.

9. The method for manufacturing a display device, according to claim 7,
wherein the first EL film and the second EL film are formed by an evaporation method using a metal mask.

10. The method for manufacturing a display device,
according to claim 7,
wherein the first EL film and the second EL film are formed by a wet method.

11. The method for manufacturing a display device, according to claim 7, further comprising:
forming a sacrificial film over the first EL film and the second EL film;
forming a resist mask over the sacrificial film; and
processing the sacrificial film to form a first sacrificial layer over the first EL layer, a second sacrificial layer over the second EL layer, a third sacrificial layer over the third EL layer, and a fourth sacrificial layer over the fourth EL layer.

12. (canceled)

13. The method for manufacturing a display device, according to claim 7,
wherein the insulating film is formed by a spin coating method, a spray coating method, or a screen printing method.

14. The method for manufacturing a display device, according to claim 7,
wherein the insulating film comprises a photosensitive material, and
wherein the insulating film is processed by a photolithography method.

15. The method for manufacturing a display device, according to claim 7, further comprising:
forming a common layer over the first EL layer, the second EL layer, the third EL layer, the fourth EL layer, and the insulating layer; and
forming a common electrode over the common layer,
wherein the common layer comprises at least one of a hole-injection layer, a hole-transport layer, a hole-blocking layer, an electron-blocking layer, an electron-transport layer, and an electron-injection layer.
